(19) United States
(12) Patent Application Publication
(10) Pub. No.: US 2017/0003586 A1
(43) Pub. Date: Jan. 5, 2017

(54) PHOTOSENSITIVE RESIN COMPOSITION AND USES THEREOF

(71) Applicant: CHI MEI CORPORATION, TAINAN CITY (TW)

(72) Inventors: HAO-WEI LIAO, TAINAN CITY (TW); HUNG-CHIA CHOU, TAINAN CITY (TW)

(21) Appl. No.: 15/195,730

(22) Filed: Jun. 28, 2016

(30) Foreign Application Priority Data
Jun. 30, 2015 (TW) 104121182

(51) Int. Cl. G03F 7/00; G03F 7/16; G02B 5/22; G03F 7/32; G03F 7/40; G02F 1/1335; G03F 7/031; G03F 7/20

(52) U.S. Cl. CPC G03F 7/0007; G03F 7/031; G03F 7/168; G03F 7/20; G03F 7/32; G03F 7/40; G02F 1/133514; G02B 5/22

(57) ABSTRACT

The invention relates to a photosensitive resin composition for black matrix, a color filter formed by the black matrix, and a liquid crystal display element. The photosensitive resin composition comprises an alkali-soluble resin (A), a compound containing an ethylenically unsaturated group (B), a photoinitiator (C), a solvent (D), a black pigment (E), and a compound (F) containing Formula (1). The photosensitive resin composition for black matrix has the advantage of good linearity of pattern with high finesse.

### BACKGROUND OF THE INVENTION

1. Field of the Invention

The present invention relates to a photosensitive resin composition for black matrix and a color filter and liquid crystal display element formed by the aforementioned black matrix. More particularly, the present invention provides a photosensitive resin composition for black matrix having good linearity of pattern with high finesse, a color filter formed by the black matrix, and a liquid crystal display device

2. Description of the Related Art

Recently, as various techniques of liquid crystal display are promptly developed, a black matrix is usually disposed in the gaps between stripes and dots of the color filter in a liquid crystal display, for improving the contract ratio and display quality of the liquid crystal display. The black matrix can prevent the reduction of contrast ratio and the reduction of color purity due to the light leakage between pixels.

Generally, the black matrix may be an evaporated film including chromium or chromium oxide. However, the black matrix formed by such evaporated film causes several disadvantages such as the complicated process and costly materials. To solve this issue, the black matrix may be formed by photolithographic process.

Japan published patent application No. 2006-259716 discloses a photosensitive resin composition for black matrix. The photosensitive resin composition includes a high amount of a black pigment, an alkali-soluble resin, a photopolymerization initiator, a reactive monomer having two functional groups, and an organic solvent. The reactive monomer having the two functional groups can improve the reaction among the compounds so as to form a fine pattern. Therefore, the resulted photosensitive resin composition has a good light-shielding property and high sensitivity.

Moreover, Japan published patent application No. 2008-268854 discloses a photosensitive resin composition for black matrix. The photosensitive resin composition an alkali-soluble resin having a carboxylic group and an unsaturated group, a photopolymerizable monomer having an ethylenically unsaturated group, a photopolymerization initiator, and a black pigment in high amount. The alkali-soluble resin having the carboxylic group and the unsaturated group may improve the resolution of the photosensitive resin composition.

Although the light-shielding property of the photosensitive resin composition may be enhanced by increasing the amount of the black pigment, however, after the aforementioned photosensitive resin composition is developed, the linearity of pattern with high finesse of the black matrix cannot be accepted in the field. Therefore, a photosensitive resin composition for a black matrix having good linearity of pattern with high finesse is still required.

### SUMMARY OF THE INVENTION

In the present invention, a specific alkali-soluble resin are provided to obtain a photosensitive resin composition have good linearity of pattern with high finesse.

Therefore, the present invention relates to a photosensitive resin composition comprising:
an alkali-soluble resin (A);
a compound (B) containing an ethylenically unsaturated group;
a photoinitiator (C);
a solvent (D);
a black pigment (E); and a compound (F) having a structure represented by Formula (1);
wherein:
the alkali-soluble resin (A) comprises a resin (A-1) having an unsaturated group, and the resin (A-1) having the unsaturated group is obtained by polymerizing a mixture comprising an epoxy compound (a-1-1) containing at least two epoxy groups, and a compound (a-1-2) containing at least one carboxylic acid group and at least one ethylenically unsaturated group;

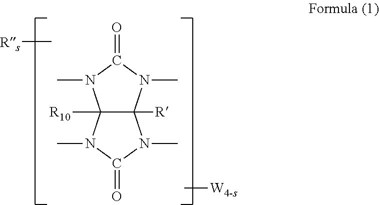

in Formula (1), R′ is selected from the group consisting of a hydrogen atom, a substituted or unsubstituted C₁-C₂₀ hydrocarbon group and a substituted or unsubstituted C₁-C₂₀ acyl group; each R′ is the same or different;
R″ is selected from the group consisting of a hydrogen atom, a substituted or unsubstituted C₁-C₁₅ hydrocarbon group, a substituted or unsubstituted C₁-C₁₅ acyl group and a substituted or unsubstituted C₁-C₁₅ nitro group; each R″ is the same or different;
s represents 0, 1 or 2; and
W represents

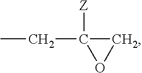

wherein, Z represents a hydrogen atom or a C₁-C₄ alkyl group.

The present invention also provides a black matrix formed by the photosensitive resin composition as mentioned above.

The present invention also provides a color filter comprising the black matrix as mentioned above.

The present invention further provides a liquid crystal display element comprising the color filter as mentioned above.

### DETAILED DESCRIPTION OF THE INVENTION

The present invention provides a photosensitive resin composition comprising:
an alkali-soluble resin (A);
a compound (B) containing an ethylenically unsaturated group;
a photoinitiator (C);
a solvent (D);
a black pigment (E); and
a compound (F) having a structure represented by Formula (1);
wherein:
the alkali-soluble resin (A) comprises a resin (A-1) having an unsaturated group, and the resin (A-1) having the unsaturated group is obtained by polymerizing a mixture comprising an epoxy compound (a-1-1) containing at least two epoxy groups, and a compound (a-1-2) containing at least one carboxylic acid group and at least one ethylenically unsaturated group;

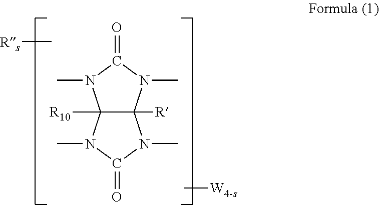

in Formula (1), R′ is selected from the group consisting of a hydrogen atom, a substituted or unsubstituted C₁-C₂₀ hydrocarbon group and a substituted or unsubstituted C₁-C₂₀ acyl group; each R′ is the same or different;
R″ is selected from the group consisting of a hydrogen atom, a substituted or unsubstituted C₁-C₁₅ hydrocarbon group, a substituted or unsubstituted C₁-C₁₅ acyl group and a substituted or unsubstituted C₁-C₁₅ nitro group; each R″ is the same or different;
s represents 0, 1 or 2; and
W represents

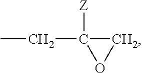

wherein, Z represents a hydrogen atom or a C₁-C₄ alkyl group.

The alkali-soluble resin (A) according to the present invention includes the resin (A-1) having the unsaturated group. Moreover, the alkali-soluble resin (A) optionally includes another alkali-soluble resin (A-2).

The resin (A-1) having the unsaturated group is obtained by polymerizing a mixture. The mixture includes the epoxy compound (a-1-1) containing at least two epoxy groups, and the compound (a-1-2) containing at least one carboxylic acid group and at least one ethylenically unsaturated group. Moreover, the mixture optionally include a carboxylic acid anhydride compound (a-1-3) and a compound (a-1-4) having an epoxy group.

The epoxy compound (a-1-1) containing at least two epoxy groups comprises a compound represented by Formula (2), a compound represented by Formula (3) or combinations thereof:

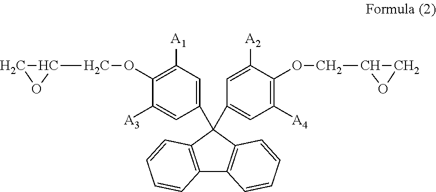

wherein in Formula (2), A₁ to A₄ independently represent a hydrogen atom, a halogen atom, a C₁-C₅ alkyl group, a C₁-C₅ alkoxy group, a C₆-C₁₂ aromatic group or a C₆-C₁₂ aromatic alkyl group.

The compound containing the structure represented by Formula (2) includes but is not limited to a bisphenol fluorene-type compound having an epoxy group obtained by reacting a bisphenol fluorene and epihalohydrin.

Examples of the aforementioned bisphenol fluorene-type compound include but are not limited to 9,9-bis(4-hydroxyphenyl)fluorine, 9,9-bis(4-hydroxy-3-methylphenyl)fluorine, 9,9-bis(4-hydroxy-3-chlorophenyl)fluorine, 9,9-bis(4-hydroxy-3-bromophenyl)fluorine, 9,9-bis(4-hydroxy-3-fluorophenyl)fluorine, 9,9-bis(4-hydroxy-3-methoxyphenyl)fluorine, 9,9-bis(4-hydroxy-3,5-dimethylphenyl)fluorine, 9,9-bis(4-hydroxy-3,5-dichlorophenyl)fluorine, 9,9-bis(4-hydroxy-3,5-dibromophenyl)fluorine, or a similar compound thereof, or any combination of the above-mentioned compounds.

Examples of the aforementioned epihalohydrin include but are not limited to epichlorohydrin, epibromohydrin, or a similar compound thereof, or any combination of the above-mentioned compounds.

Examples of the bisphenol fluorene-type compound having the epoxy group include (1) products made by Nippon Steel Chemical Co., Ltd. such as the trade name of ESF-300 or similar products thereof; (2) products made by Osaka Gas Co., Ltd. such as the trade names of PG-100, EG-210, or similar products thereof; or (3) products made by S.M.S. Technology Co. such as the trade names of SMS-F9PhPG, SMS-F9CrG, SMS-F914PG, or similar products thereof.

In other embodiment of the invention, the epoxy compound (a-1-1) containing at least two epoxy groups comprises the structure represented by Formula (3):

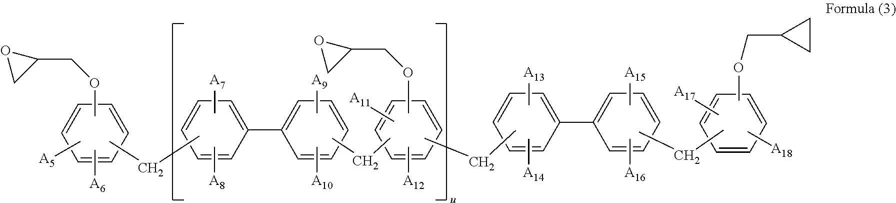

wherein in Formula (3), A₅ to A₁₈ independently represent a hydrogen atom, a halogen atom, a C₁-C₈ alkyl group or a C₆-C₁₅ aromatic group, and u represents an integer of 0 to 10.

The compound (a-1-1) represented by Formula (3) is obtained by reacting a compound represented by Formula (3-1) as below and an epihalohydrin in the presence of an alkali metal hydroxide:

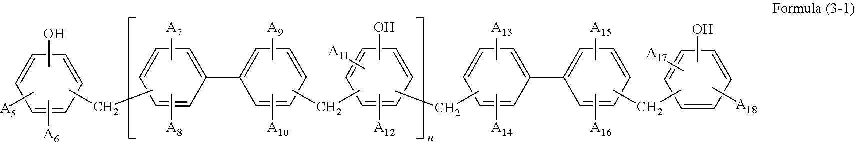

in Formula (3-1), A₅ to A₁₈ and u are the same to the aforementioned definition, and are not repeated again.

The aforementioned compound represented by Formula (3) is obtained by condensing a compound represented by Formula (3-1-1) and phenol in the presence of an acid catalyst, thereby forming the compound represented by Formula (3-1).

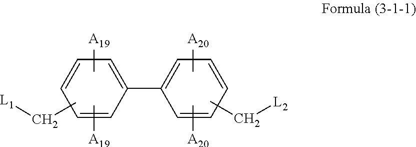

in Formula (3-1-1), A₁₉ and A₂₀ independently represent a hydrogen atom, a halogen atom, a C₁-C₈ alkyl group or a C₆-C₁₅ aryl group; L₁ and L₂ independently represent a halogen atom, a C₁-C₆ alkyl group, or a C₁-C₆ alkoxy group. The alkyl group is preferably a methyl group, an ethyl group, or tertiary butyl. The alkoxy group is preferably a methoxy group or an ethoxy group.

Examples of the aforementioned phenol include but are not limited to phenol, cresol, ethylphenol, n-propylphenol, isobutylphenol, t-butylphenol, octylphenol, nonylphenol, xylenol, methylbutylphenol, di-t-butylphenol, vinylphenol, propenylphenol, ethinylphenol, cyclopentylphenol, cyclohexylphenol, cyclohexylcresol, or a similar compound thereof. The phenol may be used alone or in any combination.

Based on 1 mole of the used amount of the aforementioned compound represented by Formula (3-1-1), the used amount of phenol is 0.5 moles to 20 moles, and preferably 2 moles to 15 moles.

Examples of the acid catalyst include but are not limited to hydrochloric acid, sulfuric acid, p-toluenesulfonic acid, oxalic acid, boron trifluoride, aluminium chloride anhydrous, zinc chloride, or a similar compound thereof. The acid catalyst may be used alone or in any combination.

The acid catalyst is preferably p-toluenesulfonic acid, sulfuric acid, hydrochloric acid, or any combination of the above-mentioned compounds.

The used amount of the acid catalyst is not particularly limited. Based on 100 percentages by weight of the compound represented by Formula (3-1-1), the used amount of the acid catalyst is 0.1 percentages by weight to 30 percentages by weight.

The condensation reaction may be conducted without a solvent or under the existence of an organic solvent. Examples of the organic solvent include toluene, xylene, methyl isobutyl ketone, or a similar compound thereof. The organic solvent may be used alone or in any combination.

Based on 100 percentages by weight of the total used amount of the compound represented by Formula (3-1-1) and the phenol, the used amount of the organic solvent is 50 percentages by weight to 300 percentages by weight; preferably 100 percentages by weight to 250 percentages by weight.

The reaction temperature of the condensation reaction is 40° C. to 180° C. and the reaction time of the condensation reaction is 1 hour to 8 hour.

After the condensation reaction is completed, a neutralization treatment or a rinse treatment may be optionally conducted.

In the neutralization treatment, the pH value of the reacted solution is adjusted to pH 3 to pH 7, and preferably pH 5 to pH 7.

The rinse treatment may be conducted by using a neutralizer, wherein the neutralizer is an alkaline substance, and examples thereof include but are not limited to ammonia, sodium dihydrogen phosphate; alkali metal hydroxides such as sodium hydroxide, potassium hydroxide, etc.; alkaline earth metal hydroxides such as calcium hydroxide, magnesium hydroxide, etc.; organic amines such as diethylene triamine, triethylenetetramine, aniline, phenylene diamine, etc.; or any combination of the above-mentioned compounds. The neutralizing agent may be used alone or in any combination.

The rinse treatment may be conducted with a known method, such as adding an aqueous solution containing a neutralizer in the reacted solution and then extracting repeatedly. After the neutralization treatment or the rinse treatment, the unreacted phenol and solvent may be distilled off through a heat treatment under reduced pressure, and then condensation is conducted to obtain the compound having the structure of Formula (3-1).

Then, an excessive amount of epihalohydrin is added to proceed dehydrohalogenation on the epihalohydrin and the compound having the structure of Formula (3-1), so as to obtain the compound having the structure represented by Formula (3).

Examples of the epihalohydrin include but are not limited to epichlorohydrin (3-chloro-1,2-epoxypropane), epibromohydrin (3-bromo-1,2-epoxypropane), or a combination of the above-mentioned compounds.

Before the dehydrohalogenation reaction is conducted, an alkali metal hydroxide such as sodium hydroxide and potassium hydroxide may be pre-added or added during the reaction process. The reaction temperature of the dehydrohalogenation reaction is 20° C. to 120° C. and the reaction time thereof is 1 hour to 10 hours.

In an embodiment, the alkali metal hydroxide added in the dehydrohalogenation reaction may also be an aqueous solution thereof. In this embodiment, when the aqueous solution of alkali metal hydroxide is continuously added in the dehydrohalogenation reaction system, water and epihalohydrin may be continuously distilled under reduced pressure or normal pressure to separate and remove water, and epihalohydrin may be continuously flown back to the reaction system.

Before the dehydrohalogenation reaction is conducted, a quaternary ammonium salt such as tetramethyl ammonium chloride, tetramethyl ammonium bromide, trimethyl benzyl ammonium chloride, etc., may also be added as a catalyst, and then an alkali metal hydroxide or an aqueous solution thereof is added after reacting for 1 hour to 5 hours at 50° C. to 150° C. Then, the mixture is reacted for 1 hour to 10 hours at 20° C. to 120° C. to proceed the dehydrohalogenation reaction.

Based on the total hydroxyl groups in the compound represented by Formula (3-1) as 1 equivalent, the used amount of the epihalohydrin is 1 equivalent to 20 equivalents; preferably 2 equivalents to 10 equivalents. Based on the total hydroxyl groups in the compound represented by Formula (3-1) as 1 equivalent, the used amount of the alkali metal hydroxide added in the dehydrohalogenation is 0.5 equivalents to 15 equivalents; preferably 0.9 equivalents to 11 equivalents.

To proceed the dehydrohalogenation reaction smoothly, an alcohol such as methanol, ethanol, or a similar compound thereof may also be added into the reaction system. In addition, an aprotic polar solvent such as dimethyl sulfone or dimethyl sulfoxide may also be added to into the reaction system.

When alcohol is used, based on 100 percentages by weight of the used amount of the epihalohydrin, the used amount of the alcohol is 2 percentages by weight to 20 percentages by weight; preferably 4 percentages by weight to 15 percentages by weight. When an aprotic polar solvent is used, based on 100 percentages by weight of the used amount of the epihalohydrin, the used amount of the polar aprotic solvent is 5 percentages by weight to 100 percentages by weight; preferably 10 percentages by weight to 90 percentages by weight.

After the above-mentioned dehydrohalogenation reaction is completed, a rinse treatment may be optionally conducted. Then, the epihalohydrin, the phenol, and the aprotic polar solvent are removed by using a method of heating at a temperature of 110° C. to 250° C. and at a pressure lower than 1.3 kPa (10 mmHg).

To prevent the epoxy resin formed from containing a hydrolyzable halogen, the solution after the dehydrohalogenation reaction may be added in a solvent such as toluene and methyl isobutyl ketone and an aqueous alkali metal hydroxide such as sodium hydroxide and potassium hydroxide, and then the dehydrohalogenation reaction is conducted again. In this dehydrohalogenation reaction, based on the total hydroxyl groups in the compound represented by Formula (3-1) as 1 equivalent, the used amount of the alkali metal hydroxide added in the dehydrohalogenation is 0.01 moles to 0.3 moles; preferably 0.05 moles to 0.2 moles. Moreover, the range of the reaction temperature of the dehydrohalogenation reaction is 50° C. to 120° C. and the range of the reaction time thereof is 0.5 hours to 2 hours.

After the dehydrohalogenation reaction is completed, the salts are removed through steps such as filtering and rinsing. Moreover, solvents such as toluene and methyl isobutyl ketone may be distilled off through a method of heating under reduced pressure to obtain the compound (a-1-1) having the structure represented by Formula (3). Examples of the compound having the structure represented by Formula (3) include but are not limited to products such as NC-3000, NC-3000H, NC-3000S, or NC-3000P made by Nippon Kayaku Co., Ltd.

The compound (a-1-2) containing at least one carboxylic acid group and at least one ethylenically unsaturated group may be selected from one of the following groups (1) to (3): (1) acrylate, methacrylate, 2-methacryloyloxyethylbutanedioic acid, 2-methacryloyloxybutylbutanedioic acid, 2-methacryloyloxyethylhexanedioic acid, 2-methacryloyloxybutylhexanedioic acid, 2-methacryloyloxyethylhexahydrophthalic acid, 2-methacryloyloxyethyl maleic acid, 2-methacryloyloxypropylmaleic acid, 2-methacryloyloxybutylmaleic acid, 2-methacryloyloxypropylbutanedioic acid, 2-methacryloyloxypropylhexane dioic acid, 2-methacryloyloxypropyltetrahydrophthalic acid, 2-methacryloyloxy propylphthalic acid, 2-methacryloyloxybutylphthalic acid, 2-methacryloyloxy butylhydrophthalic acid, or a similar compound thereof; (2) a compound obtained by reacting (meth)acrylate having a hydroxyl group and a dicarboxylic acid compound, wherein examples of the dicarboxylic acid compound include hexanedioic acid, butanedioic acid, maleic acid, phthalic acid, or a similar compound thereof; (3) a half ester compound obtained by reacting (meth)acrylate having a hydroxyl group and the carboxylic acid anhydride compound (a-1-3), wherein examples of the (meth)acrylate having the hydroxyl group include (2-hydroxyethyl)acrylate, (2-hydroxyethyl)methacrylate, (2-hydroxypropyl)acrylate, (2-hydroxypropyl)methacrylate, (4-hydroxybutyl)acrylate, (4-hydroxybutyl)methacrylate, pentaerythritol trimethacrylate, or a similar compound thereof. Besides, the carboxylic acid anhydride compound may be the same as the following contents, and is therefore not repeated herein.

The carboxylic acid anhydride compound (a-1-3) may be selected from dicarboxylic acid anhydride compound, tetracarboxylic acid anhydride compounds, or any combination of the above-mentioned compounds.

The above-mentioned dicarboxylic acid anhydride compounds include but are not limited to, butanedioic anhydride, maleic anhydride, itaconic anhydride, phthalic anhydride, tetrahydrophthalic anhydride, hexahydrophthalic anhydride, methyl tetrahydrophthalic anhydride, methyl hexahydrophthalic anhydride, methyl endo-methylene tetrahydrophthalic anhydride, chlorendic anhydride, glutaric anhydride, 1,3-dioxoisobenzofuran-5-carboxylic acid anhydride, or a similar compound thereof.

The above-mentioned tetracarboxylic acid anhydride compounds include but are not limited to, benzophenone tetracarboxylic dianhydride (BTDA), dibenzenetetracarboxylic dianhydride, diphenyl ether tetracarboxylic dianhydride, or a similar compound thereof.

Examples of the compound (a-1-4) having the epoxy group include glycidyl methacrylate, 3,4-epoxycyclohexyl methacrylate, a glycidyl ether compound having an unsaturated group, an unsaturated compound having an epoxy group, or a combination of the above-mentioned compounds.

Examples of the glycidyl ether compound having the unsaturated group include Denacol EX-111, Denacol EX-121, Denacol EX-141, Denacol EX-145, Denacol EX-146, Denacol EX-171, or Denacol EX-192 (products of Nagase ChemteX Corporation).

The resin (A-1) having the unsaturated group may be obtained by polymerizing the epoxy compound (a-1-1) containing at least two epoxy groups having the structure represented by Formula (2) and the compound (a-1-2) containing at least one carboxylic acid group and at least one ethylenically unsaturated group to form a reaction product having a hydroxyl group, followed by adding the carboxylic acid anhydride compound (a-1-3) to proceed a reaction. Based on the total amount of the hydroxyl group as 1 equivalent, the used amount of the carboxylic acid anhydride compound (a-1-3) is preferably from 0.4 to 1 equivalent, and more preferably 0.75 to 1 equivalent. When a plurality of the carboxylic acid anhydride compounds (a-1-3) are used, the plurality of carboxylic acid anhydride compounds (a-1-3) may be added in the reaction in sequence or at the same time. When the carboxylic acid anhydride compound (a-1-3) includes the dicarboxylic acid anhydride compound and the tetracarboxylic acid anhydride compound, the molar ratio of the dicarboxylic acid anhydride compound to the tetracarboxylic acid anhydride compound is 1/99 to 90/10, and preferably 5/95 to 80/20. The range of the reaction temperature is 50° C. to 130° C.

In other embodiment of the invention, the resin (A-1) having the unsaturated group may be obtained by reacting the epoxy compound (a-1-1) containing at least two epoxy groups and containing the structure represented by Formula (3) and the compound (a-1-2) containing at least one carboxylic acid group and at least one ethylenically unsaturated group to form a reaction product having a hydroxyl group, followed by adding the carboxylic acid anhydride compound (a-1-3) and/or the compound (a-1-4) having the epoxy group to proceed a polymerization reaction. Based on the total amount of the epoxy groups of the epoxy compound (a-1-1) containing at least two epoxy groups represented by Formula (3) as 1 equivalent, the used amount of the compound (a-1-2) containing at least one carboxylic acid group and at least one ethylenically unsaturated group is from 0.8 to 1.5 equivalent, and preferably 0.9 to 1.1 equivalent. Based on the total hydroxyl groups of the intermediate product containing the hydroxyl group as 100 percentage by mole (mole %), the used amount of the carboxylic acid anhydride compound (a-1-3) is from 10 to 100 mole %, preferably 20 to 100 mole %, and more preferably 30 to 100 mole %.

When preparing the resin (A-1) having the unsaturated group, to speed up the reaction, an alkali compound is generally added in the reaction solution as a reaction catalyst. Examples of the reaction catalyst include but are not limited to triphenyl phosphine, triphenyl stibine, triethylamine, triethanolamine, tetramethylammonium chloride, or benzyltriethylammonium chloride, etc. The reaction catalyst may be used alone or in any combination.

Based on 100 parts by weight of the total used amount of the epoxy compound (a-1-1) containing at least two epoxy groups and the compound (a-1-2) containing at least one carboxylic acid group and at least one ethylenically unsaturated group, the used amount of the reaction catalyst is from 0.01 to 10 parts by weight, and preferably 0.3 to 5 parts by weight.

Moreover, to control the degree of polymerization, an inhibitor is generally added in the reaction solution. Examples of the inhibitor include but are not limited to methoxyphenol, methylhydroquinone, hydroquinone, 2,6-di-t-butyl-p-cresol, phenothiazine, or a similar compound thereof. The inhibitor may be used alone or in any combination.

Based on 100 parts by weight of the total used amount of the epoxy compound (a-1-1) containing at least two epoxy groups and the compound (a-1-2) containing at least one carboxylic acid group and at least one ethylenically unsaturated group, the used amount of the polymerization inhibitor is from 0.01 to 10 parts by weight, and preferably 0.1 to 5 parts by weight.

When preparing the resin (A-1) having the unsaturated group, a polymerization reaction solvent may be added into the reaction solution. Examples of the polymerization reaction solvent include but are not limited to alcohol compounds such as ethanol, propanol, isopropanol, butanol, isobutanol, 2-butanol, hexanol, ethylene glycol, or a similar compound thereof; ketone compounds such as methyl ethyl ketone, cyclohexanone, or a similar compound thereof; aromatic hydrocarbon compounds such as toluene, xylene, or a similar compound thereof; cellosolve compounds such as cellosolve, butyl cellosolve, or a similar compound thereof; carbitol compounds such as carbitol, butyl carbitol, or a similar compound thereof; propylene glycol alkyl ether compounds such as propylene glycol monomethyl ether or a similar compound thereof; poly(propylene glycol)alkyl ether compounds such as di(propylene glycol) methyl ether or a similar compound thereof; acetic acid ester compounds such as ethyl acetate, butyl acetate, ethylene glycol monoethyl ether acetate, propylene glycol monomethyl ether acetate, or a similar compound thereof; alkyl lactate compounds such as ethyl lactate, butyl lactate, or a similar compound thereof; or dialkyl glycol ethers. The polymerization reaction solvent may be used alone or in any combination.

The acid value of the resin (A-1) having the unsaturated group according to the present invention is 50 mgKOH/g to 150 mgKOH/g.

Based on 100 parts by weight of the used amount of the alkali-soluble resin (A), the used amount of the resin (A-1) having the unsaturated group is from 30 parts by weight to 100 parts by weight, preferably from 35 parts by weight to 95 parts by weight, and more preferably from 40 parts by weight to 90 parts by weight.

If the resin (A-1) having the unsaturated group is absent from the alkali-soluble resin (A), the photosensitive resin composition has poor linearity of pattern with high finesse.

The other alkali-soluble resin (A-2) according to the invention includes but is not limited to resins having a carboxylic group or a hydroxyl group. Examples of the other alkali-soluble resin (A-2) includes alkali-soluble resins other than the resin (A-1) having the unsaturated group such as acrylic-based resin, urethane-based resin, or novolac resin, etc.

Based on 100 parts by weight of the used amount of the alkali-soluble resin (A), the used amount of the other alkali-soluble resin (A-2) is from 0 part by weight to 70 parts by weight, preferably from 5 parts by weight to 65 parts by weight, and more preferably from 10 parts by weight to 60 parts by weight.

The compound (B) containing the ethylenically unsaturated group may include a compound (B-1) having one ethylenically unsaturated group or a compound (B-2) having at least two (including two)ethylenically unsaturated groups.

Examples of the compound (B-1) having one ethylenically unsaturated group include but are not limited to (meth)acrylamide, (meth)acryloylmorpholine, 7-amino-3,7-dimethyloctyl(meth)acrylate, isobutoxymethyl(meth)acrylamide, isobornyloxyethyl(meth)acrylate, isobornyl(meth)acrylate, 2-ethylhexyl(meth)acrylate, ethyl diethylene glycol(meth)acrylate, t-octyl(meth)acrylamide, diacetone(meth)acrylamide, dimethylaminoethyl(meth)acrylate, dodecyl(meth)acrylate, dicyclopentenyloxyethyl(meth)acrylate, dicyclopentenyl(meth)acrylate, N,N-dimethyl(meth)acrylamide, tetrachlorophenyl(meth)acrylate, 2-tetrachlorophenoxy ethyl(meth)acrylate, tetrahydrofurfuryl(meth)acrylate, tetrabromophenyl(meth)acrylate, 2-tetrabromophenoxyethyl(meth)acrylate, 2-trichlorophenoxyethyl(meth)acrylate, tribromophenyl(meth)acrylate, 2-tribromophenoxyethyl(meth)acrylate, 2-hydroxyethyl(meth)acrylate, 2-hydroxypropyl(meth)acrylate, vinylcaprolactam, N-vinylpyrrolidone, phenoxyethyl(meth)acrylate, pentachlorophenyl(meth)acrylate, pentabromophenyl(meth)acrylate, polyethylene glycol mono(meth)acrylate, polypropylene glycol mono(meth)acrylate, or bornyl(meth)acrylate. The compound (B-1) having one ethylenically unsaturated group may be used alone or in any combination.

Examples of the compound (B-2) having at least two (including two) ethylenically unsaturated groups include but are not limited to ethylene glycol di(meth)acrylate, dicyclopentenyl di(meth)acrylate, triethylene glycol di(meth)acrylate, tetraethylene glycol di(meth)acrylate, tri(2-hydroxyethyl)isocyanate di(meth)acrylate, tri(2-hydroxyethyl)isocyanate tri(meth)acrylate, caprolactone-modified tri(2-hydroxyethyl)isocyanate tri(meth)acrylate, trimethylolpropyl tri(meth)acrylate, ethylene oxide (EO) modified trimethylolpropyl tri(meth)acrylate, propylene oxide (PO) modified trimethylolpropyl tri(meth)acrylate, tripropylene glycol di(meth)acrylate, neo-pentyl glycol di(meth)acrylate, 1,4-butanediol di(meth)acrylate, 1,6-hexanediol di(meth)acrylate, pentaerythritol tri(meth)acrylate, pentaerythritol tetra(meth)acrylate, polyester di(meth)acrylate, polyethylene glycol di(meth)acrylate, dipentaerythritol hexa(meth)acrylate, dipentaerythritol penta(meth)acrylate, dipentaerythritol tetra(meth)acrylate, caprolactone-modified dipentaerythritol hexa(meth)acrylate, caprolactone-modified dipentaerythritol penta(meth)acrylate, di(trimethylolpropyl)tetra(meth)acrylate, EO-modified bisphenol A di(meth)acrylate, PO-modified bisphenol A di(meth)acrylate, EO-modified hydrogenated bisphenol A di(meth)acrylate, PO-modified hydrogenated bisphenol A di(meth)acrylate, PO-modified glycerol tri(meth)acrylate, EO-modified bisphenol F di(meth)acrylate, polyglycidyl(meth)acrylate of novolac resin, or any combination of the above-mentioned compounds. The compound (B-2) having at least two (including two) ethylenically unsaturated groups may be used alone or in any combination.

Examples of the compound (B) containing the ethylenically unsaturated group include but are not limited to trimethylolpropyl triacrylate, EO-modified trimethylolpropyl triacrylate, PO-modified trimethylolpropyl triacrylate, pentaerythritol triacrylate, pentaerythritol tetraacrylate, dipentaerythritol hexaacrylate, dipentaerythritol pentaacrylate, dipentaerythritol tetraacrylate, caprolactone-modified dipentaerythritol hexaacrylate, di(trimethylolpropyl)tetraacrylate, PO-modified glycerol triacrylate, or any combination of the above-mentioned compounds.

The compound (B) containing the ethylenically unsaturated group is preferably trimethylolpropyl triacrylate, dipentaerythritol tetracrylate, dipentaerythritol hexaacrylate, or any combination of the above-mentioned compounds.

Based on 100 parts by weight of the used amount of the alkali-soluble resin (A), the used amount of the compound (B) containing the ethylenically unsaturated group is from 20 parts by weight to 200 parts by weight, preferably from 25 parts by weight to 180 parts by weight, and more preferably from 30 parts by weight to 150 parts by weight.

The photoinitiator (C) according to the invention comprises a photoinitiator (C-1) represented by Formula (4):

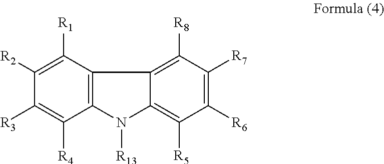

wherein in Formula (4), R₁, R₂, R₃, R₄, R₅, R₆, R₇ and R₈ are independently hydrogen, C₁-C₂₀ alkyl,

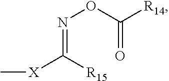

COR₁₆, OR₁₇, halogen, NO₂ or

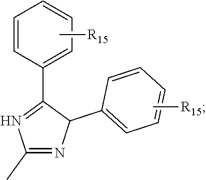

or R₁ and R₂, R₂ and R₃, R₃ and R₄, R₅ and R₆, R₆ and R₇, or R₇ and R₈ are independently C₂-C₁₀ alkenyl which is substituted by

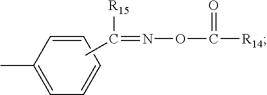

or R₁ and R₂, R₂ and R₃, R₃ and R₄, R₅ and R₆, R₆ and R₇, or R₇ and R₈ are together independently —(CH₂)ₚ—Y—(CH₂)_{q}—; or
R₁ and R₂, R₂ and R₃, R₃ and R₄, R₅ and R₆, R₆ and R₇, or R₇ and R₈ are together independently

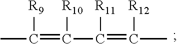

and
provided that R₁ and R₂, R₂ and R₃, R₃ and R₄, R₅ and R₆, R₆ and R₇, R₇ and R₈, or any combination thereof, is

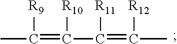

R₉, R₁₀, R₁₁ and R₁₂ are independently hydrogen, C₁-C₂₀ alkyl which is unsubstituted or substituted by one or more halogen, phenyl, CN, OH, SH, C₁-C₄-alkoxy, (CO)OH or any combination thereof, or (CO)O(C₁-C₄ alkyl); or
R₉, R₁₀, R₁₁ and R₁₂ are independently unsubstituted phenyl or phenyl substituted by one or more C₁-C₆ alkyl, halogen, CN, OR₁₇, SR₁₈, or any combination thereof, or by NR₁₉R₂₀; or
R₉, R₁₀, R₁₁, and R₁₂ are independently halogen, CN, OR₁₇, SR₁₈, SOR₁₈, SO₂R₁₈, or NR₁₉R₂₀, wherein OR₁₇, SR₁₈, or NR₁₉R₂₀ optionally comprises a 5-membered ring or 6-membered ring via radicals R₁₇, R₁₈, R₁₉, R₂₀, or any combination thereof, with one of carbon atoms of a naphthyl ring; or

R₉, R₁₀, R₁₁, and R₁₂ are independently

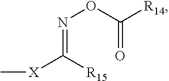

COR₁₆ or NO₂;
Y is O, S, NR₂₆ or a direct bond;
p is an integer 0, 1, 2 or 3;
q is an integer 1, 2 or 3;
X is CO or a direct bond; R₁₃ is C₁-C₂₀ alkyl which is unsubstituted or substituted by one or more halogen, R₁₇, COOR₁₇, OR₁₇, SR₁₈, CONR₁₉R₂₀, NR₁₉R₂₀, PO(OCₖH₂ₖ₊₁)₂, or any combination thereof, or by

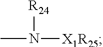

or
R₁₃ is C₂-C₂₀ alkyl which is interrupted by one or more O, S, SO, SO₂, NR₂₆, CO, or any combination thereof; or
R₁₃ is C₂-C₁₂ alkenyl which is uninterrupted or is interrupted by one or more O, CO, NR₂₆, or any combination thereof, wherein the interrupted C₂-C₂₀ alkyl and the uninterrupted or interrupted C₂-C₁₂ alkenyl are unsubstituted or substituted by one or more halogen; or
R₁₃ is C₄-C₈ cycloalkenyl, C₂-C₁₂ alkynyl, or C₃-C₁₀ cycloalkyl which is uninterrupted or interrupted by one or more O, S, CO, NR₂₆, or any combination thereof; or
R₁₃ is phenyl or naphthyl, each of which is unsubstituted or substituted by one or more OR₁₇, SR₁₈, NR₁₉R₂₀,

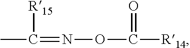

COR₁₆, CN, NO₂, halogen, C₁-C₂₀ alkyl, C₁-C₄ haloalkyl, C₂-C₂₀ alkyl, or any combination thereof, which is interrupted by one or more O, S, CO, NR₂₆, or any combination thereof, or each of which is substituted by C₃-C₁₀ cycloalkyl or by C₃-C₁₀ cycloalkyl which is interrupted by one or more O, S, CO, NR₂₆, or any combination thereof;
k is an integer 1 to 10;
R₁₄ is hydrogen, C₃-C₈ cycloalkyl, C₂-C₈ alkenyl, C₁-C₂₀ alkoxy, or C₁-C₂₀ alkyl which is unsubstituted or substituted by one or more halogen, phenyl, C₁-C₂₀ alkylphenyl, CN, or any combination thereof; or
R₁₄ is phenyl or naphthyl, each of which is unsubstituted or substituted by one or more C₁-C₆ alkyl, C₁-C₄ haloalkyl, halogen, CN, OR₁₇, SR₁₈, NR₁₉R₂₀, or any combination thereof; or
R₁₄ is C₃-C₂₀ heteroaryl, C₁-C₈ alkoxy, benzyloxy or phenoxy, which benzyloxy and phenoxy are unsubstituted or substituted by one or more C₁-C₆ alkyl, C₁-C₄ haloalkyl, halogen, or any combination thereof;
R₁₅ is C₆-C₂₀ aryl or C₃-C₂₀ heteroaryl each of which is unsubstituted or substituted by one or more phenyl, halogen, C₁-C₄ haloalkyl, CN, NO₂, OR₁₇, SR₁₈, NR₁₉R₂₀, PO(OCₖH₂ₖ₊₁)₂, SO—C₁-C₁₀ alkyl, SO₂—C₁-C₁₀ alkyl, or any combination thereof, by C₂-C₂₀ alkyl which is interrupted by one or more O, S, NR₂₆, or any combination thereof, or each of which is substituted by C₁-C₂₀ alkyl which is unsubstituted or substituted by one or more halogen, COOR₁₇, CONR₁₉R₂₀, phenyl, C₃-C₈ cycloalkyl, C₃-C₂₀ heteroaryl, C₆-C₂₀ aryloxycarbonyl, C₃-C₂₀ heteroaryloxycarbonyl, OR₁₇, SR₁₈, NR₁₉R₂₀, or any combination thereof; or
R₁₅ is hydrogen, C₂-C₁₂ alkenyl, C₃-C₈ cycloalkyl which is uninterrupted or is interrupted by one or more O, CO, NR₂₆, or any combination thereof; or
R₁₅ is C₁-C₂₀ alkyl which is unsubstituted or substituted by one or more halogen, OR₁₇, SR₁₈, C₃-C₈ cycloalkyl, C₃-C₂₀ heteroaryl, C₆-C₂₀ aryloxycarbonyl, C₃-C₂₀ heteroaryloxycarbonyl, NR₁₉R₂₀, COOR₁₇, CONR₁₉R₂₀, PO(OCₖH₂ₖ₊₁)₂,

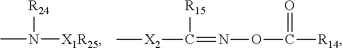

phenyl, or any combination thereof, or the C₁-C₂₀ alkyl is substituted by phenyl which is substituted by halogen, C₁-C₂₀ alkyl, C₁-C₄ haloalkyl, OR₁₇, SR₁₈, or NR₁₉R₂₀; or
R₁₅ is C₂-C₂₀ alkyl which is interrupted by one or more O, SO, SO₂, or any combination thereof, and which interrupted C₂-C₂₀ alkyl is unsubstituted or substituted by one or more halogen, OR₁₇, COOR₁₇, CONR₁₉R₂₀, phenyl or by phenyl which is substituted by OR₁₇, SR₁₈, or NR₁₉R₂₀; or
R₁₅ is C₂-C₂₀ alkanoyl, or benzoyl which is unsubstituted or substituted by one or more C₁-C₆ alkyl, halogen, phenyl, OR₁₇, SR₁₈, NR₁₉R₂₀, or any combination thereof; or
R₁₅ is naphthoyl which is unsubstituted or is substituted by one or more OR₁₇ or is C₃-C₁₄ heteroarylcarbonyl; or
R₁₅ is C₂-C₁₂ alkoxycarbonyl which is uninterrupted or is interrupted by one or more O and which interrupted or uninterrupted C₂-C₁₂ alkoxycarbonyl is unsubstituted or substituted by one or more hydroxyl group; or
R₁₅ is phenoxycarbonyl which is unsubstituted or substituted by one or more C₁-C₆ alkyl, halogen, C₁-C₄ haloalkyl, phenyl, OR₁₇, SR₁₈, NR₁₉R₂₀, or any combination thereof; or
R₁₅ is CN, CONR₁₉R₂₀, NO₂, C₁-C₄ haloalkyl, S(O)ₘ—C₁-C₆ alkyl; S(O)ₘ-phenyl which is unsubstituted or substituted by C₁-C₁₂ alkyl or SO₂—C₁-C₆ alkyl; or
R₁₅ is SO₂O-phenyl which is unsubstituted or substituted by C₁-C₁₂ alkyl; or R₁₅ is diphenyl phosphinoyl or di-(C₁-C₄ alkoxy)-phosphinoyl;
m is 1 or 2;
R′₁₄ has one of the meanings as given for R₁₄;
R′₁₅ has one of the meanings as given for R₁₅;
X₁ is O, S, SO, or SO₂;
X₂ is O, CO, S, or a direct bond;
R₁₆ is C₆-C₂₀ aryl or C₃-C₂₀ heteroaryl each of which is unsubstituted or substituted by one or more phenyl, halogen, C₁-C₄ haloalkyl, CN, NO₂, OR₁₇, SR₁₈, NR₁₉R₂₀, or any combination thereof, or by C₁-C₂₀ alkyl which is interrupted by one or more O, S, or NR₂₆, or any combination thereof, each of which is substituted by one or more C₁-C₂₀ alkyl which is unsubstituted or substituted by one or more halogen, COOR₁₇, CONR₁₉R₂₀, phenyl, C₃-C₈ cycloalkyl, C₃-C₂₀ heteroaryl, C₆-C₂₀ aryloxycarbonyl, C₃-C₂₀ heteroaryloxycarbonyl, OR₁₇, SR₁₈, NR₁₉R₂₀, or any combination thereof; or
R₁₆ is hydrogen, C₁-C₂₀ alkyl which is unsubstituted or substituted by one or more halogen, phenyl, OH, SH, CN, C₃-C₆ alkenoxy, OCH₂CH₂CN, OCH₂CH₂(CO)O(C₁-C₄ alkyl), O(CO)—(C₁-C₄ alkyl), O(CO)-phenyl, (CO)OH, (CO)O(C₁-C₄ alkyl), or any combination thereof; or
R₁₆ is C₂-C₁₂ alkyl which is interrupted by one or more O, S, NR₂₆, or any combination thereof; or
R₁₆ is (CH₂CH₂O)ₙ₊₁H, (CH₂CH₂O)ₙ(CO)—(C₁-C₈ alkyl), C₂-C₁₂ alkenyl, or C₃-C₈ cycloalkyl; or
R₁₆ is phenyl substituted by SR₁₈ wherein radical R₁₈ denotes a direct bond to a phenyl or naphthyl ring of a carbazole moiety to which a COR₁₆ group is attached;
n is 1 to 20;
R₁₇ is hydrogen, phenyl-C₁-C₃ alkyl, C₁-C₂₀ alkyl which is unsubstituted or substituted by one or more halogen, OH, SH, CN, C₃-C₆ alkenoxy, OCH₂CH₂CN, OCH₂CH₂(CO)O(C₁-C₄ alkyl), O(CO)—(C₁-C₄ alkyl), O(CO)—(C₂-C₄)alkenyl, O(CO)-phenyl, (CO)OH, (CO)O(C₁-C₄ alkyl), C₃-C₂₀ cycloalkyl, SO₂—(C₁-C₄ haloalkyl), O(C₁-C₄ haloalkyl), or any combination thereof, or by C₃-C₂₀ cycloalkyl which is interrupted by one or more O; or
R₁₇ is C₂-C₂₀ alkyl which is interrupted by one or more O, S, NR₂₆, or any combination thereof; or
R₁₇ is (CH₂CH₂O)ₙ₊₁H, (CH₂CH₂O)ₙ(CO)—(C₁-C₈ alkyl), C₁-C₈ alkanoyl, C₂-C₁₂ alkenyl, C₃-C₆ alkenoyl, or C₃-C₂₀ cycloalkyl which is uninterrupted or interrupted by one or more O, S, CO, NR₂₆, or any combination thereof; or
R₁₇ is C₁-C₈ alkyl-C₃-C₁₀ cycloalkyl which is uninterrupted or interrupted by one or more O; or
R₁₇ is benzoyl which is unsubstituted or substituted by one or more C₁-C₆ alkyl, halogen, OH, C₁-C₃ alkoxy, or any combination thereof; or
R₁₇ is phenyl, naphthyl, or C₃-C₂₀ heteroaryl, each of which is unsubstituted or substituted by one or more halogen, OH, C₁-C₁₂ alkyl, C₁-C₁₂ alkoxy, CN, NO₂, phenyl-C₁-C₃ alkyloxy, phenoxy, C₁-C₁₂ alkylsulfanyl, phenylsulfanyl, N(C₁-C₁₂ alkyl)₂, diphenylamino,

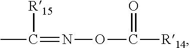

or any combination thereof; or
R₁₇ comprises a direct bond to one of carbon atoms of phenyl or naphthyl ring on which

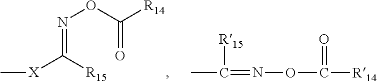

is located;
R₁₈ is hydrogen, C₂-C₁₂ alkenyl, C₃-C₂₀ cycloalkyl, or phenyl-C₁-C₃ alkyl, wherein the C₂-C₁₂ alkenyl, C₃-C₂₀ cycloalkyl, or phenyl-C₁-C₃ alkyl is uninterrupted or interrupted by one or more O, S, CO, NR₂₆, COOR₁₇, or any combination thereof; or
R₁₈ is C₁-C₂₀ alkyl which is unsubstituted or is substituted by one or more OH, SH, CN, C₃-C₆ alkenoxy, OCH₂CH₂CN, OCH₂CH₂(CO)O(C₁-C₄ alkyl), O(CO)—(C₂-C₄)alkenyl, O(CO)—(C₁-C₄ alkyl), O(CO)-phenyl, (CO)OR₁₇, or any combination thereof; or
R₁₈ is C₂-C₂₀ alkyl which is interrupted by one or more O, S, CO, NR₂₆, COOR₁₇, or any combination thereof; or
R₁₈ is (CH₂CH₂O)ₙH, (CH₂CH₂O)ₙ(CO)—(C₁-C₈ alkyl), C₂-C₈ alkanoyl, or C₃-C₆ alkenoyl; or
R₁₈ is benzoyl which is unsubstituted or substituted by one or more C₁-C₆ alkyl, halogen, OH, C₁-C₄ alkoxy, C₁-C₄ alkylsulfanyl, or any combination thereof; or
R₁₈ is phenyl, naphthyl, or C₃-C₂₀ heteroaryl, each of which is unsubstituted or substituted by one or more halogen, C₁-C₁₂ alkyl, C₁-C₄ haloalkyl, C₁-C₁₂ alkoxy, CN, NO₂, phenyl-C₁-C₃ alkyloxy, phenoxy, C₁-C₁₂ alkylsulfanyl, phenylsulfanyl, N(C₁-C₁₂ alkyl)₂, diphenylamino, (CO)O(C₁-C₈ alkyl), (CO)—C₁-C₈ alkyl, (CO)N(C₁-C₈ alkyl)₂,

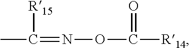

or any combination thereof;
R₁₉ and R₂₀ are independently hydrogen, C₁-C₂₀ alkyl, C₂-C₄ hydroxyalkyl, C₂-C₁₀ alkoxyalkyl, C₂-C₅ alkenyl, C₃-C₂₀ cycloalkyl, phenyl-C₁-C₃ alkyl, C₁-C₈ alkanoyl, C₁-C₈ alkanoyloxy, C₃-C₁₂ alkenoyl SO₂—(C₁-C₄ haloalkyl), or benzoyl; or
R₁₉ and R₂₀ are phenyl, naphthyl, or C₃-C₂₀ heteroaryl, each of which is unsubstituted or substituted by one or more halogen, C₁-C₄ haloalkyl, C₁-C₂₀ alkoxy, C₁-C₁₂ alkyl, benzoyl, C₁-C₁₂ alkoxy, or any combination thereof; or
R₁₉ and R₂₀ together with the N-atom to which they are attached comprise a 5- or 6-membered saturated or unsaturated ring which is uninterrupted or is interrupted by O, S, or NR₁₇, and which is unsubstituted or substituted by one or more C₁-C₂₀ alkyl, C₁-C₂₀ alkoxy, ═O, OR₁₇, SR₁₈, NR₂₁R₂₂, (CO)R₂₃, NO₂, halogen, C₁-C₄-haloalkyl, CN, phenyl,

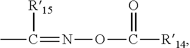

or any combination thereof, or by C₃-C₂₀ cycloalkyl which is uninterrupted or is interrupted by one or more O, S, CO, NR₁₇, or any combination thereof; or
R₁₉ and R₂₀ together with the N-atom to which they are attached comprise a heteroaromatic ring system which is unsubstituted or substituted by one or more C₁-C₂₀ alkyl, C₁-C₄ haloalkyl, C₁-C₂₀ alkoxy, ═O, OR₁₇, SR₁₈, NR₂₁R₂₂, (CO)R₂₃,

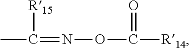

halogen, NO₂, CN, phenyl, or any combination thereof, or by C₃-C₂₀ cycloalkyl which is uninterrupted or is interrupted by one or more O, S, CO, NR₁₇, or any combination thereof;
R₂₁ and R₂₂ are independently hydrogen, C₁-C₂₀ alkyl, C₁-C₄ haloalkyl, C₃-C₁₀ cycloalkyl, or phenyl; or
R₂₁ and R₂₂ together with the N-atom to which they are attached comprise a 5- or 6-membered saturated or unsaturated ring, which is uninterrupted or is interrupted by O, S, or NR₂₆, and which 5- or 6-membered saturated or unsaturated ring is not condensed or to which 5- or 6-membered saturated or unsaturated ring a benzene ring is condensed;
R₂₃ is hydrogen, OH, C₁-C₂₀ alkyl, C₁-C₄ haloalkyl, C₂-C₂₀ alkyl which is interrupted by one or more O, CO, or NR₂₆, C₃-C₂₀ cycloalkyl, or any combination thereof, which is uninterrupted or is interrupted by O, S, CO, or NR₂₆, or R₂₃ is phenyl, naphthyl, phenyl-C₁-C₄ alkyl, OR₁₇, SR₁₈, or NR₂₁R₂₂;
R₂₄ is (CO)OR₁₇, CONR₁₉R₂₀, (CO)R₁₇; or R₂₄ has one of the meanings given for R₁₉ and R₂₀;
R₂₅ is COOR₁₇, CONR₁₉R₂₀, (CO)R₁₇; or R₂₅ has one of the meanings given for R₁₇;
R₂₆ is hydrogen, C₁-C₂₀ alkyl, C₁-C₄ haloalkyl, or C₂-C₂₀ alkyl which is interrupted by one or more O or CO, or any combination thereof, or is phenyl-C₁-C₄ alkyl, or C₃-C₈ cycloalkyl which is uninterrupted or is interrupted by one or more O or CO, or any combination thereof, or is (CO)R₁₉ or is phenyl which is unsubstituted or substituted by one or more C₁-C₂₀ alkyl, halogen, C₁-C₄ haloalkyl, OR₁₇, SR₁₈, NR₁₉R₂₀,

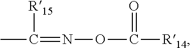

or any combination thereof; and
provided that at least one group

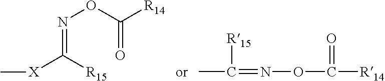

is present in the molecule.

The photoinitiator (C-1) represented by Formula (4) is characterized in comprising one or more annelated unsaturated rings at the carbazole moiety. In other words, at least one pair of R₁ and R₂, R₂ and R₃, R₃ and R₄, R₅ and R₆, R₆ and R₇, or R₇ and R₈ is

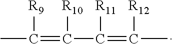

In one embodiment, the C₁-C₂₀ alkyl is linear or branched and is, for example, C₁-C₁₈—, C₁-C₁₄—, C₁-C₁₂—, C₁-C₈—, C₁-C₆- or C₁-C₄ alkyl or C₄-C₁₂— or C₄-C₈ alkyl. Examples are methyl, ethyl, propyl, iso-propyl, n-butyl, sec-butyl, isobutyl, tert-butyl, pentyl, hexyl, heptyl, 2,4,4-trimethylpentyl, 2-ethylhexyl, octyl, nonyl, decyl, dodecyl, tetradecyl, pentadecyl, hexadecyl, octadecyl and icosyl. The C₁-C₆ alkyl has the same meanings as given above for C₁-C₂₀ alkyl up to the corresponding number of C-atoms.

The unsubstituted or substituted C₁-C₂₀ alkyl containing one or more C—C multiple bonds, refers to alkenyl as explained below.

The C₁-C₄ haloalkyl is C₁-C₄ alkyl as defined above substituted by halogen as defined below. The alkyl radical is for example mono- or poly-halogenated, up to the exchange of all H-atoms by halogen. It is for example CₙHₓHal_{y}, wherein x+y=2n+1 and Hal is halogen, preferably F. Examples are chloromethyl, trichloromethyl, trifluoromethyl or 2-bromopropyl, especially trifluoromethyl or trichloromethyl. C₂-C₄ hydroxyalkyl means C₂-C₄ alkyl, which substituted by one or two O-atoms. The alkyl radical is linear or branched. Examples are 2-hydroxyethyl, 1-hydroxyethyl, 1-hydroxypropyl, 2-hydroxypropyl, 3-hydroxypropyl, 1-hydroxybutyl, 4-hydroxybutyl, 2-hydroxybutyl, 3-hydroxybutyl, 2,3-dihydroxypropyl, or 2,4-dihydroxybutyl. C₂-C₁₀ alkoxyalkyl is C₂-C₁₀ alkyl, which is interrupted by one O-atom. C₂-C₁₀ alkyl has the same meanings as given above for C₁-C₂₀ alkyl up to the corresponding number of C-atoms. Examples are methoxymethyl, methoxyethyl, methoxypropyl, ethoxymethyl, ethoxyethyl, ethoxypropyl, propoxymethyl, propoxyethyl, propoxypropyl.

The C₂-C₂₀ alkyl which is interrupted by one or more O, S, NR₂₆ or CO is for example interrupted 1-9, 1-5, 1-3 or once or twice by O S, NR₂₆ or CO. If more than one interrupting radicals are present they are of the same kind or different. Two O-atoms are separated by at least one methylene group, preferably at least two methylene groups, namely ethylene. The alkyl groups are linear or branched. For example the following structural units will occur, —CH₂—CH₂—O—CH₂CH₃, —[CH₂CH₂O]_{y}—CH₃, wherein y=1-9, —(CH₂—CH₂O)₇—CH₂CH₃, —CH₂—CH(CH₃)—O—CH₂—CH₂CH₃, —CH₂—CH(CH₃)—O—CH₂—CH₃, —CH₂—CH₂—S—CH₂CH₃, —CH₂—CH(CH₃)—NR₂₆—CH₂—CH₃, —CH₂—CH₂—COO—CH₂CH₃ or —CH₂—CH(CH₃)—OCO—CH₂—CH₂CH₃.

The C₃-C₁₀ cycloalkyl, C₃-C₁₀ cycloalkyl and C₃-C₈ cycloalkyl in the context of the present application is to be understood as alkyl which at least comprises one ring. It is for example cyclopropyl, cyclobutyl, cyclopentyl, cyclohexyl, cyclooctyl, especially cyclopentyl and cyclohexyl. C₃-C₁₀ cycloalkyl in the context of the present invention is also meant to cover bicyclic rings, in other words a bridged ring, such as

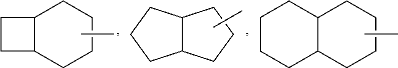

and corresponding rings. Further examples are structures like

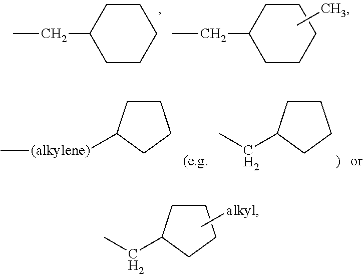

as well as bridged or fused ring systems, e.g.

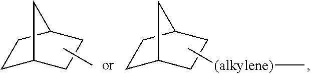

etc. are also meant to be covered by the term.

The C₃-C₂₀ cycloalkyl which is interrupted by O, S, CO, NR₂₆ has the meanings given above, wherein at least one CH₂-group of the alkyl is exchanged by either O, S, CO or NR₂₆. Examples are structures like

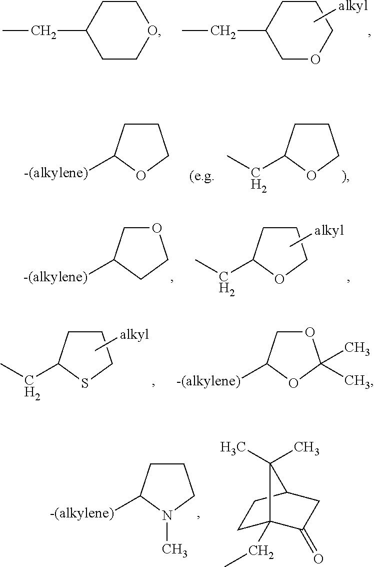

etc.

The C₁-C₈alkyl-C₃-C₁₀cycloalkyl is C₃-C₁₀ cycloalkyl, as defined above which is substituted by one or more alkyl groups with up to 8 carbon atoms. Examples are

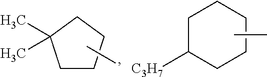

etc.

The C₁-C₈ alkyl-C₃-C₁₀ cycloalkyl which is interrupted by one or more O is O-interrupted C₃-C₁₀ cycloalkyl as described above which is substituted by one or more alkyl groups with up to 8 carbon atoms. Examples are

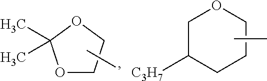

etc.

The C₁-C₁₂ alkoxy is C₁-C₁₂ alkyl, which is substituted by one-O-atom. The C₁-C₁₂ alkyl has the same meanings as given above for C₁-C₂₀ alkyl up to the corresponding number of C-atoms. C₁-C₄ alkoxy is linear or branched, for example, methoxy, ethoxy, propoxy, iso-propoxy, n-butyloxy, sec-butyloxy, isobutyloxy, tert-butyloxy. C₁-C₈ alkoxy and C₁-C₄-alkoxy have the same meanings as above up to the corresponding numbers of C— atoms.

The C₁-C₁₂ alkylsulfanyl is C₁-C₁₂ alkyl, which is substituted by one-S-atom. C₁-C₁₂ alkyl has the same meanings as given above for C₁-C₂₀ alkyl up to the corresponding number of C-atoms. The C₁-C₄ alkylsulfanyl is linear or branched, for example, methylsulfanyl, ethylsulfanyl, propylsulfanyl, isopropylsulfanyl, n-butylsulfanyl, sec-butylsulfanyl, isobutylsulfanyl, tert-butylsulfanyl.

The phenyl-C₁-C₃ alkyl is for example benzyl, phenylethyl, α-methylbenzyl or α,α-dimethylbenzyl, especially benzyl.

The phenyl-C₁-C₃alkoxyl is for example benzyloxy, phenylethyloxy, α-methylbenzyloxy or α,α-dimethylbenzyloxy, especially benzyloxy.

The C₂-C₁₂ alkenyl radicals are mono- or polyunsaturated and are for example C₂-C₁₀-, C₂-C₈-, C₂-C₅-alkenyl e.g. vinyl, allyl, methallyl, 1,1-dimethylallyl, 1-butenyl, 3-butenyl, 2-butenyl, 1,3-pentadienyl, 5-hexenyl, 7-octenyl or dodecenyl, especially allyl. The C₂-C₅ alkenyl radicals have the same meanings as given above for C₂-C₁₂ alkenyl radicals up to the corresponding number of C-atoms.

The C₂-C₁₂ alkenyl which is interrupted by one or more O, CO or NR₂₆ is for example interrupted 1-9, 1-5, 1-3 or once or twice by O S, NR₂₆ or CO. If more than one interrupting radicals are present they are of the same kind or different. Two O-atoms are separated by at least one methylene group, preferably at least two methylene groups, namely ethylene. The alkenyl groups are linear or branched and are defined as above. For example following structural units can be formed —CH═CH—O—CH₂CH₃, —CH═CH—O—CH═CH₂ etc.

The C₄-C₈ cycloalkenyl has one or more double bonds and is for example C₄-C₆-cycloalkenyl or C₆-C₅-cycloalkenyl. Examples are cyclobutenyl, cyclopentenyl, cyclohexenyl or cyclooctenyl, especially cyclopentenyl and cyclohexenyl, preferably cyclohexenyl.

The C₃-C₆ alkenoxy is mono or polyunsaturated and has one of the meanings given for alkenyl above with the attached oxy group up to the corresponding number of C-atoms. Examples are allyloxy, methallyloxy, butenyloxy, pentenoxy, 1,3-pentadienyloxy, 5-hexenyloxy.

The C₂-C₁₂ alkinyl is mono or polyunsaturated, linear or branched and is for example C₂-C₈—, C₂-C₆- or C₂-C₄ alkinyl. Examples are ethinyl, propinyl, butinyl, 1-butinyl, 3-butinyl, 2-butinyl, pentinyl hexinyl, 2-hexinyl, 5-hexinyl, octinyl, etc.

The C₂-C₂₀ alkanoyl is linear or branched and is, for example, C₂-C₁₈—, C₂-C₁₄—, C₂-C₁₂—, C₂-C₈—, C₂-C₆- or C₂-C₄ alkanoyl or C₄-C₁₂- or C₄-C₈ alkanoyl. Examples are acetyl, propionyl, butanoyl, isobutanoyl, pentanoyl, hexanoyl, heptanoyl, octanoyl, nonanoyl, decanoyl, dodecanoyl, tetradecanoyl, pentadecanoyl, hexadecanoyl, octadecanoyl, icosanoyl, preferably acetyl. The C₁-C₈ alkanoyl has the same meanings as given above for the C₂-C₂₀ alkanoyl up to the corresponding number of C-atoms.

The C₂-C₁₂ alkoxycarbonyl is a linear or branched and is, for example, methoxycarbonyl, ethoxycarbonyl, propoxycarbonyl, n-butyloxycarbonyl, isobutyloxycarbonyl, 1,1-dimethylpropoxycarbonyl, pentyloxycarbonyl, hexyloxycarbonyl, heptyloxycarbonyl, octyloxycarbonyl, nonyloxycarbonyl, decyloxycarbonyl or dodecyloxycarbonyl, especially methoxycarbonyl, ethoxycarbonyl, propoxycarbonyl, n-butyloxycarbonyl or iso-butyloxycarbonyl, preferably methoxycarbonyl.

The C₂-C₁₂ alkoxycarbonyl which is interrupted by one or more O is linear or branched. Two O-atoms are separated by at least two methylene groups, namely ethylene. Said interrupted alkoxycarbonyl is unsubstituted or substituted by one or more hydroxyl groups. The C₆-C₂₀ aryloxycarbonyl is for example phenyloxycarbonyl [=phenyl-O—(CO)—], naphtyloxycarbonyl, anthryloxycarbonyl etc. The C₅-C₂₀ heteroaryloxycarbonyl is C₅-C₂₀ heteroaryl-O—CO—.

The C₃-C₁₀ cycloalkylcarbonyl is C₃-C₁₀ cycloalkyl-CO—, wherein the cycloalkyl has one of the meanings indicated above up to the corresponding number of C-atoms. C₃-C₁₀ cycloalkylcarbonyl which is interrupted by one or more O, S, CO, NR₂₆, refers to interrupted cycloalkyl-CO—, where the interrupted cycloalkyl is defined as described above.

The C₃-C₁₀ cycloalkyloxycarbonyl is C₃-C₁₀ cycloalkyl-O—(CO)—, wherein the cycloalkyl has one of the meanings indicated above up to the corresponding number of C-atoms. The C₃-C₁₀ cycloalkyloxycarbonyl which is interrupted by one or more O, S, CO, NR₂₆ refers to interrupted cycloalkyl-O—(CO)—, where the interrupted cycloalkyl is defined as described above.

The C₁-C₂₀ alkylphenyl refers to phenyl which is substituted by one or more alkyl groups, where the sum of the C atoms is up to 20.

The C₆-C₂₀ aryl is for example phenyl, naphthyl, anthryl, phenanthryl, pyrene, chrysene, naphthacene, triphenylene etc., in particular phenyl or naphthyl, preferably phenyl. Naphthyl is 1-naphthyl or 2-naphthyl.

In the context of the present invention C₃-C₂₀ heteroaryl is meant to comprise either one ring or a multiple ring system, e.g. a fused ring-system. Examples are thienyl, benzo[b]thienyl, naphtho[2,3-b]thienyl, thianthrenyl, furyl, dibenzofuryl, chromenyl, xanthenyl, thioxanthyl, phenoxathiinyl, pyrrolyl, imidazolyl, pyrazolyl, pyrazinyl, pyrimidinyl, pyridazinyl, indolizinyl, isoindolyl, indolyl, indazolyl, purinyl, quinolizinyl, isoquinolyl, quinolyl, phthalazinyl, naphthyridinyl, quinoxalinyl, quinazolinyl, cinnolinyl, pteridinyl, carbazolyl, β-carbolinyl, phenanthridinyl, acridinyl, perimidinyl, phenanthrolinyl, phenazinyl, isothiazolyl, phenothiazinyl, isoxazolyl, furazanyl, phenoxazinyl, 7-phenanthryl, anthraquinone-2-yl (=9,10-dioxo-9,10-dihydroanthracen-2-yl), 3-benzo[b]thienyl, 5-benzo[b]thienyl, 2-benzo[b]thienyl, 4-dibenzofuryl, 4,7-dibenzofuryl, 4-methyl-7-dibenzofuryl, 2-xanthenyl, 8-methyl-2-xanthenyl, 3-xanthenyl, 2-phenoxyathiinyl, 2,7-phenoxathiinyl, 2-pyrrolyl, 3-pyrrolyl, 5-methyl-3-pyrrolyl, 2-imidazolyl, 4-imidazolyl, 5-imidazolyl, 2-methyl-4-imidazolyl, 2-ethyl-4-imidazolyl, 2-ethyl-5-imidazolyl, 1H-tetrazol-5-yl, 3-pyrazolyl, 1-methyl-3-pyrazolyl, 1-propyl-4-pyrazolyl, 2-pyrazinyl, 5,6-dimethyl-2-pyrazinyl, 2-indolizinyl, 2-methyl-3-isoindolyl, 2-methyl-1-isoindolyl, 1-methyl-2-indolyl, 1-methyl-3-indolyl, 1,5-dimethyl-2-indolyl, 1-methyl-3-indazolyl, 2,7-dimethyl-8-purinyl, 2-methoxy-7-methyl-8-purinyl, 2-quinolizinyl, 3-isoquinolyl, 6-isoquinolyl, 7-isoquinolyl, 3-methoxy-6-isoquinolyl, 2-quinolyl, 6-quinolyl, 7-quinolyl, 2-methoxy-3-quinolyl, 2-methoxy-6-quinolyl, 6-phthalazinyl, 7-phthalazinyl, 1-methoxy-6-phthalazinyl, 1,4-dimethoxy-6-phthalazinyl, 1,8-naphthyridin-2-yl, 2-quinoxalinyl, 6-quinoxalinyl, 2,3-dimethyl-6-quinoxalinyl, 2,3-dimethoxy-6-quinoxalinyl, 2-quinazolinyl, 7-quinazolinyl, 2-dimethylamino-6-quinazolinyl, 3-cinnolinyl, 6-cinnolinyl, 7-cinnolinyl, 3-methoxy-7-cinnolinyl, 2-pteridinyl, 6-pteridinyl, 7-pteridinyl, 6,7-dimethoxy-2-pteridinyl, 2-carbazolyl, 3-carbazolyl, 9-methyl-2-carbazolyl, 9-methyl-3-carbazolyl, f-carbolin-3-yl, 1-methyl-3-carbolin-3-yl, 1-methyl-3-carbolin-6-yl, 3-phenanthridinyl, 2-acridinyl, 3-acridinyl, 2-perimidinyl, 1-methyl-5-perimidinyl, 5-phenanthrolinyl, 6-phenanthrolinyl, 1-phenazinyl, 2-phenazinyl, 3-isothiazolyl, 4-isothiazolyl, 5-isothiazolyl, 2-phenothiazinyl, 3-phenothiazinyl, 10-methyl-3-phenothiazinyl, 3-isoxazolyl, 4-isoxazolyl, 5-isoxazolyl, 4-methyl-3-furazanyl, 2-phenoxazinyl, 10-methyl-2-phenoxazinyl, etc.

The C₃-C₂₀ heteroaryl in particular is thienyl, benzo[b]thienyl, thianthrenyl, thioxanthyl, 1-methyl-2-indolyl or 1-methyl-3-indolyl; especially thienyl.

The C₄-C₂₀heteroarylcarbonyl are C₃-C₂₀ heteroaryl groups as defined above linked to the rest of the molecule via a CO group.

The substituted aryl radicals phenyl, naphthyl, C₆-C₂₀aryl or C₅-C₂₀heteroaryl are substituted 1 to 7, 1 to 6 or 1 to 4 times respectively, in particular one, two or three times. It is evident that a defined aryl radical cannot have more substituents than free positions at the aryl ring.

The substituents on the phenyl ring are preferably in positions 4 or in 3,4-, 3,4,5-, 2,6-, 2,4- or 2,4,6-configuration on the phenyl ring.

The interrupted radicals which are interrupted once or more times are for example interrupted 1-19, 1-15, 1-12, 1-9, 1-7, 1-5, 1-4, 1-3 or once or twice (it is evident, that the number of interrupting atoms depends on the number of C-atoms to be interrupted). The substituted radicals, which are substituted once or more times have for example 1-7, 1-5, 1-4, 1-3 or one or two identical or different substituents.

A radical substituted by one or more defined substituents is meant to have either one substitutent or more substituents of identical or different definitions as given. Halogen is fluorine, chlorine, bromine and iodine, especially fluorine, chlorine and bromine, preferably fluorine and chlorine. If R₁ and R₂, R₂ and R₃, R₃ and R₄, or R₅ and R₆, R₆ and R₇, R₇ and R₈ independently of each other together are

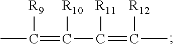

for example the following structures (Ia)-(Ii) are formed:

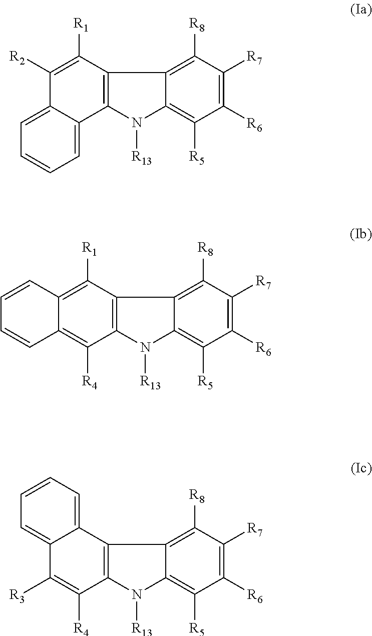

or for example also structures like (Id)-(Ih):

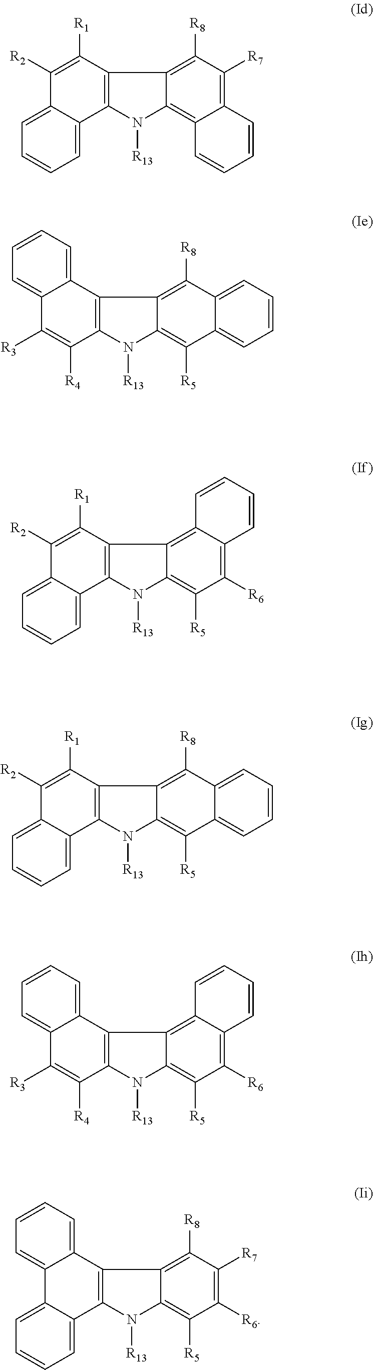

Preferred are structures (Ia).

Characterizing for the photoinitiator (C-1) represented by Formula (4) is, that at least one phenyl ring is condensed to the carbazole moiety to form a “naphthyl” ring. That is one of the above structures is given in Formula (4).

If R₁ and R₂, R₂ and R₃, R₃ and R₄, R₅ and R₆, R₆ and R₇, or R₇ structures like

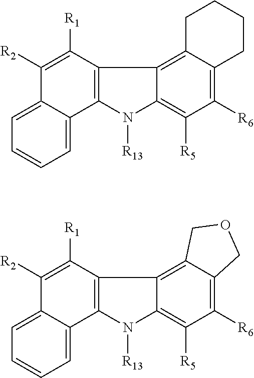

etc. are formed.

If the substituents OR₁₇, SR₁₈, SOR₁₈, SO₂R₁₈ or NR₁₉R₂₀, on a phenyl or naphthyl ring form 5- or 6-membered rings via the radicals R₁₇, R₁₈, R₁₉ and/or R₂₀ with one of the carbon atoms of the naphthyl ring, structures comprising three or more rings (inclusive the naphthyl ring) are obtained.

Examples are

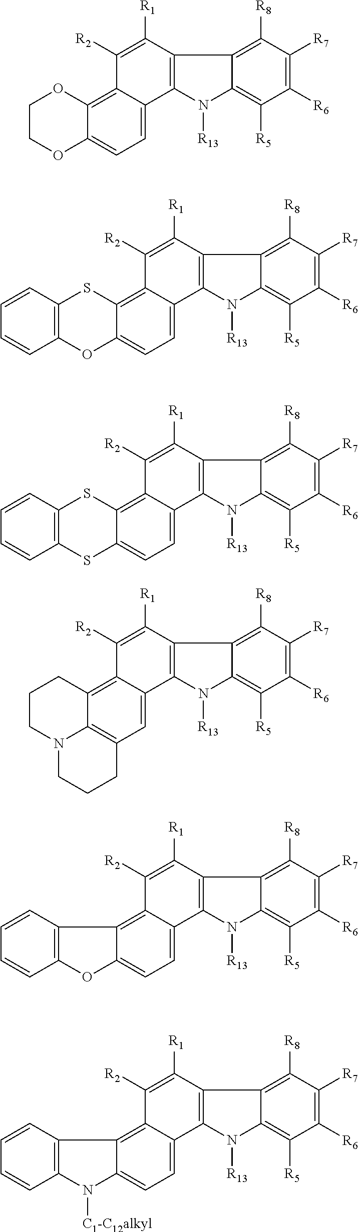

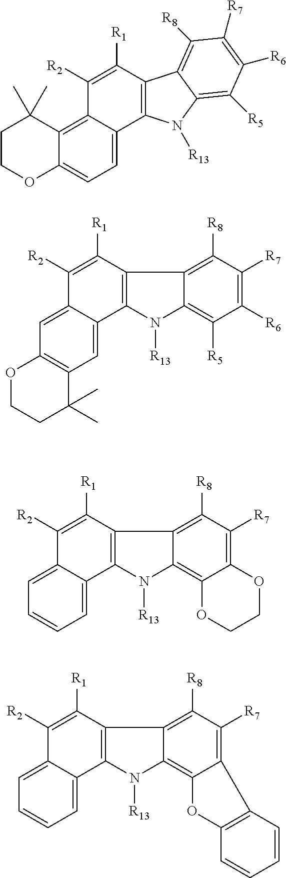

etc.

If R₁₇ forms a direct bond to one of the carbon atoms of the phenyl or naphthyl ring on which the group

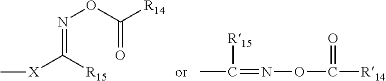

is located, for example structures like

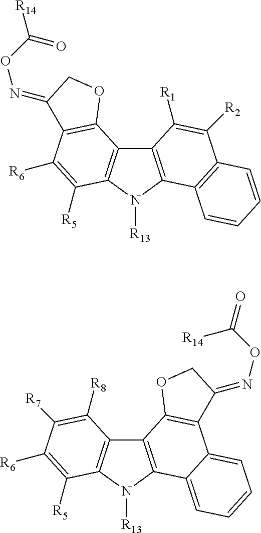

etc. are formed.

If R₁₆ is phenyl substituted by SR₁₈ wherein the radical R₁₈ denotes a direct bond to the phenyl or naphthyl ring of the carbazole moiety to which the COR₁₆ group is attached for example structures like

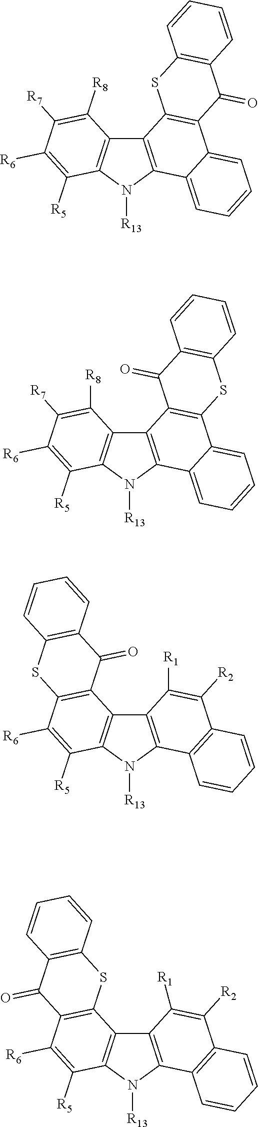

etc. are formed. That is, if R₁₆ is phenyl substituted by SR₁₈ wherein the radical R₁₈ denotes a direct bond to the phenyl or naphthyl ring of the carbazole moiety to which the COR₁₆ group is attached, a thioxanthyl moiety together with one of the phenyl rings or the naphthyl ring of the carbazole moiety is formed.

If R₁₉ and R₂₀ together with the N-atom to which they are attached form a 5- or 6-membered saturated or unsaturated ring which optionally is interrupted by O, S or NR₁₇, saturated or unsaturated rings are formed, for example aziridine, pyrrole, thiazole, pyrrolidine, oxazole, pyridine, 1,3-diazine, 1,2-diazine, piperidine or morpholine. Preferably, if R₁₉ and R₂₀ together with the N-atom to which they are attached form a 5- or 6-membered saturated or unsaturated ring which optionally is interrupted by O, S or NR₁₇, 5- or 6-membered saturated rings which are not interrupted or which are interrupted by O or NR₁₇, in particular by O, are formed.

If R₂₁ and R₂₂ together with the N-atom to which they are attached form a 5- or 6-membered saturated or unsaturated ring, which optionally, is interrupted by O, S or NR₂₆, and to which saturated or unsaturated ring optionally a benzene ring is condensed, saturated or unsaturated rings are formed, for example aziridine, pyrrole, thiazole, pyrrolidine, oxazole, pyridine, 1,3-diazine, 1,2-diazine, piperidine or morpholine, or corresponding annelated rings, e.g.

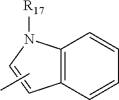

etc.

If R₁₉ and R₂₀ together with the N-atom to which they are attached form a heteroaromatic ring system, said ring system is meant to comprise more than one ring, e.g. two or three rings, as well as one or more than one heteroatoms, from the same kind or different ones. Suitable heteroatoms are for example, N, S, O or P, in particular N, S or O. Examples are, carbazole, indole, isoindole, indazole, purine, isoquinoline, quinoline, carboline, phenothiazine etc.

The terms “and/or” or “or/and” in the present context are meant to express that not only one of the defined alternatives (substituents) may be present, but also several of the defined alternatives (substituents) together, namely mixtures of different alternatives (substituents).

The term “at least” is meant to define one or more than one, for example one or two or three, preferably one or two.

The term “optionally substituted” means, that the radical to which it refers is either unsubstituted or substituted.

The term “optionally interrupted” means, that the radical to which it refers is either not interrupted or is interrupted.

Throughout this specification and the claims which follow, unless the context requires otherwise, the word “comprise”, or variations such as “comprises” or “comprising”, will be understood to imply the inclusion of a stated integer or step or group of integers or steps but not the exclusion of any other integer or step or group of integers or steps. The term “(meth)acrylate” in the context of the present application is meant to refer to the acrylate as well as to the corresponding methacrylate.

The preferences indicated in the text for the compounds according to the present invention in the context of this invention are intended to refer to all categories of the claims, that is to the claims directed to compositions, use, process, color filter etc. as well.

The photoinitiator (C-1) represented by Formula (4) is prepared by methods described in the literature, for example by reaction of the corresponding oximes with an acyl halide, in particular a chloride, or an anhydride in an inert solvent such as for example t-butyl methyl ether, tetrahydrofurane (THF) or dimethylformamide in the presence of a base, for example triethylamine or pyridine, or in a basic solvent such as pyridine. As example in the following the preparation of compounds of the formula Ia, wherein R₇ is the oxime ester group and X is a direct bond is described [the reactions for the compounds (Ib)-(Ih) are performed starting from the appropriate oxime]:

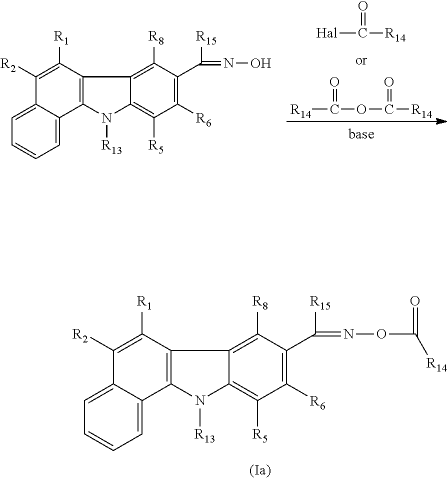

R₁, R₂, R₅, R₆, R₈, R₁₃, R₁₄ and R₁₅ are as defined above, Hal means a halogen atom, in particular Cl.

R₁₄ preferably is methyl.

Such reactions are well known to those skilled in the art, and are generally carried out at temperatures of −15 to +50° C., preferably 0 to 25° C.

When X is CO, the corresponding oxime is synthesized by the nitrosation of the methylene group with an alkyl nitrite such as for example methyl nitrite, ethyl nitrite, isopropyl nitrite, butyl nitrite or isoamyl nitrite. Then, the esterification is carried out under the same condition as mentioned above:

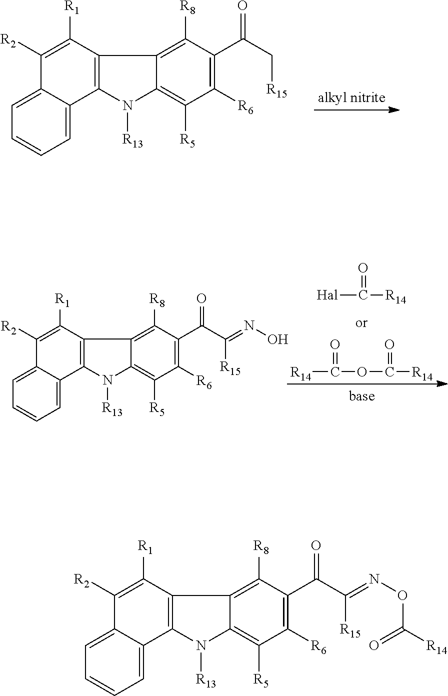

Subject of the invention therefore also is a process for the preparation of the photoinitiator (C-1) represented by Formula (4) as defined above by reacting the corresponding oxime compound with an acyl halide of Formula (a) or an anhydride of Formula (b)

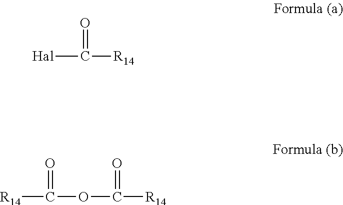

Hal is a halogen, in particular Cl, and R₁₄ is as defined above.

The oximes required as starting materials may be obtained by a variety of methods described in standard chemistry textbooks (for instance in J. March, Advanced Organic Chemistry, 4th Edition, Wiley Interscience, 1992), or in specialized monographs, for example, S. R. Sandler & W. Karo, Organic functional group preparations, Vol. 3, Academic Press.

One of the most convenient methods is, for example, the reaction of aldehydes or ketones with hydroxylamine or its salt in polar solvents like dimethylacetamide (DMA), aqueous DMA, ethanol or aqueous ethanol. In that case, a base such as sodium acetate or pyridine is added to control the pH of the reaction mixture. It is well known that the rate of the reaction is pH-dependent, and the base may be added at the beginning or continuously during the reaction. Basic solvents such as pyridine may also be used as base and/or solvent or cosolvent. The reaction temperature is generally from room temperature to the refluxing temperature of the mixture, usually about 20-120° C.

The corresponding ketone intermediates are for example prepared by the methods described in the literature, for example in standard chemistry textbooks (for instance in J. March, Advanced Organic Chemistry, 4th Edition, Wiley Interscience, 1992). In addition, successive Friedel-Crafts reaction is effective for synthesis of the intermediates. Such reactions are well known to those skilled in the art.

Another convenient synthesis of oximes is the nitrosation of “active” methylene groups with nitrous acid or an alkyl nitrite. Both alkaline conditions, as described for example in Organic Syntheses coll. Vol. VI (J. Wiley & Sons, New York, 1988), pp 199 and 840, and acidic conditions, as described, for example, in Organic Synthesis coll. vol V, pp 32 and 373, coll. vol. III, pp 191 and 513, coll. vol. II, pp. 202, 204 and 363, are suitable for the preparation of the oximes used as starting materials in the invention. Nitrous acid is usually generated from sodium nitrite. The alkyl nitrite can be for example methyl nitrite, ethyl nitrite, isopropyl nitrite, butyl nitrite, or isoamyl nitrite.

Another embodiment of the invention are the free oxime compounds of the formula (IA):

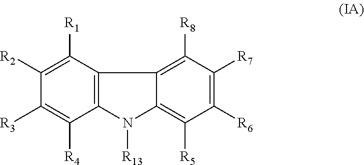

wherein R₁, R₂, R₃, R₄, R₅, R₆, R₇ and R₈ independently of each other are hydrogen, C₁-C₂ alkyl,

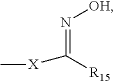

COR₁₆, OR₁₇, halogen, NO₂, or

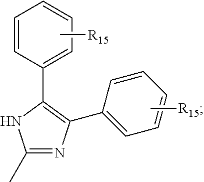

or R₁ and R₂, R₂ and R₃, R₃ and R₄, R₅ and R₆, R₆ and R₇, or R₇ and R₈ independently of each other are C₂-C₁₀ alkenyl which is substituted by

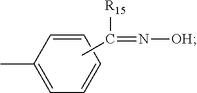

or R₁ and R₂, R₂ and R₃, R₃ and R₄, R₅ and R₆, R₆ and R₇, or R₇ and R₈ independently of each other together are —(CH₂)ₚ—Y—(CH₂)_{q}—;
or R₁ and R₂, R₂ and R₃, R₃ and R₄, R₅ and R₆, R₆ and R₇, or R₇ and R₈ independently of each other together are

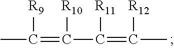

provided that at least one pair of R₁ and R₂, R₂ and R₃, R₃ and R₄, R₅ and R₆, R₆ and R₇, or R₇ and R₈ is

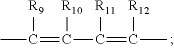

R₉, R₁₀, R₁₁ and R₁₂ independently of each other are hydrogen, C₁-C₂₀ alkyl which is unsubstituted or substituted by one or more halogen, phenyl, CN, OH, SH, C₁-C₄-alkoxy, (CO)OH or by (CO)O(C₁-C₄ alkyl);
or R₉, R₁₀, R₁₁, and R₁₂ independently of each other are unsubstituted phenyl or phenyl substituted by one or more C₁-C₆alkyl, halogen, CN, OR₁₇, SR₁₈ or by NR₁₉R₂₀;
or R₉, R₁₀, R₁₁, and R₁₂ independently of each other are halogen, CN, OR₁₇, SR₁₈, SOR₁₈, SO₂R₁₈ or NR₁₉R₂₀, wherein the substituents OR₁₇, SR₁₈ or NR₁₉R₂₀ optionally form 5- or 6-membered rings via the radicals R₁₇, R₁₈, R₁₉ and/or R₂₀ with one of the carbon atoms of the naphthyl ring;
or R₉, R₁₀, R₁₁ and R₁₂ independently of each other are

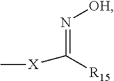

COR₁₆ or NO₂;
Y is O, S, NR₂₆ or a direct bond;
p is an integer 0, 1, 2 or 3;
q is an integer 1, 2 or 3;
X is CO or a direct bond;
R₁₃ is C₁-C₂₀ alkyl which is unsubstituted or substituted by one or more halogen, R₁₇, COOR₁₇, OR₁₇, SR₁₈, CONR₁₉R₂₀, NR₁₉R₂₀,

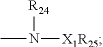

PO(OCₖH₂ₖ₊₁)₂, or by
or R₁₃ is C₂-C₂₀ alkyl which is interrupted by one or more O, S, SO, SO₂, NR₂₆ or CO,
or is C₂-C₁₂ alkenyl which is uninterrupted or interrupted by one or more O, CO or NR₂₆,
wherein the interrupted C₂-C₂₀ alkyl and the uninterrupted or interrupted C₂-C₁₂ alkenyl are unsubstituted or are substituted by one or more halogen;
or R₁₃ is C₄-C₈ cycloalkenyl, C₂-C₁₂ alkinyl, or C₃-C₁₀ cycloalkyl which is uninterrupted or interrupted by one or more O, S, CO or NR₂₆;
or R₁₃ is phenyl or naphthyl each of which is unsubstituted or substituted by one or more OR₁₇, SR₁₈, NR₁₉R₂₀,

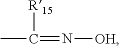

COR₁₆, CN, NO₂, halogen, C₁-C₂₀ alkyl, C₁-C₄ haloalkyl, C₂-C₂₀ alkyl which is interrupted by one or more O, S, CO or NR₂₆, or each of which is substituted by C₃-C₁₀ cycloalkyl or by C₃-C₁₀ cycloalkyl which is interrupted by one or more O, S, CO, or NR₂₆;
k is an integer 1 to 10;
R₁₅ is C₆-C₂₀ aryl or C₃-C₂₀ heteroaryl each of which is unsubstituted or substituted by one or more phenyl, halogen, C₁-C₄ haloalkyl, CN, NO₂, OR₁₇, SR₁₈, NR₁₉R₂₀, PO(OCₖH₂ₖ₊₁)₂, SO—C₁-C₁₀ alkyl, SO₂—C₁-C₁₀ alkyl, by C₂-C₂₀ alkyl which is interrupted by one or more O, S or NR₂₆, or each of which is substituted by C₁-C₂₀ alkyl which is unsubstituted or substituted by one or more halogen, COOR₁₇, CONR₁₉R₂₀, phenyl, C₃-C₈cycloalkyl, C₃-C₂₀ heteroaryl, C₆-C₂₀ aryloxycarbonyl, C₃-C₂₀ heteroaryloxycarbonyl, OR₁₇, SR₁₈ or NR₁₉R₂₀;
or R₁₅ is hydrogen, C₂-C₁₂ alkenyl, C₃-C₈ cycloalkyl which is uninterrupted or is interrupted by one or more O, CO or NR₂₆;
or R₁₅ is C₁-C₂₀ alkyl which is unsubstituted or substituted by one or more halogen, OR₁₇, SR₁₈, C₃-C₈ cycloalkyl, C₃-C₂₀ heteroaryl, C₆-C₂₀ aryloxycarbonyl, C₃-C₂₀ heteroaryloxycarbonyl, NR₁₉R₂₀, COOR₁₇, CONR₁₉R₂₀, PO(OCₖH₂ₖ₊₁)₂,

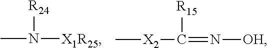

phenyl, or the C₁-C₂₀ alkyl is substituted by phenyl which is substituted by halogen, C₁-C₂₀ alkyl, C₁-C₄ haloalkyl, OR₁₇, SR₁₈, or NR₁₉R₂₀;
or R₁₅ is C₂-C₂₀ alkyl which is interrupted by one or more O, SO or SO₂, and which interrupted C₂-C₂₀ alkyl is unsubstituted or substituted by one or more halogen, OR₁₇, COOR₁₇, CONR₁₉R₂₀, phenyl or by phenyl which is substituted by OR₁₇, SR₁₈ or NR₁₉R₂₀;
or R₁₅ is C₂-C₂₀ alkanoyl or benzoyl which is unsubstituted or substituted by one or more C₁-C₆ alkyl, halogen, phenyl, OR₁₇, SR₁₈ or NR₁₉R₂₀;
or R₁₅ is naphthoyl which is unsubstituted or is substituted by one or more OR₁₇ or is C₃-C₁₄ heteroarylcarbonyl;
or R₁₅ is C₂-C₁₂ alkoxycarbonyl which is uninterrupted or is interrupted by one or more O and which interrupted or uninterrupted C₂-C₁₂ alkoxycarbonyl is unsubstituted or substituted by one or more hydroxyl groups;
or R₁₅ is phenoxycarbonyl which is unsubstituted or substituted by one or more C₁-C₆ alkyl, halogen, C₁-C₄ haloalkyl, phenyl, OR₁₇, SR₁₈ or NR₁₉R₂₀;
or R₁₅ is CN, CONR₁₉R₂₀, NO₂, C₁-C₄ haloalkyl, S(O)ₘ—C₁-C₆alkyl; S(O)ₘ-phenyl which is unsubstituted or substituted by C₁-C₁₂ alkyl or SO₂—C₁-C₆ alkyl;
or R₁₅ is SO₂O-phenyl which is unsubstituted or substituted by C₁-C₁₂alkyl; or is diphenyl phosphinoyl or di-(C₁-C₄ alkoxy)-phosphinoyl;
m is 1 or 2;
R′₁₅ has one of the meanings as given for R₁₅;
X₁ is O, S, SO or SO₂;
X₂ is O, CO, S or a direct bond;
R₁₆ is C₆-C₂₀ aryl or C₃-C₂₀ heteroaryl each of which is unsubstituted or substituted by one or more phenyl, halogen, C₁-C₄haloalkyl, CN, NO₂, OR₁₇, SR₁₈, NR₁₉R₂₀, or by C₁-C₂₀ alkyl which is interrupted by one or more O, S, or NR₂₆, or each of which is substituted by one or more C₁-C₂₀ alkyl which is unsubstituted or substituted by one or more halogen, COOR₁₇, CONR₁₉R₂₀, phenyl, C₃-C₈ cycloalkyl, C₃-C₂₀ heteroaryl, C₆-C₂₀ aryloxycarbonyl, C₃-C₂₀ heteroaryloxycarbonyl, OR₁₇, SR₁₈ or NR₁₉R₂₀;
or R₁₆ is hydrogen, C₁-C₂₀ alkyl which is unsubstituted or substituted by one or more halogen, phenyl, OH, SH, CN, C₃-C₆ alkenoxy, OCH₂CH₂CN, OCH₂CH₂(CO)O(C₁-C₄ alkyl), O(CO)—(C₁-C₄ alkyl), O(CO)-phenyl, (CO)OH or (CO)O(C₁-C₄ alkyl);
or R₁₆ is C₂-C₁₂ alkyl which is interrupted by one or more O, S or NR₂₆;
or R₁₆ is (CH₂CH₂O)ₙ₊₁H, (CH₂CH₂O)ₙ(CO)—(C₁-C₈ alkyl), C₂-C₁₂ alkenyl or C₃-C₈ cycloalkyl;
or R₁₆ is phenyl substituted by SR₁₈ wherein the radical R₁₈ denotes a direct bond to the phenyl or naphthyl ring of the carbazole moiety to which the COR₁₆ group is attached;
n is 1 to 20;
R₁₇ is hydrogen, phenyl-C₁-C₃ alkyl, C₁-C₂₀ alkyl which is unsubstituted or substituted by one or more halogen, OH, SH, CN, C₃-C₆ alkenoxy, OCH₂CH₂CN, OCH₂CH₂(CO)O(C₁-C₄ alkyl), O(CO)—(C₁-C₄ alkyl), O(CO)—(C₂-C₄) alkenyl, O(CO)-phenyl, (CO)OH, (CO)O(C₁-C₄ alkyl), SO₂—(C₁-C₄ haloalkyl), O(C₁-C₄ haloalkyl), C₃-C₂₀ cycloalkyl, or by C₃-C₂₀ cycloalkyl which is interrupted by one or more O;
or R₁₇ is C₂-C₂₀ alkyl which is interrupted by one or more O, S or NR₂₆;
or R₁₇ is (CH₂CH₂O)ₙ₊₁H, (CH₂CH₂O)ₙ(CO)—(C₁-C₈ alkyl), C₁-C₈ alkanoyl, C₂-C₁₂ alkenyl, C₃-C₆ alkenoyl, or C₃-C₂₀ cycloalkyl which is uninterrupted or interrupted by one or more O, S, CO or NR₂₆;
or R₁₇ is C₁-C₈ alkyl-C₃-C₁₀ cycloalkyl which is uninterrupted or interrupted by one or more O;
or R₁₇ is benzoyl which is unsubstituted or substituted by one or more C₁-C₆ alkyl, halogen, OH or C₁-C₃ alkoxy;
or R₁₇ is phenyl, naphthyl or C₃-C₂₀ heteroaryl, each of which is unsubstituted or substituted by one or more halogen, OH, C₁-C₁₂ alkyl, C₁-C₁₂ alkoxy, CN, NO₂, phenyl-C₁-C₃ alkyloxy, phenoxy, C₁-C₁₂ alkylsulfanyl, phenylsulfanyl, N(C₁-C₁₂ alkyl)₂, diphenylamino or

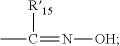

or R₁₇ forms a direct bond to one of the carbon atoms of the phenyl or naphthyl ring on which the group

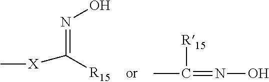

is located;
R₁₈ is hydrogen, C₂-C₁₂ alkenyl, C₃-C₂₀ cycloalkyl, or phenyl-C₁-C₃ alkyl, wherein the C₂-C₁₂ alkenyl, C₃-C₂₀ cycloalkyl, or phenyl-C₁-C₃ alkyl is uninterrupted or interrupted by one or more O, S, CO, NR₂₆ or COOR₁₇;
or R₁₈ is C₁-C₂₀ alkyl which is unsubstituted or is substituted by one or more OH, SH, CN, C₃-C₆ alkenoxy, OCH₂CH₂CN, OCH₂CH₂(CO)O(C₁-C₄ alkyl), O(CO)—(C₂-C₄)alkenyl, O(CO)—(C₁-C₄ alkyl), O(CO)-phenyl or (CO)OR₁₇;
or R₁₈ is C₂-C₂₀ alkyl which is interrupted by one or more O, S, CO, NR₂₆ or COOR₁₇;
or R₁₈ is (CH₂CH₂O)ₙH, (CH₂CH₂O)ₙ(CO)—(C₁-C₈ alkyl), C₂-C₈ alkanoyl or C₃-C₆ alkenoyl;
or R₁₈ is benzoyl which is unsubstituted or substituted by one or more C₁-C₆ alkyl, halogen, OH, C₁-C₄ alkoxy or C₁-C₄ alkylsulfanyl;
or R₁₈ is phenyl, naphthyl or C₃-C₂₀heteroaryl, each of which is unsubstituted or substituted by one or more halogen, C₁-C₁₂ alkyl, C₁-C₄ haloalkyl, C₁-C₁₂ alkoxy, CN, NO₂, phenyl-C₁-C₃ alkyloxy, phenoxy, C₁-C₁₂ alkylsulfanyl, phenylsulfanyl, N(C₁-C₁₂ alkyl)₂, diphenylamino, (CO)O(C₁-C₈ alkyl), (CO)—C₁-C₈ alkyl, (CO)N(C₁-C₈ alkyl)₂ or

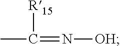

R₁₉ and R₂₀ independently of each other are hydrogen, C₁-C₂₀ alkyl, C₂-C₄ hydroxyalkyl, C₂-C₁₀ alkoxyalkyl, C₂-C₅ alkenyl, C₃-C₂₀ cycloalkyl, phenyl-C₁-C₃ alkyl, SO₂—(C₁-C₄ haloalkyl), C₁-C₈ alkanoyl, C₁-C₈ alkanoyloxy, C₃-C₁₂ alkenoyl or benzoyl;
or R₁₉ and R₂₀ are phenyl, naphthyl or C₃-C₂₀ heteroaryl, each of which is unsubstituted or substituted by one or more halogen, C₁-C₄ haloalkyl, C₁-C₂₀ alkoxy, C₁-C₁₂ alkyl, benzoyl or C₁-C₁₂ alkoxy;
or R₁₉ and R₂₀ together with the N-atom to which they are attached form a 5- or 6-membered saturated or unsaturated ring which is uninterrupted or is interrupted by O, S or NR₁₇, and which 5- or 6-membered saturated or unsaturated ring is unsubstituted or substituted by one or more C₁-C₂₀ alkyl, C₁-C₂₀ alkoxy, ═O, OR₁₇, SR₁₈, NR₂₁R₂₂, (CO)R₂₃, NO₂, halogen, C₁-C₄-haloalkyl, CN, phenyl,

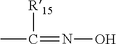

or by C₃-C₂₀ cycloalkyl which is uninterrupted or is interrupted by one or more O, S, CO or NR₁₇;
or R₁₉ and R₂₀ together with the N-atom to which they are attached form a heteroaromatic ring system which is unsubstituted or substituted by one or more C₁-C₂₀ alkyl, C₁-C₄ haloalkyl, C₁-C₂₀ alkoxy, ═O, OR₁₇, SR₁₈, NR₂₁R₂₂, (CO)R₂₃,

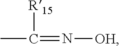

halogen, NO₂, CN, phenyl or by C₃-C₂₀ cycloalkyl which is uninterrupted or is interrupted by one or more O, S, CO or NR₁₇;
R₂₁ and R₂₂ independently of each other are hydrogen, C₁-C₂₀alkyl, C₁-C₄ haloalkyl, C₃-C₁₀ cycloalkyl or phenyl;
or R₂₁ and R₂₂ together with the N-atom to which they are attached form a 5- or 6-membered saturated or unsaturated ring, which is uninterrupted or is interrupted by O, S or NR₂₆, and which 5- or 6-membered saturated or unsaturated ring is not condensed or to which 5- or 6-membered saturated or unsaturated ring a benzene ring is condensed;
R₂₃ is hydrogen, OH, C₁-C₂₀ alkyl, C₁-C₄ haloalkyl, C₂-C₂₀ alkyl which is interrupted by one or more O, CO or NR₂₆, C₃-C₂₀ cycloalkyl which is uninterrupted or is interrupted by O, S, CO or NR₂₆;
or R₂₃ is phenyl, naphthyl, phenyl-C₁-C₄ alkyl, OR₁₇, SR₁₈ or NR₂₁R₂₂;
R₂₄ is (CO)OR₁₇, CONR₁₉R₂₀, (CO)R₁₇; or R₂₄ has one of the meanings given for R₁₉ and R₂₀;
R₂₅ is COOR₁₇, CONR₁₉R₂₀, (CO)R₁₇; or R₂₅ has one of the meanings given for R₁₇;
R₂₆ is hydrogen, C₁-C₂₀ alkyl, C₁-C₄ haloalkyl, C₂-C₂₀ alkyl which is interrupted by one or more O or CO, or is phenyl-C₁-C₄ alkyl, C₃-C₈ cycloalkyl which is uninterrupted or is interrupted by one or more O or CO, or is (CO)R₁₉ or is phenyl which is unsubstituted or substituted by one or more C₁-C₂₀ alkyl, halogen, C₁-C₄haloalkyl, OR₁₇, SR₁₈, NR₁₉R₂₀ or

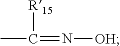

provided that at least one group

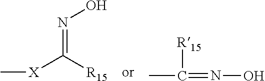

is present in the molecule.

The preferences for the radicals defined for the photoinitiator (C-1) represented by Formula (IA) correspond to the ones as given for the photoinitiator (C-1) represented by Formula (4) as given below, except that each defined oxime ester group, as for example

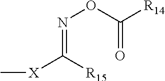

is exchanged by the corresponding free oxime radical

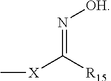

Every oxime ester group can exist in two configurations, (Z) or (E). It is possible to separate the isomers by conventional methods, but it is also possible to use the isomeric mixture as such as photoinitiating species. Therefore, the invention also relates to mixtures of configurational isomers of the photoinitiator (C-1) represented by Formula (4).

Preferred is the photoinitiator (C-1) represented by Formula (4) as defined above, wherein R₁, R₂, R₃, R₄, R₅, R₆, R₇ and R₈ independently of each other are hydrogen, C₁-C₂₀ alkyl,

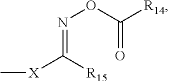

COR₁₆ or NO₂, or R₁ and R₂, R₂ and R₃, R₃ and R₄, R₅ and R₆, R₆ and R₇ or R₇ and R₈ independently of each other together are

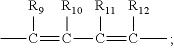

provided that at least one pair of R₁ and R₂, R₂ and R₃, R₃ and R₄, R₅ and R₆, R₆ and R₇, or R₇ and R₈ is

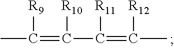

X is CO or a direct bond;
R₁₃ is C₁-C₂₀ alkyl which is unsubstituted or substituted by one or more halogen, OR₁₇, SR₁₈, COOR₁₇, CONR₁₉R₂₀ or by PO(OCₖH₂ₖ₊₁)₂;
or R₁₃ is C₂-C₂₀ alkyl which is interrupted by one or more O, S, NR₂₆ or CO;
or R₁₃ is phenyl or naphthyl both of which are unsubstituted or substituted by one or more

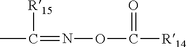

or COR₁₆;
R₁₄ is C₁-C₂₀ alkyl, phenyl or C₁-C₈ alkoxy;
R₁₅ is phenyl, naphthyl, C₃-C₂₀ heteroaryl each of which is unsubstituted or substituted by one or more phenyl, halogen, C₁-C₄ haloalkyl, OR₁₇, SR₁₈, or C₂-C₂₀ alkyl which is interrupted by one or more O or S, or each of which is substituted by one or more C₁-C₂₀ alkyl which is unsubstituted or substituted by one or more halogen, COOR₁₇, CONR₁₉R₂₀, phenyl, C₃-C₈ cycloalkyl, C₃-C₂₀ heteroaryl, C₆-C₂₀ aryloxycarbonyl, C₄-C₂₀ heteroaryloxycarbonyl, OR₁₇, SR₁₈, NR₁₉R₂₀ or PO(OCₖH₂ₖ₊₁)₂;
or R₁₅ is C₁-C₂₀ alkyl which is unsubstituted or substituted by one or more OR₁₇, SR₁₈, C₃-C₈ cycloalkyl, C₃-C₂₀ heteroaryl, NR₁₉R₂₀, COOR₁₇, CONR₁₉R₂₀ or PO(OCₖH₂ₖ₊₁)₂;
R′₁₄ has one of the meanings as given for R₁₄;
R′₁₅ has one of the meanings as given for R₁₅;
R₁₆ is phenyl which is unsubstituted or substituted by one or more OR₁₇, SR₁₈, NR₁₉R₂₀, or by C₂-C₂₀ alkyl which is interrupted by one or more O, S, or NR₂₆,
or R₁₆ is phenyl which is substituted by one or more C₁-C₂₀ alkyl which is unsubstituted or substituted by one or more halogen, COOR₁₇, CONR₁₉R₂₀, phenyl, C₃-C₈ cycloalkyl, C₃-C₂₀ heteroaryl, C₆-C₂₀ aryloxycarbonyl, C₄-C₂₀ heteroaryloxycarbonyl, OR₁₇, SR₁₈ or NR₁₉R₂₀;
or R₁₆ is C₁-C₂₀ alkyl which is unsubstituted or substituted by halogen, phenyl, OH, SH, CN, C₃-C₆ alkenoxy, OCH₂CH₂(CO)O(C₁-C₄ alkyl), O(CO)—(C₁-C₄ alkyl), or (CO)O(C₁-C₄ alkyl);
R₁₇ is C₁-C₂₀alkyl which is unsubstituted or substituted by one or more halogen, OCH₂CH₂(CO)O(C₁-C₄ alkyl), O(C₁-C₄ alkyl), (CO)O(C₁-C₄ alkyl), C₃-C₂₀ cycloalkyl, or by C₃-C₂₀ cycloalkyl which is interrupted by one or more O; or
R₁₇ is C₂-C₂₀ alkyl which is interrupted by one or more O;
R₁₈ is methyl substituted by (CO)OR₁₇;
R₁₉ and R₂₀ independently of one another are hydrogen, phenyl, C₁-C₂₀ alkyl, C₁-C₈ alkanoyl or C₁-C₈ alkanoyloxy;
or R₁₉ and R₂₀ together with the N-atom to which they are attached form a heteroaromatic ring system which is unsubstituted or substituted by

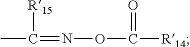

provided that at least one group

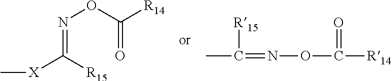

is present in the molecule.

Emphasis has to be laid on the photoinitiator (C-1) represented by Formula (4) as defined above, wherein R₁, R₂, R₅, R₆, R₇ and R₈ independently of each other are hydrogen,

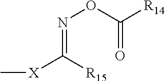

COR₁₆, or NO₂, R₃ and R₄, together are

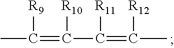

R₉, R₁₀, R₁₁ and R₁₂ are hydrogen
X is a direct bond;
R₁₃ is C₁-C₂₀ alkyl;
R₁₄ is C₁-C₂₀ alkyl;
R₁₅ is C₁-C₂₀ alkyl or phenyl which is substituted by one or more OR₁₇ or C₁-C₂₀ alkyl;
R₁₆ is phenyl which is substituted by one or more C₁-C₂₀ alkyl or OR₁₇; and
R₁₇ is C₁-C₂₀ alkyl which is unsubstituted or substituted by one or more halogen or is C₂-C₂₀ alkyl which is interrupted by one or more O;
provided that at least one group

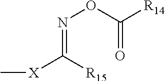

present in the molecule.

Subject of the invention further is the photoinitiator (C-1) represented by Formula (4) as defined above, wherein R₁, R₂, R₃, R₄, R₅, R₆, R₇ and R₈ independently of each other are hydrogen, or R₁ and R₂, R₃ and R₄, or R₅ and R₆, independently of each other together are

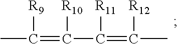

provided that at least one pair of R₁ and R₂, R₃ and R₄ or R₅ and R₆ is

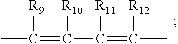

or R₂ is

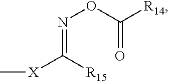

COR₁₆, NO₂ or

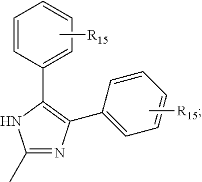

or R₇ is

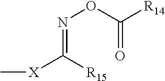

or COR₁₆;
R₉, R₁₁ and R₁₂ are hydrogen;
R₁₀ is hydrogen, OR₁₇ or COR₁₆;
X is CO or a direct bond;
R₁₃ is C₁-C₂₀ alkyl which is unsubstituted or substituted by one or more halogen, R₁₇, OR₁₇, SR₁₈, or by PO(OCₖH₂ₖ₊₁)₂;
or R₁₃ is C₂-C₂₀ alkyl which is interrupted by one or more O;
or R₁₃ is phenyl;
k is an integer 2;
R₁₄ is C₁-C₂₀ alkyl or thienyl;
R₁₅ is phenyl or naphthyl each of which is unsubstituted or substituted by one or more OR₁₇ or C₁-C₂₀ alkyl, or R₁₅ is thienyl, hydrogen, C₁-C₂₀ alkyl which is unsubstituted or substituted by one or more OR₁₇, SR₁₈, C₃-C₈ cycloalkyl, NR₁₉R₂₀ or by COOR₁₇;
or R₁₅ is C₂-C₂₀ alkyl which is interrupted by SO₂;
R₁₆ is phenyl or naphthyl each of which is unsubstituted or substituted by one or more OR₁₇, SR₁₈, NR₁₉R₂₀, or by C₁-C₂₀ alkyl;
or R₁₆ is thienyl;
R₁₇ is hydrogen, C₁-C₈ alkanoyl, C₁-C₂₀ alkyl which is unsubstituted or substituted by one or more halogen, O(CO)—(C₁-C₄ alkyl), O(CO)—(C₂-C₄)alkenyl or by C₃-C₂₀ cycloalkyl which is interrupted by one or more O;
or R₁₇ is C₂-C₂₀ alkyl which is interrupted by one or more O;
R₁₈ is C₃-C₂₀ cycloalkyl, C₁-C₂₀ alkyl which is unsubstituted or is substituted by one or more OH, O(CO)—(C₂-C₄)alkenyl or (CO)OR₁₇;
or R₁₈ is phenyl which is unsubstituted or substituted by one or more halogen;
R₁₉ and R₂₀ independently of each other are C₁-C₈ alkanoyl or C₁-C₈ alkanoyloxy;
or R₁₉ and R₂₀ together with the N-atom to which they are attached form a 5- or 6-membered saturated ring which is interrupted by O;
provided that at least one group

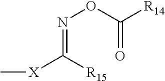

is present in the molecule.

Examples of the compounds according to the invention are the compounds of the formula (Ia)-(Ig) as defined above. Interesting are compounds of the formula (Ia), (Ib), (Ic), especially of the formula (Ia) or (Ic), or of the formula (Ia), (Ic) or (Id), in particular of the formula (Ia).

R₁, R₂, R₃, R₄, R₅, R₆, R₇ and R₈ for example independently of each other are hydrogen,

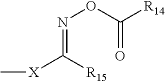

or COR₁₆, or R₁ and R₂, R₂ and R₃, R₃ and R₄, or R₅ and R₆, R₆ and R₇, R₇ and R₈ independently of each other together are

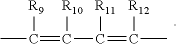

For example R₃ and R₄ or R₁ and R₂ together are

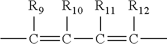

or R₃ and R₄ and R₅ and R₆ together are

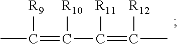

in particular R₃ and R₄ together are

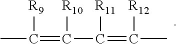

R₁, R₅, R₆ and R₈ for example are hydrogen.

R₇ in particular is hydrogen,

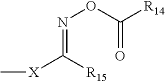

or COR₁₆. Or R₇ is

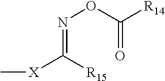

or COR₁₆, in particular

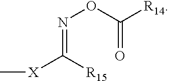

R₂ especially is

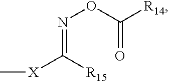

### COR₁₆ or

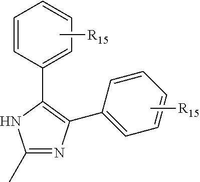

or R₂ together with R₁ is

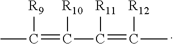

In particular R₂ is COR₁₆.

X preferably is a direct bond.

R₉, R₁₀, R₁₁ and R₁₂ for example independently of each other are hydrogen, C₁-C₂₀ alkyl, unsubstituted phenyl or phenyl substituted by one or more C₁-C₆ alkyl, halogen, OR₁₇ or by SR₁₈; or R₉, R₁₀, R₁₁, and R₁₂ independently of each other are halogen, OR₁₇, SR₁₈ or NR₁₉R₂₀, wherein the substituents OR₁₇, SR₁₈ or NR₁₉R₂₀ optionally form 5- or 6-membered rings via the radicals R₁₇, R₁₈, R₁₉ and/or R₂₀ with one of the carbon atoms of the naphthyl ring; or R₉, R₁₀, R₁₁ and R₁₂ independently of each other are

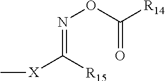

### or COR₁₆.

Especially R₉, R₁₀, R₁₁ and R₁₂ for example independently of each other are hydrogen, C₁-C₂₀ alkyl, unsubstituted phenyl or phenyl substituted by one or more C₁-C₆alkyl, halogen, OR₁₇ or by SR₁₈; or R₉, R₁₀, R₁₁, and R₁₂ independently of each other are halogen, OR₁₇, SR₁₈ or NR₁₉R₂₀; or R₉, R₁₀, R₁₁ and R₁₂ independently of each other are

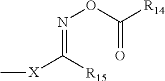

### or COR₁₆.

R₉, R₁₀, R₁₁ and R₁₂ for example independently of each other are hydrogen, C₁-C₂₀ alkyl, unsubstituted phenyl or phenyl substituted by one or more C₁-C₆alkyl; or R₉, R₁₀, R₁₁ and R₁₂ independently of each other are

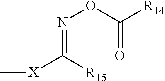

### or COR₁₆.

In another embodiment R₉, R₁₀, R₁₁ and R₁₂ for example independently of each other are hydrogen, C₁-C₂₀ alkyl, unsubstituted phenyl or phenyl substituted by one or more C₁-C₆ alkyl, halogen, OR₁₇ or by SR₁₈; or R₉, R₁₀, R₁₁, and R₁₂ independently of each other are halogen, OR₁₇, SR₁₈ or NR₁₉R₂₀, wherein the substituents OR₁₇, SR₁₈ or NR₁₉R₂₀ optionally form 5- or 6-membered rings via the radicals R₁₇, R₁₈, R₁₉ and/or R₂₀ with one of the carbon atoms of the naphthyl ring.

Further R₉, R₁₀, R₁₁ and R₁₂ for example independently of each other are hydrogen, C₁-C₂₀ alkyl, unsubstituted phenyl or phenyl substituted by one or more C₁-C₆ alkyl, halogen, OR₁₇ or by SR₁₈, or R₉, R₁₀, R₁₁, and R₁₂ independently of each other are halogen, OR₁₇, SR₁₈, NR₁₉R₂₀ or COR₁₆.

Or R₉, R₁₀, R₁₁ and R₁₂ for example independently of each other are hydrogen, C₁-C₂₀ alkyl, unsubstituted phenyl or phenyl substituted by one or more C₁-C₆ alkyl, halogen, OR₁₇ or by SR₁₈; or R₉, R₁₀, R₁₁, and R₁₂ independently of each other are halogen, OR₁₇, COR₁₆ or NR₁₉R₂₀.

Preferably R₉, R₁₁ and R₁₂ are hydrogen and R₁₀ is hydrogen, OR₁₇ or COR₁₆.

R₁₃ is for example C₁-C₂₀ alkyl which is unsubstituted or substituted by one or more halogen, COOR₁₇ or by CONR₁₉R₂₀; or R₁₃ is C₂-C₂₀ alkyl which is interrupted by one or more O, S, SO, SO₂, NR₂₆ or CO, or is C₂-C₁₂ alkenyl which optionally is interrupted by one or more O, CO or NR₂₆, or R₁₃ is C₃-C₁₀ cycloalkyl which optionally is interrupted by one or more O, S, CO, NR₂₆, or R₁₃ is phenyl or naphthyl both of which are unsubstituted or substituted by one or more OR₁₇, SR₁₈, NR₁₉R₂₀,

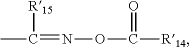

COR₁₆, NO₂, halogen, C₁-C₂₀ alkyl, C₁-C₄ haloalkyl, C₂-C₂₀ alkyl which is interrupted by one or more O; or is C₁-C₂₀ alkyl which is unsubstituted or substituted by one or more halogen, R₁₇, COOR₁₇, OR₁₇, SR₁₈, CONR₁₉R₂₀ or by PO(OCₖH₂ₖ₊₁)₂; or is C₂-C₂₀ alkyl which is interrupted by one or more O.

Further R₁₃ for example is C₁-C₂₀ alkyl which is unsubstituted or substituted by one or more halogen, R₁₇, COOR₁₇, OR₁₇, SR₁₈, CONR₁₉R₂₀ or by PO(OCₖH₂ₖ₊₁)₂, or is C₂-C₂₀ alkyl which is interrupted by one or more O, or is C₂-C₁₂ alkenyl, C₃-C₁₀ cycloalkyl, or R₁₃ is phenyl or naphthyl both of which are unsubstituted or substituted by one or more OR₁₇, SR₁₈, NR₁₉R₂₀,

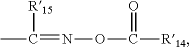

COR₁₆, NO₂, halogen, C₁-C₂₀ alkyl, C₁-C₄ haloalkyl, C₂-C₂₀ alkyl which is interrupted by one or more O.

In another embodiment R₁₃ for example is C₁-C₂₀ alkyl which is unsubstituted or substituted by one or more halogen, R₁₇, OR₁₇, SR₁₈, or by PO(OCₖH₂ₖ₊₁)₂, or is C₂-C₂₀ alkyl which is interrupted by one or more O, or is C₂-C₁₂ alkenyl, C₃-C₁₀ cycloalkyl, phenyl or naphthyl.

Or R₁₃ for example is C₁-C₂₀alkyl which is unsubstituted or substituted by one or more halogen, R₁₇, OR₁₇, SR₁₈, or by PO(OCₖH₂ₖ₊₁)₂, or is C₂-C₂₀ alkyl which is interrupted by one or more O, or is phenyl, C₂-C₁₂ alkenyl, or C₃-C₁₀ cycloalkyl.

Or R₁₃ for example is C₁-C₂₀ alkyl, phenyl, C₂-C₁₂ alkenyl, or C₃-C₁₀ cycloalkyl.

Or R₁₃ for example is C₁-C₂₀ alkyl, C₂-C₁₂ alkenyl, or C₃-C₁₀ cycloalkyl.

Preferably R₁₃ is C₁-C₂₀ alkyl, in particular C₁-C₈ alkyl, for example 2-ethylhexyl.

R₁₄ is for example hydrogen, C₃-C₈ cycloalkyl, C₂-C₅ alkenyl, C₁-C₂₀ alkoxy or C₁-C₂₀ alkyl which is unsubstituted or substituted by one or more halogen or phenyl; or R₁₄ is phenyl or naphthyl, both of which are unsubstituted or substituted by one or more C₁-C₆ alkyl, C₁-C₄ haloalkyl, halogen, OR₁₇, SR₁₈ and/or NR₁₉R₂₀; or R₁₄ is C₃-C₅ heteroaryl, for example thienyl, or is C₁-C₈ alkoxy, benzyloxy or phenoxy.

Or R₁₄ is for example C₁-C₂₀ alkyl which is unsubstituted or substituted by one or more halogen or phenyl; or R₁₄ is C₃-C₅ heteroaryl, for example thienyl, or is phenyl which is unsubstituted or substituted by one or more C₁-C₆ alkyl, C₁-C₄ haloalkyl, halogen, OR₁₇, SR₁₈ and/or NR₁₉R₂₀; or R₁₄ is C₁-C₈alkoxy, benzyloxy or phenoxy.

In another embodiment R₁₄ denotes C₁-C₂₀ alkyl which is unsubstituted or substituted by phenyl; or R₁₄ is phenyl which is unsubstituted or substituted by one or more C₁-C₆ alkyl.

Preferably R₁₄ is C₁-C₂₀ alkyl, C₃-C₅ heteroaryl, for example thienyl, or is phenyl, in particular C₁-C₂₀ alkyl or thienyl, especially C₁-C₈ alkyl.

R₁₅ for example is C₆-C₂₀ aryl or C₅-C₂₀ heteroaryl each of which is unsubstituted or substituted by one or more phenyl, halogen, C₁-C₄ haloalkyl, CN, NO₂, OR₁₇, SR₁₈, NR₁₉R₂₀, C₁-C₂₀ alkyl; or R₁₅ is hydrogen, C₃-C₈ cycloalkyl which optionally is interrupted by one or more O, CO, or NR₂₆; or R₁₅ is C₁-C₂₀ alkyl which is unsubstituted or substituted by one or more halogen, OR₁₇, C₃-C₈ cycloalkyl, C₅-C₂₀ heteroaryl, C₈-C₂₀ phenoxycarbonyl, C₅-C₂₀ heteroaryloxy-carbonyl, NR₁₉R₂₀, COOR₁₇, CONR₁₉R₂₀, PO(OCₖH₂ₖ₊₁)₂,

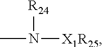

phenyl or by phenyl which is substituted by halogen, C₁-C₂₀ alkyl, C₁-C₄ haloalkyl, OR₁₇ or NR₁₉R₂₀, wherein the unsubstituted or substituted C₁-C₂₀ alkyl; or R₁₅ is C₂-C₂₀ alkyl which is interrupted by one or more O, S or SO₂, or R₁₅ is C₂-C₂₀ alkanoyl, benzoyl, C₂-C₁₂ alkoxycarbonyl, phenoxycarbonyl, CONR₁₉R₂₀, NO₂ or C₁-C₄ haloalkyl.

Further, R₁₅ is for example hydrogen, C₆-C₂₀ aryl, in particular phenyl or naphthyl each of which is unsubstituted or substituted by C₁-C₁₂ alkyl, or is C₃-C₅ heteroaryl, for example thienyl, or is C₃-C₈ cycloalkyl, C₁-C₂₀ alkyl which is unsubstituted or is substituted by one or more OR₁₇, SR₁₇, C₃-C₈-cycloalkyl, NR₁₉R₂₀ or COOR₁₇; or R₁₅ is C₂-C₂₀ alkyl which is interrupted by one or more O or SO₂.

Interesting is the photoinitiator (C-1) represented by Formula (4) wherein R₁₅ for example is hydrogen, phenyl, naphthyl each of which are unsubstituted or substituted by C₁-C₈ alkyl, or is thienyl, C₁-C₂₀ alkyl which is unsubstituted or is substituted by one or more OR₁₇, SR₁₇, C₃-C₈-cycloalkyl, NR₁₉R₂₀ or COOR₁₇; or R₁₅ is C₂-C₂₀ alkyl which is interrupted by one or more O or SO₂.

In particular R₁₅ for example is C₃-C₈ cycloalkyl or C₁-C₂₀ alkyl, in particular C₁-C₂₀ alkyl, especially C₁-C₁₂ alkyl.

Preferences for R′₁₄ and R′₁₅ are as given above for R₁₄ and R₁₅, respectively.

X₁ is for example O, S or SO; e.g. O or S, in particular O.

R₁₆ is for example C₆-C₂₀ aryl, in particular phenyl or naphthyl, especially phenyl, or C₅-C₂₀ heteroaryl, in particular thienyl, each of which is unsubstituted or substituted by one or more phenyl, halogen, C₁-C₄ haloalkyl, CN, NO₂, OR₁₇, SR₁₈, NR₁₉R₂₀, or by C₁-C₂₀ alkyl which is interrupted by one or more O, or each of which is substituted by one or more C₁-C₂₀ alkyl which is unsubstituted or substituted by one or more halogen, COOR₁₇, CONR₁₉R₂₀, phenyl, C₃-C₈ cycloalkyl, C₅-C₂₀ heteroaryl, C₆-C₂₀ aryloxycarbonyl, C₅-C₂₀ heteroaryloxycarbonyl, OR₁₇, SR₁₈ or NR₁₉R₂₀; or R₁₆ is hydrogen, C₁-C₂₀ alkyl which is unsubstituted or substituted by one or more halogen, phenyl, OH, SH, C₃-C₆ alkenoxy, OCH₂CH₂(CO)O(C₁-C₄ alkyl), O(CO)—(C₁-C₄ alkyl), O(CO)-phenyl, (CO)OH or (CO)O(C₁-C₄ alkyl); or R₁₆ is C₂-C₁₂ alkyl which is interrupted by one or more O, or is (CH₂CH₂O)ₙ₊₁H, (CH₂CH₂O)ₙ(CO)—(C₁-C₈ alkyl), C₂-C₁₂ alkenyl or C₃-C₈ cycloalkyl, and n is 1-20, for example 1 to 12 or 1 to 8, in particular 1 or 2.

The more R₁₆ for example is phenyl or naphthyl, especially phenyl, thienyl or carbazole each of which is unsubstituted or substituted by one or more phenyl, halogen, C₁-C₄ haloalkyl, OR₁₇, SR₁₈, NR₁₉R₂₀ or by C₁-C₂₀ alkyl; or R₁₆ is C₁-C₂₀ alkyl which is unsubstituted or substituted by one or more halogen, phenyl, OH, SH, C₃-C₆ alkenoxy, OCH₂CH₂(CO)O(C₁-C₄ alkyl), O(CO)—(C₁-C₄ alkyl), O(CO)-phenyl, (CO)OH or (CO)O(C₁-C₄ alkyl); or R₁₆ is C₂-C₁₂ alkyl which is interrupted by one or more O, or is (CH₂CH₂O)ₙ₊₁H, (CH₂CH₂O)ₙ(CO)—(C₁-C₈ alkyl), C₂-C₁₂ alkenyl or C₃-C₈ cycloalkyl, and n is 1 to 20, for example 1 to 12 or 1 to 8, in particular 1 or 2.

Further R₁₆ for example is phenyl or naphthyl, especially phenyl, each of which is unsubstituted or substituted by one or more phenyl, halogen, C₁-C₄ haloalkyl, OR₁₇, SR₁₈, NR₁₉R₂₀ or by C₁-C₂₀ alkyl; or R₁₆ is C₃-C₅ heteroaryl, especially thienyl.

In particular R₁₆ for example is phenyl which is unsubstituted or substituted by one or more OR₁₇, SR₁₈, NR₁₉R₂₀ or by C₁-C₂₀ alkyl, or R₁₆ is thienyl.

Preferably R₁₆ for example is phenyl or naphthyl each of which is unsubstituted or substituted by one or more C₁-C₂₀ alkyl.

Especially R₁₆ is phenyl which is substituted by one or more or C₁-C₂₀ alkyl.

R₁₇ for example is hydrogen, phenyl-C₁-C₃ alkyl, C₁-C₂₀ alkyl which is unsubstituted or substituted by one or more halogen, OH, OCH₂CH₂(CO)O(C₁-C₄ alkyl), O(CO)—(C₁-C₄ alkyl), O(CO)—(C₂-C₄)alkenyl, O(CO)-phenyl, (CO)OH, (CO)O(C₁-C₄ alkyl), C₃-C₂₀ cycloalkyl, or by C₃-C₂₀ cycloalkyl which is interrupted by one or more O; or R₁₇ is C₂-C₂₀ alkyl which is interrupted by one or more O; is (CH₂CH₂O)ₙ+1H, (CH₂CH₂O)ₙ(CO)—(C₁-C₈ alkyl), C₁-C₈ alkanoyl, C₂-C₁₂ alkenyl, C₃-C₆ alkenoyl, or C₃-C₂₀ cycloalkyl which optionally is interrupted by one or more O; or R₁₇ is benzoyl which is unsubstituted or substituted by one or more C₁-C₆ alkyl, halogen, OH or C₁-C₃ alkoxy; or R₁₇ is phenyl, naphthyl or C₅-C₂₀ heteroaryl, each of which is unsubstituted or substituted by one or more halogen, OH, C₁-C₁₂ alkyl, C₁-C₁₂ alkoxy, CN, NO₂, phenyl-C₁-C₃ alkyloxy, phenoxy, C₁-C₁₂ alkylsulfanyl, phenylsulfanyl, N(C₁-C₁₂ alkyl)₂, diphenylamino or

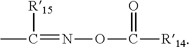

In another embodiment R₁₇ for example is hydrogen, phenyl-C₁-C₃ alkyl, C₁-C₂₀ alkyl which is unsubstituted or substituted by one or more halogen, O(CO)—(C₁-C₄ alkyl), O(CO)—(C₂-C₄ alkenyl) or by C₂-C₂₀ alkyl which is interrupted by one or more O; or is C₁-C₈ alkanoyl, C₂-C₁₂ alkenyl, C₃-C₆ alkenoyl, C₂-C₂₀ alkyl which is interrupted by one or more O, C₃-C₂₀ cycloalkyl which optionally is interrupted by one or more O; or is benzoyl which is unsubstituted or substituted by one or more C₁-C₆ alkyl, halogen, OH or C₁-C₃ alkoxy; or is phenyl or naphthyl each of which is unsubstituted or substituted by one or more halogen, C₁-C₁₂ alkyl or C₁-C₁₂ alkoxy.

R₁₇ for example also is hydrogen, phenyl-C₁-C₃ alkyl, C₁-C₈ alkanoyl, C₁-C₂₀ alkyl which is unsubstituted or is substituted by one or more halogen, C₃-C₂₀ cycloalkyl, O(CO)—(C₁-C₄ alkyl), O(CO)—(C₂-C₄ alkenyl) or by C₂-C₂₀ alkyl which is interrupted by one or more O, or R₁₇ is C₂-C₂₀ alkyl which is interrupted by one or more O.

In particular R₁₇ is hydrogen, C₁-C₈ alkanoyl, C₁-C₂₀ alkyl which is unsubstituted or substituted by one or more O(CO)—(C₁-C₄ alkyl), O(CO)—(C₂-C₄ alkenyl) or by C₂-C₂₀ alkyl which is interrupted by one or more O, or R₁₇ is C₂-C₂₀ alkyl which is interrupted by one or more O.

R₁₈ for example is C₃-C₂₀ cycloalkyl which is uninterrupted or interrupted by one or more O; or R₁₈ is C₁-C₂₀ alkyl which is unsubstituted or is substituted by one or more OH, O(CO)—(C₂-C₄)alkenyl, O(CO)—(C₁-C₄ alkyl) or (CO)OR₁₇; or R₁₈ is C₂-C₂₀ alkyl which is interrupted by one or more O, S, CO, NR₂₆ or COOR₁₇; or R₁₈ is C₂-C₈ alkanoyl or C₃-C₆ alkenoyl, benzoyl; or R₁₈ is phenyl, naphthyl or C₃-C₂₀ heteroaryl, each of which is unsubstituted or substituted by one or more halogen, C₁-C₁₂ alkyl, C₁-C₄ haloalkyl, C₁-C₁₂ alkoxy or NO₂.

In another embodiment R₁₈ is for example C₃-C₂₀ cycloalkyl, C₁-C₂₀ alkyl which is unsubstituted or is substituted by one or more OH, O(CO)—(C₂-C₄)alkenyl, O(CO)—(C₁-C₄ alkyl) or (CO)OR₁₇; or R₁₈ is phenyl or naphthyl each of which is unsubstituted or substituted by one or more halogen or C₁-C₁₂ alkyl, in particular by halogen.

R₁₈ for example is C₁-C₂₀ alkyl, C₂-C₁₂ alkenyl, C₃-C₂₀ cycloalkyl, phenyl-C₁-C₃ alkyl, C₂-C₈ alkanoyl, benzoyl, phenyl or naphthyl.

For example R₁₈ is C₁-C₂₀ alkyl which is substituted by one or more OH, O(CO)—(C₂-C₄)alkenyl, O(CO)—(C₁-C₄ alkyl) or (CO)OR₁₇, or Rₛ₁ is phenyl which is substituted by one or more halogen.

Preferably Rₛ₁ is C₁-C₈ alkyl which is substituted as defined above.

R₁₉ and R₂₀ for example independently of each other are hydrogen, C₁-C₂₀ alkyl, C₂-C₄ hydroxyalkyl, C₃-C₂₀ cycloalkyl, phenyl-C₁-C₃ alkyl, phenyl or naphthyl, C₁-C₈ alkanoyl, C₁-C₈ alkanoyloxy, C₃-C₁₂ alkenoyl or benzoyl; or R₁₉ and R₂₀ together with the N-atom to which they are attached form a 5- or 6-membered saturated or unsaturated ring which optionally is interrupted by O, S or NR₁₇; or R₁₉ and R₂₀ together with the N-atom to which they are attached form a heteroaromatic ring system which is unsubstituted or substituted by one or more C₁-C₂₀ alkyl, C₁-C₄ haloalkyl, or

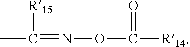

Furthermore R₁₉ and R₂₀ for example independently of each other are hydrogen, C₁-C₂₀ alkyl, C₂-C₄ hydroxyalkyl, C₃-C₂₀ cycloalkyl, phenyl-C₁-C₃ alkyl, C₁-C₈ alkanoyl, C₁-C₈ alkanoyloxy, C₃-C₁₂ alkenoyl or benzoyl; or R₁₉ and R₂₀ together with the N-atom to which they are attached form a 5- or 6-membered saturated ring which optionally is interrupted by O or NR₁₇; or R₁₉ and R₂₀ together with the N-atom to which they are attached form a carbazole ring.

R₁₉ and R₂₀ for example independently of each other are hydrogen, C₁-C₂₀ alkyl, C₂-C₄ hydroxyalkyl, C₃-C₂₀ cycloalkyl, phenyl-C₁-C₃ alkyl, C₁-C₈ alkanoyl, C₁-C₈ alkanoyloxy, C₃-C₁₂ alkenoyl or benzoyl; or R₁₉ and R₂₀ together with the N-atom to which they are attached form a 5- or 6-membered saturated ring which optionally is interrupted by O or NR₁₇.

Preferably R₁₉ and R₂₀ independently of each other are C₁-C₈ alkanoyl, C₁-C₈ alkanoyloxy; or R₁₉ and R₂₀ together with the N-atom to which they are attached form a morpholino ring.

R₂₁ and R₂₂ for example independently of each other are hydrogen, C₁-C₂₀ alkyl, C₁-C₄ haloalkyl, C₃-C₁₀ cycloalkyl or phenyl; or R₂₁ and R₂₂ together with the N-atom to which they are attached form a morpholino ring.

Especially R₂₁ and R₂₂ independently of each other are hydrogen or C₁-C₂₀ alkyl.

R₂₃ is for example hydrogen, OH, phenyl or C₁-C₂₀ alkyl. In particular R₂₃ is hydrogen, OH or C₁-C₄ alkyl.

The preferences for R₂₄ are as given for R₁₉ and R₂₀.

The preferences for R₂₅ are as given for R₁₇.

R₂₆ for example is hydrogen, C₁-C₂₀ alkyl, C₁-C₄ haloalkyl, C₂-C₂₀ alkyl which is interrupted by one or more O or CO, or is phenyl-C₁-C₄ alkyl, C₃-C₈ cycloalkyl which optionally is interrupted by one or more O or CO, or is (CO)R₁₉ or phenyl which is unsubstituted or substituted by one or more C₁-C₂₀ alkyl, halogen, C₁-C₄ haloalkyl, OR₁₇, SR₁₈, NR₁₉R₂₀.

Or R₂₆ for example denotes hydrogen, C₁-C₂₀ alkyl, C₁-C₄ haloalkyl, phenyl-C₁-C₄ alkyl, C₃-C₈ cycloalkyl, (CO)R₁₉ or phenyl which is unsubstituted or substituted by one or more C₁-C₂₀ alkyl. Further R₂₆ for example is hydrogen or C₁-C₂₀ alkyl, in particular C₁-C₄ alkyl.

Examples of the photoinitiator (C-1) represented by Formula (4) of the present invention are

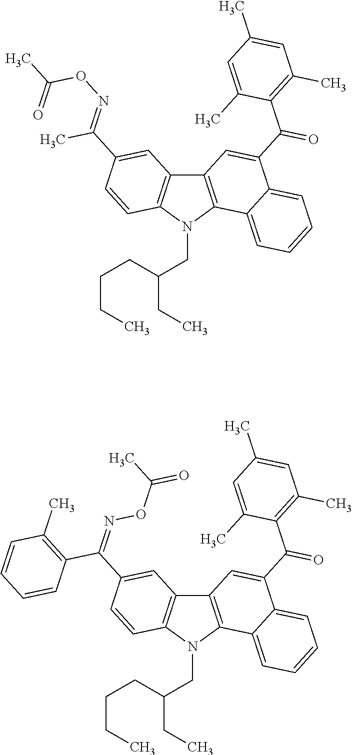 [SMILES: CCCCC(CC)Cn1c2ccc(/C(C)=N/OC(C)=O)cc2c2cc(C(=O)c3c(C)cc(C)cc3C)c3ccccc3c21 ; CCCCC(CC)Cn1c2ccc(/C(=N\OC(C)=O)c3ccccc3C)cc2c2cc(C(=O)c3c(C)cc(C)cc3C)c3ccccc3c21]

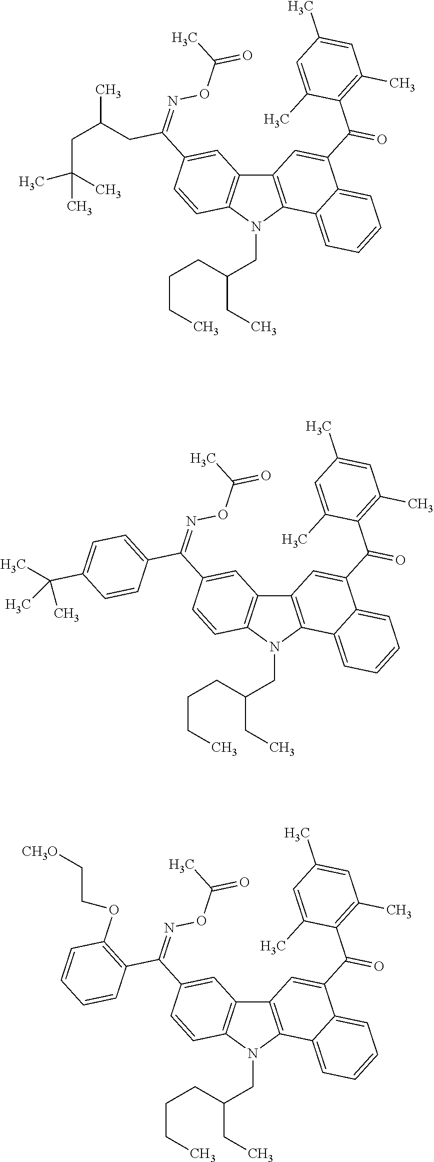

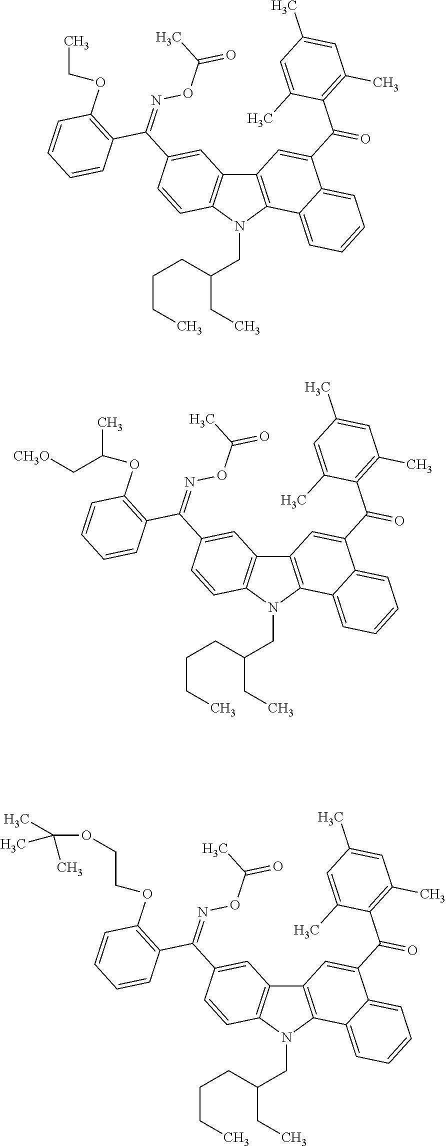

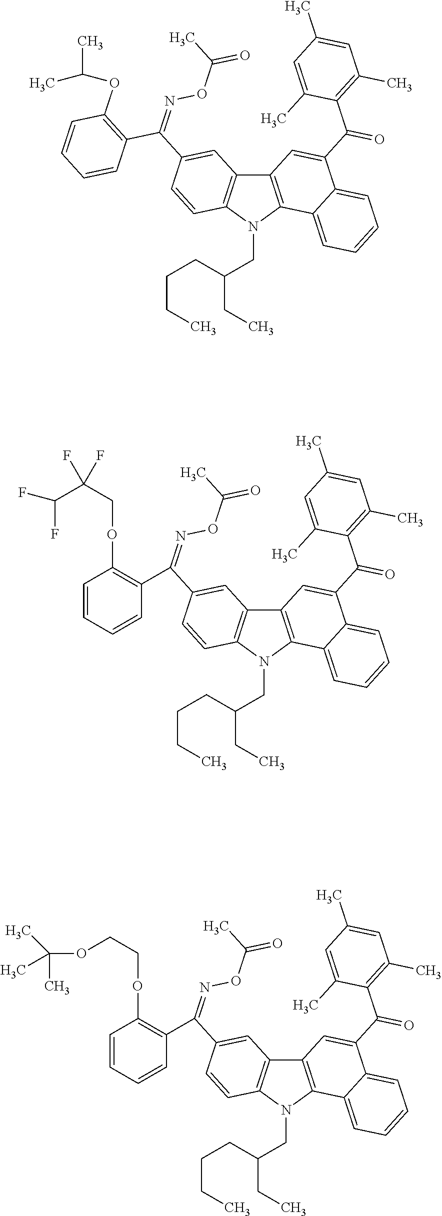

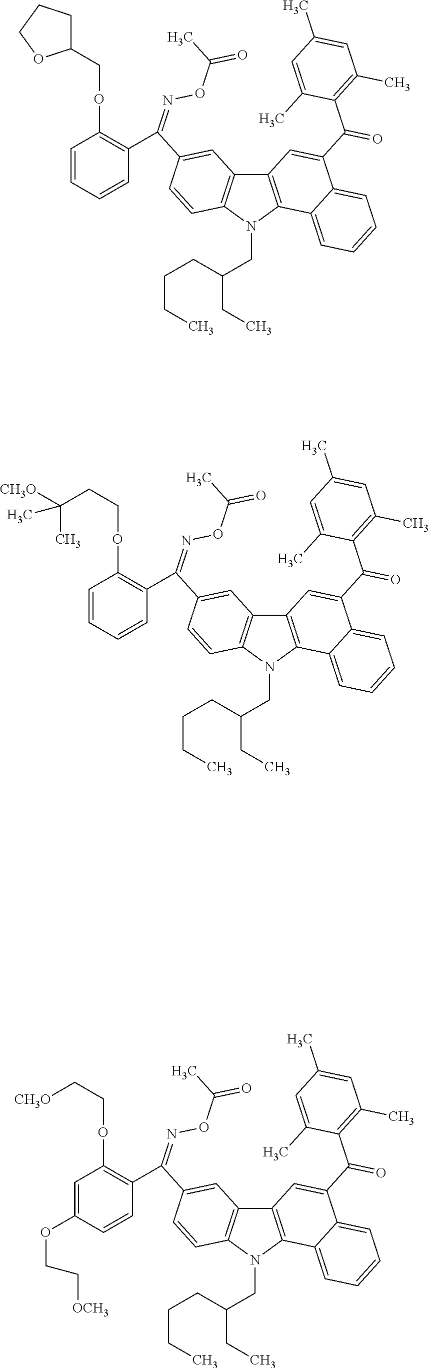

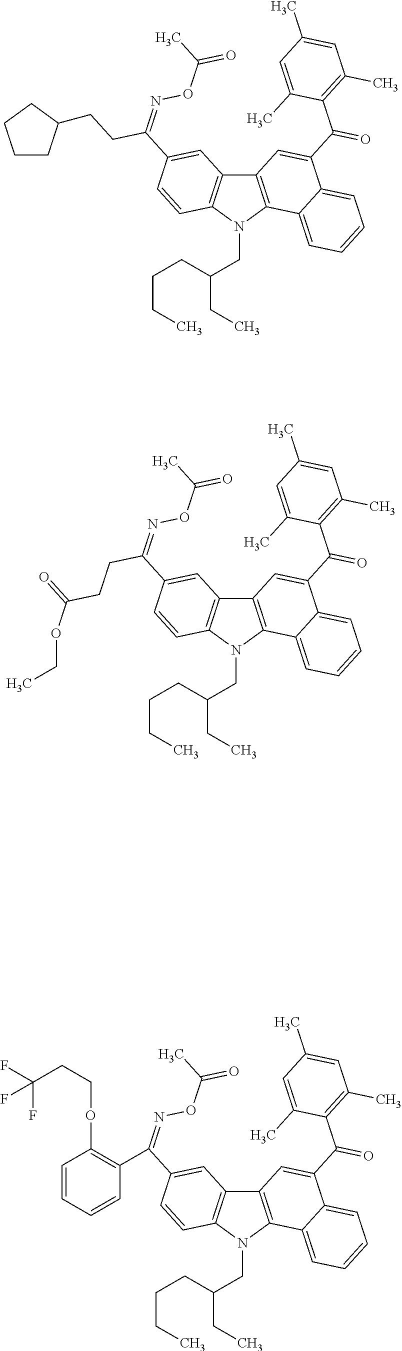

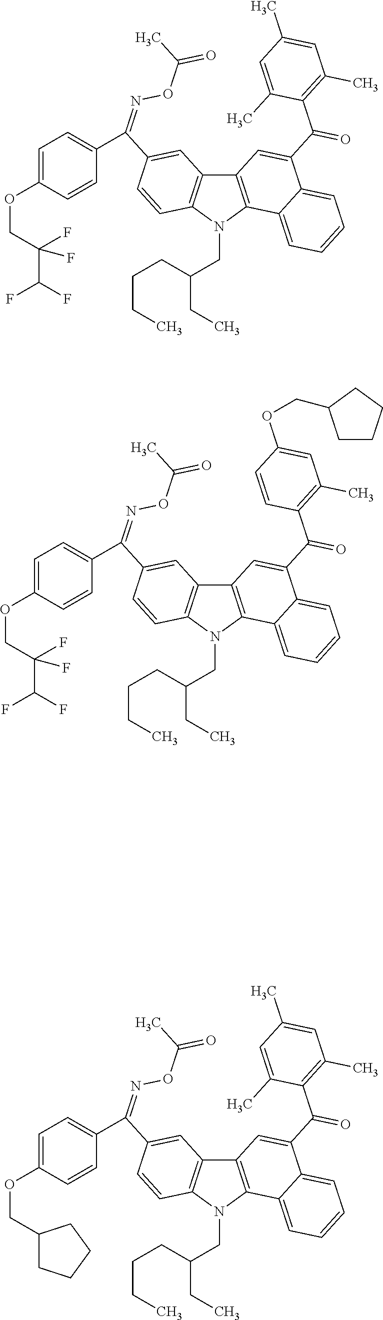 [SMILES: CCCCC(CC)Cn1c2ccc(/C(=N\OC(C)=O)c3ccc(OCC(F)(F)C(F)F)cc3)cc2c2cc(C(=O)c3c(C)cc(C)cc3C)c3ccccc3c21 ; CCCCC(CC)Cn1c2ccc(/C(=N\OC(C)=O)c3ccc(OCC(F)(F)C(F)F)cc3)cc2c2cc(C(=O)c3ccc(OCC4CCCC4)cc3C)c3ccccc3c21 ; CCCCC(CC)Cn1c2ccc(/C(=N\OC(C)=O)c3ccc(OCC4CCCC4)cc3)cc2c2cc(C(=O)c3c(C)cc(C)cc3C)c3ccccc3c21]

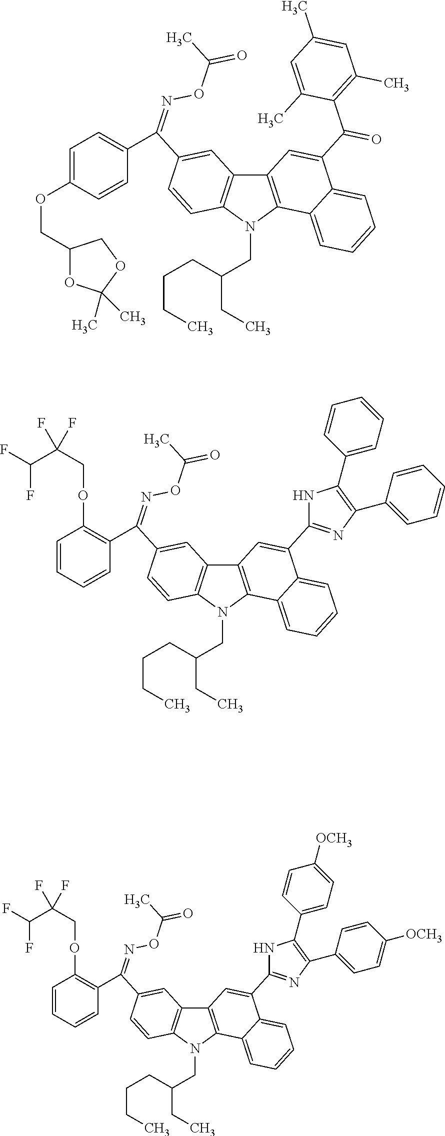 [SMILES: CCCCC(CC)Cn1c2ccc(/C(=N\OC(C)=O)c3ccc(OCC4COC(C)(C)O4)cc3)cc2c2cc(C(=O)c3c(C)cc(C)cc3C)c3ccccc3c21 ; CCCCC(CC)Cn1c2ccc(/C(=N\OC(C)=O)c3ccccc3OCC(F)(F)C(F)F)cc2c2cc(-c3nc(-c4ccccc4)c(-c4ccccc4)[nH]3)c3ccccc3c21 ; CCCCC(CC)Cn1c2ccc(/C(=N\OC(C)=O)c3ccccc3OCC(F)(F)C(F)F)cc2c2cc(-c3nc(-c4ccc(OC)cc4)c(-c4ccc(OC)cc4)[nH]3)c3ccccc3c21]

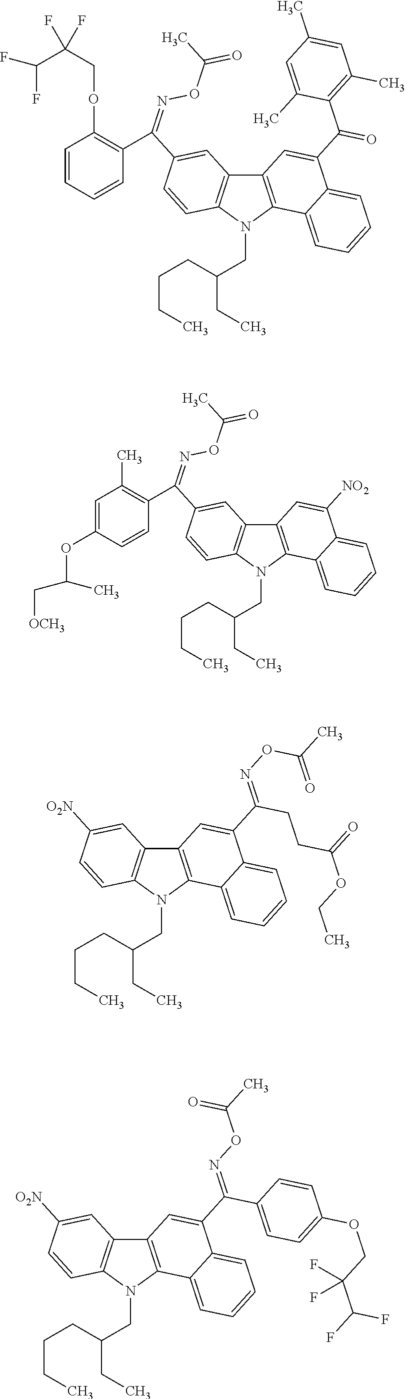 [SMILES: CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21 ; CCCCC(CC)Cn1c2ccc(/C(=N\OC(C)=O)c3ccc(OC(C)COC)cc3C)cc2c2cc([N+](=O)[O-])c3ccccc3c21 ; CCCCC(CC)Cn1c2ccc([N+](=O)[O-])cc2c2cc(/C(CCC(=O)OCC)=N/OC(C)=O)c3ccccc3c21 ; CCCCC(CC)Cn1c2ccc([N+](=O)[O-])cc2c2cc(/C(=N/OC(C)=O)c3ccc(OCC(F)(F)C(F)F)cc3)c3ccccc3c21]

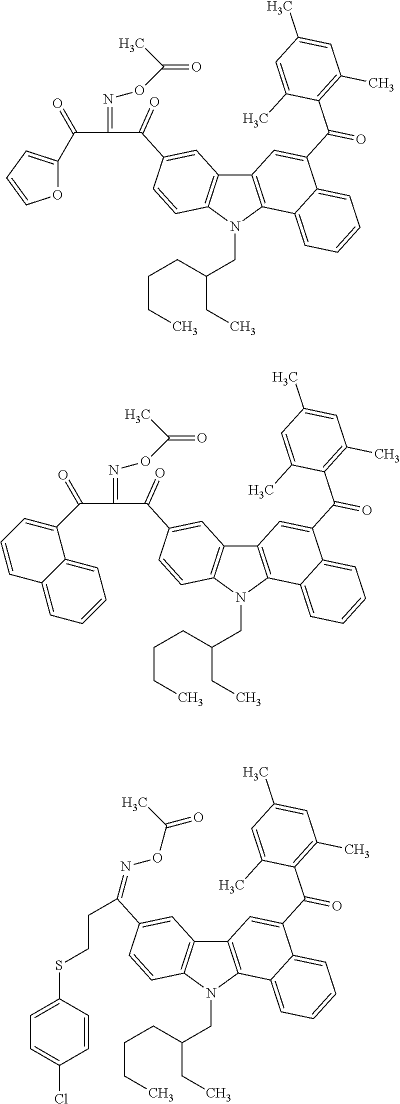 [SMILES: CCCCC(CC)Cn1c2ccc(C(=O)/C(=N\OC(C)=O)C(=O)c3ccco3)cc2c2cc(C(=O)c3c(C)cc(C)cc3C)c3ccccc3c21 ; CCCCC(CC)Cn1c2ccc(C(=O)/C(=N\OC(C)=O)C(=O)c3cccc4ccccc34)cc2c2cc(C(=O)c3c(C)cc(C)cc3C)c3ccccc3c21 ; CCCCC(CC)Cn1c2ccc(/C(CCSc3ccc(Cl)cc3)=N\OC(C)=O)cc2c2cc(C(=O)c3c(C)cc(C)cc3C)c3ccccc3c21]

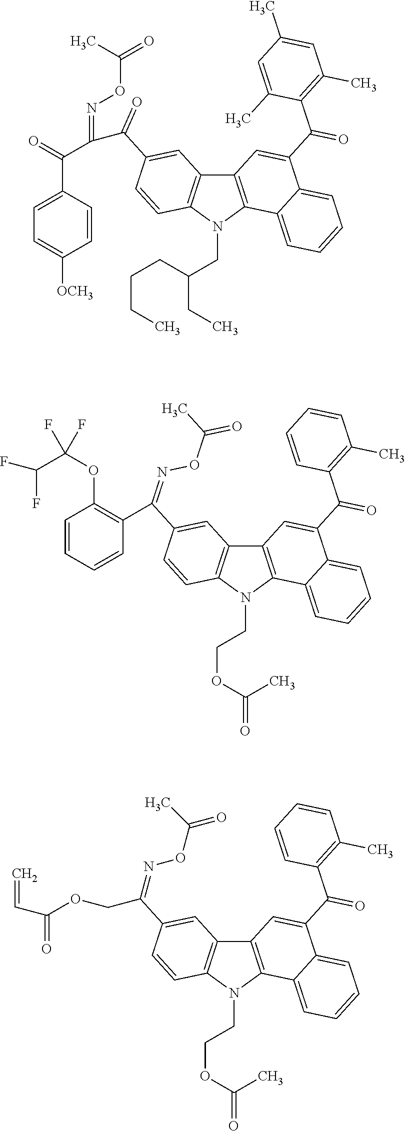 [SMILES: CCCCC(CC)Cn1c2ccc(C(=O)/C(=N\OC(C)=O)C(=O)c3ccc(OC)cc3)cc2c2cc(C(=O)c3c(C)cc(C)cc3C)c3ccccc3c21 ; CC(=O)OCCn1c2ccc(/C(=N\OC(C)=O)c3ccccc3OC(F)(F)C(F)F)cc2c2cc(C(=O)c3ccccc3C)c3ccccc3c21 ; C=CC(=O)OC/C(=N/OC(C)=O)c1ccc2c(c1)c1cc(C(=O)c3ccccc3C)c3ccccc3c1n2CCOC(C)=O]

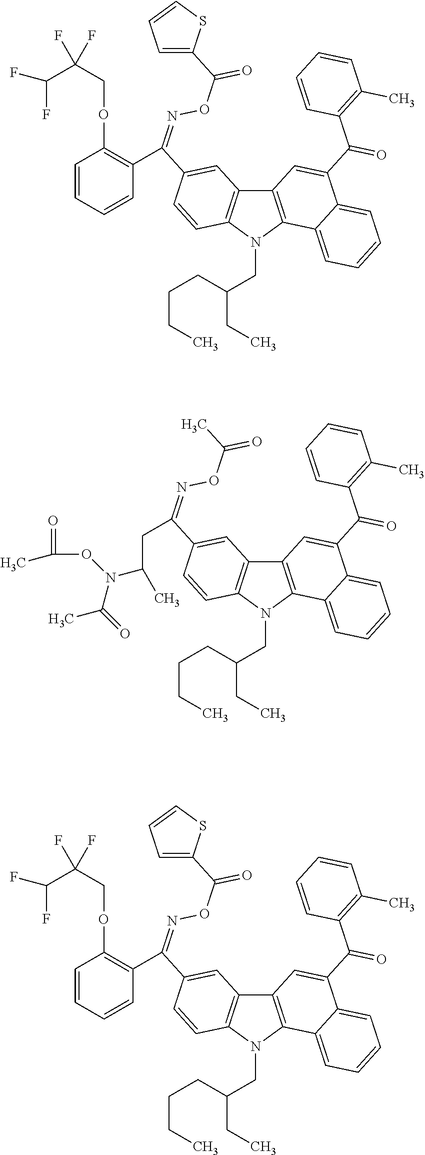

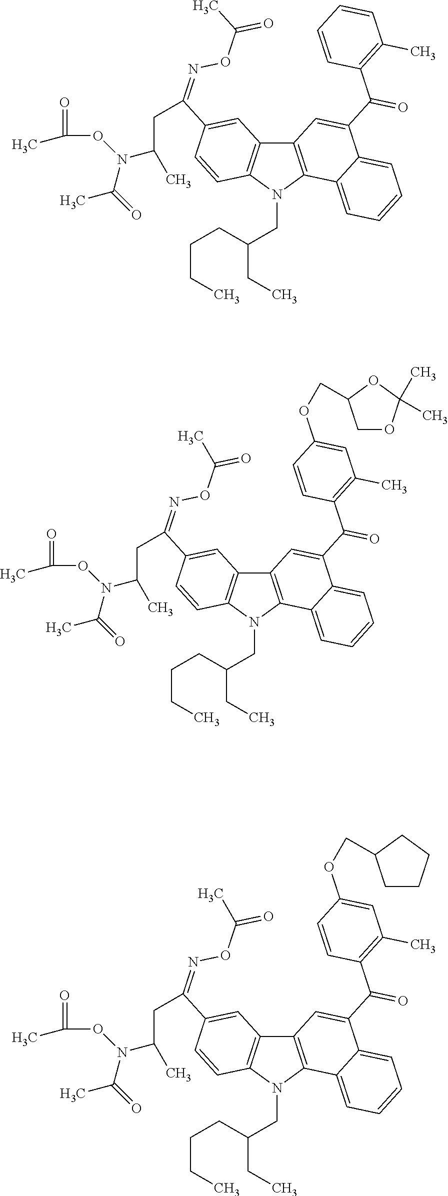

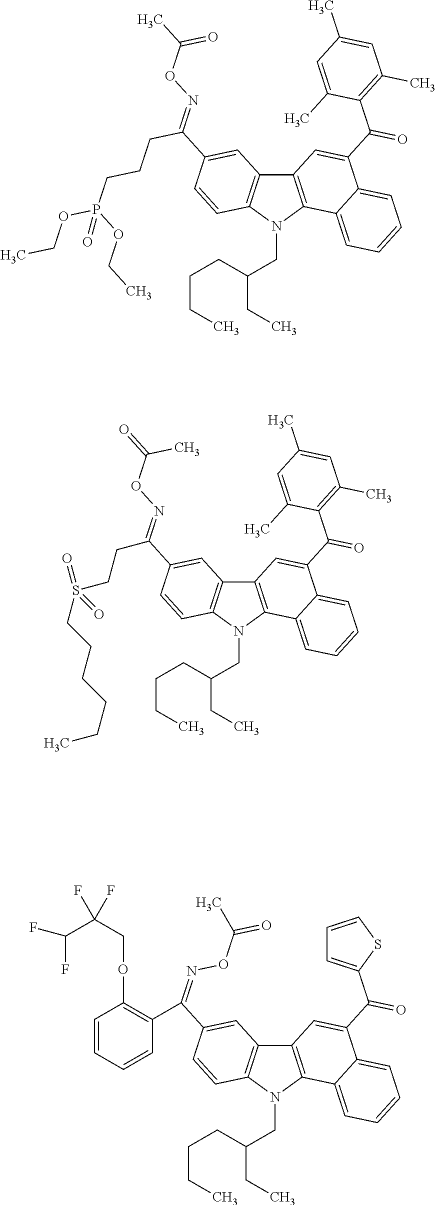

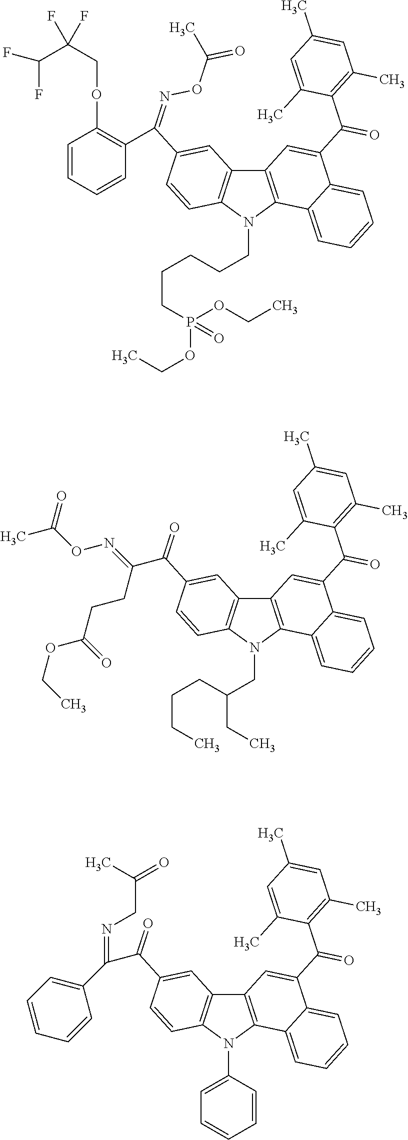

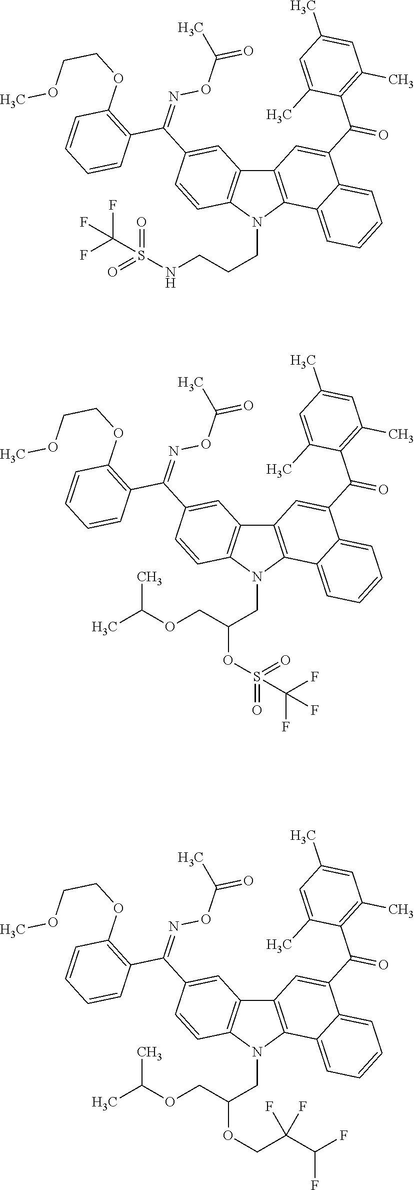

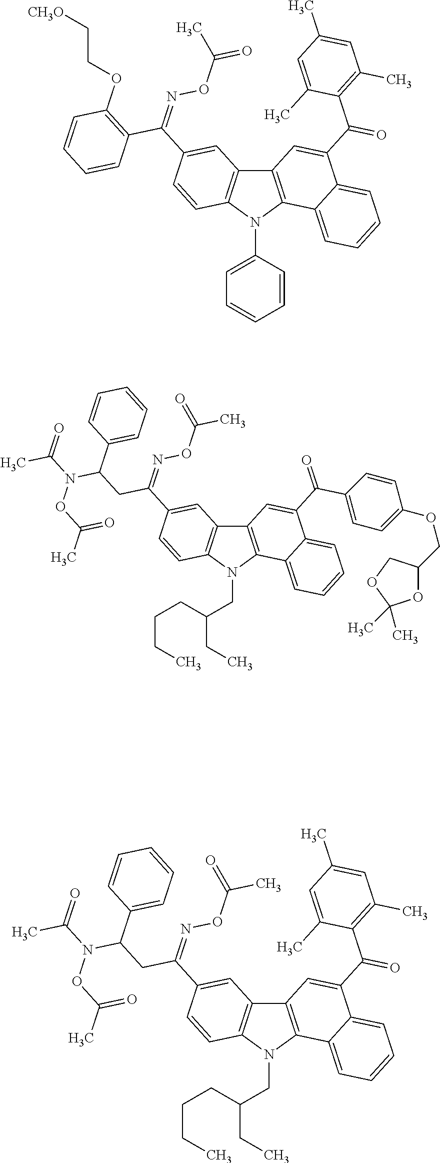

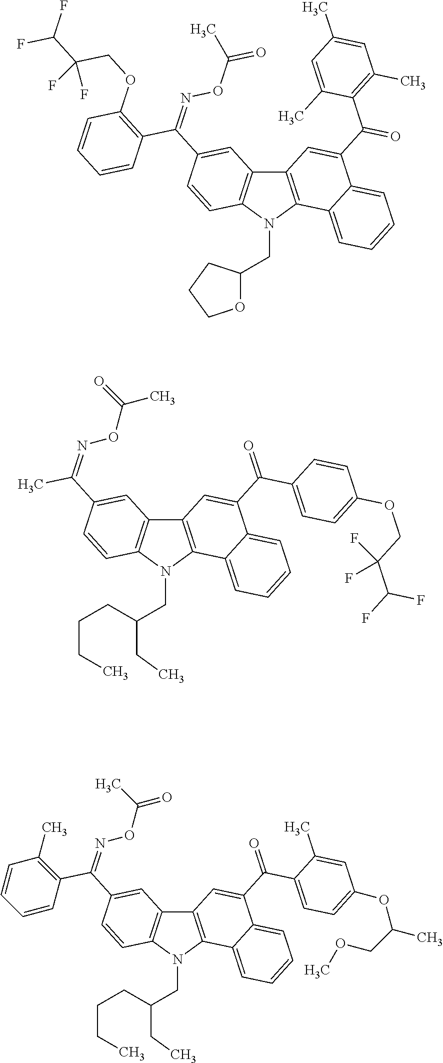

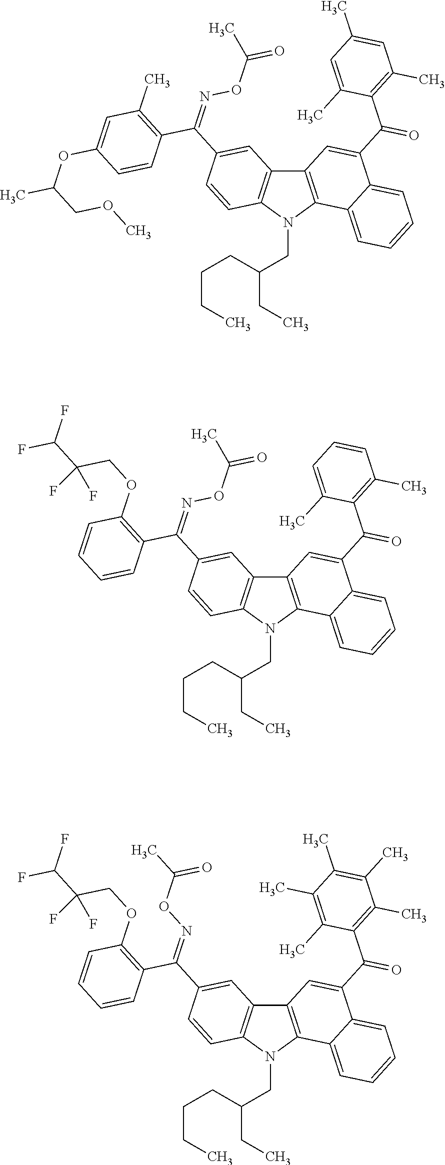 [SMILES: CCCCC(CC)Cn1c2ccc(/C(=N\OC(C)=O)c3ccc(OC(C)COC)cc3C)cc2c2cc(C(=O)c3c(C)cc(C)cc3C)c3ccccc3c21 ; CCCCC(CC)Cn1c2ccc(/C(=N\OC(C)=O)c3ccccc3OCC(F)(F)C(F)F)cc2c2cc(C(=O)c3c(C)cccc3C)c3ccccc3c21 ; CCCCC(CC)Cn1c2ccc(/C(=N/OC(C)=O)c3ccccc3OCC(F)(F)C(F)F)cc2c2cc(C(=O)c3c(C)c(C)c(C)c(C)c3C)c3ccccc3c21]

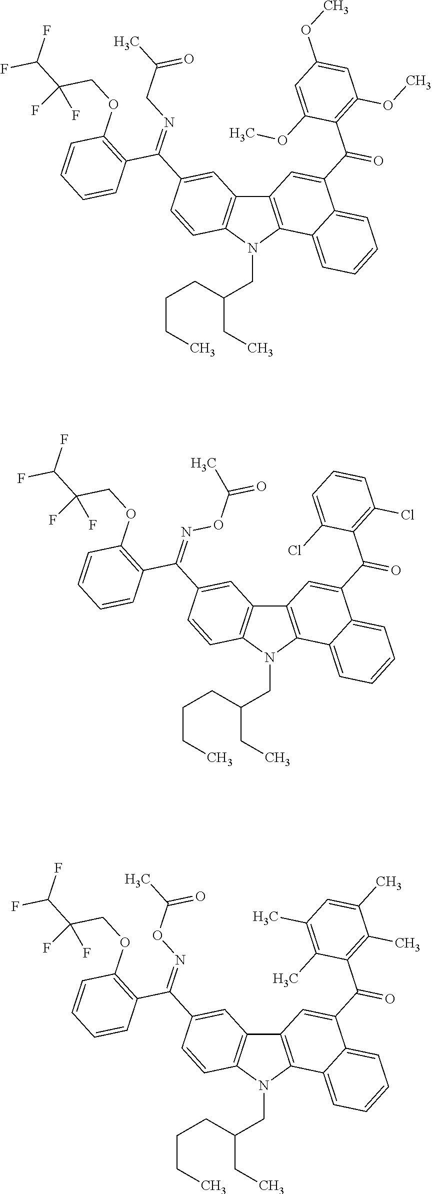 [SMILES: CCCCC(CC)Cn1c2ccc(/C(=N/CC(C)=O)c3ccccc3OCC(F)(F)C(F)F)cc2c2cc(C(=O)c3c(OC)cc(OC)cc3OC)c3ccccc3c21 ; CCCCC(CC)Cn1c2ccc(/C(=N\OC(C)=O)c3ccccc3OCC(F)(F)C(F)F)cc2c2cc(C(=O)c3c(Cl)cccc3Cl)c3ccccc3c21 ; CCCCC(CC)Cn1c2ccc(/C(=N/OC(C)=O)c3ccccc3OCC(F)(F)C(F)F)cc2c2cc(C(=O)c3c(C)c(C)cc(C)c3C)c3ccccc3c21]

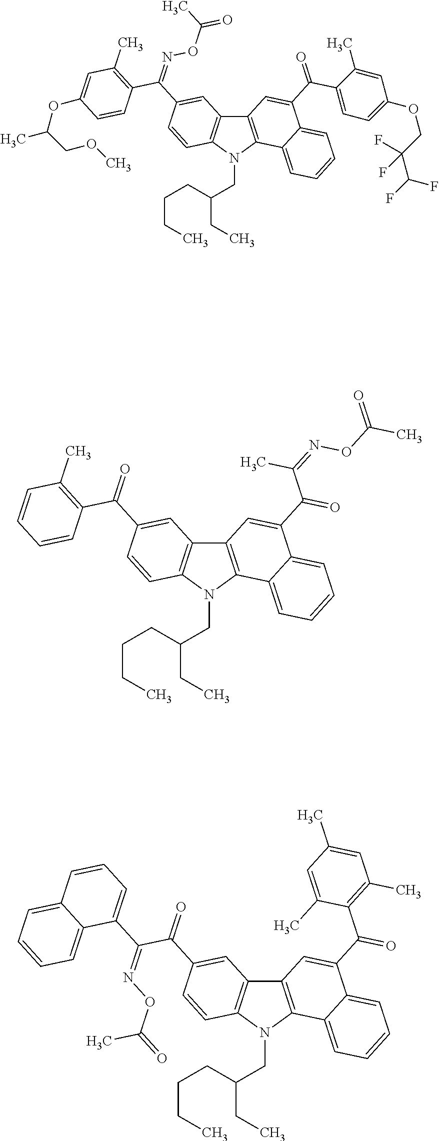 [SMILES: CCCCC(CC)Cn1c2ccc(/C(=N\OC(C)=O)c3ccc(OC(C)COC)cc3C)cc2c2cc(C(=O)c3ccc(OCC(F)(F)C(F)F)cc3C)c3ccccc3c21 ; CCCCC(CC)Cn1c2ccc(C(=O)c3ccccc3C)cc2c2cc(C(=O)/C(C)=N\OC(C)=O)c3ccccc3c21 ; CCCCC(CC)Cn1c2ccc(C(=O)/C(=N\OC(C)=O)c3cccc4ccccc34)cc2c2cc(C(=O)c3c(C)cc(C)cc3C)c3ccccc3c21]

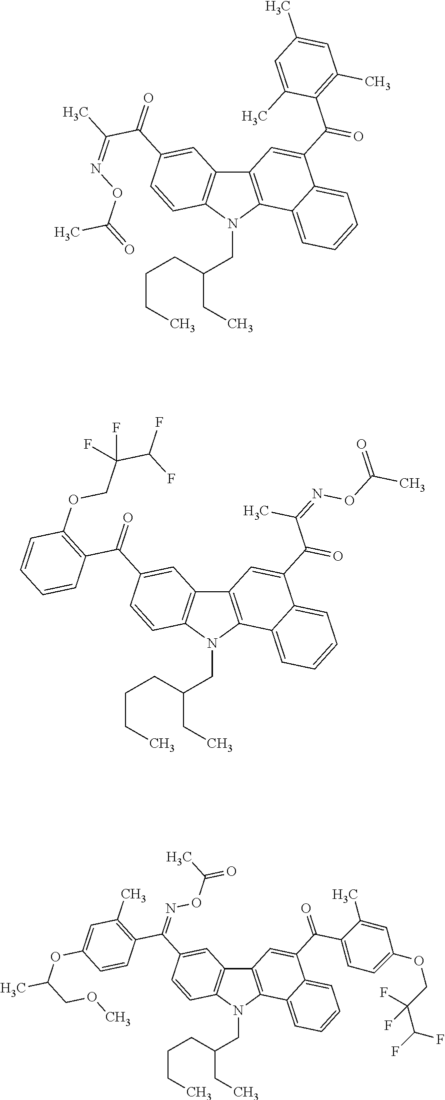

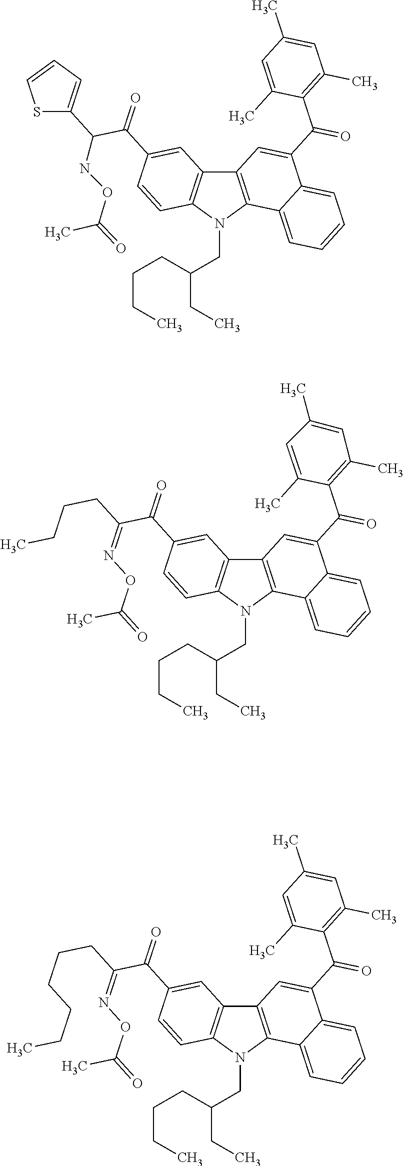

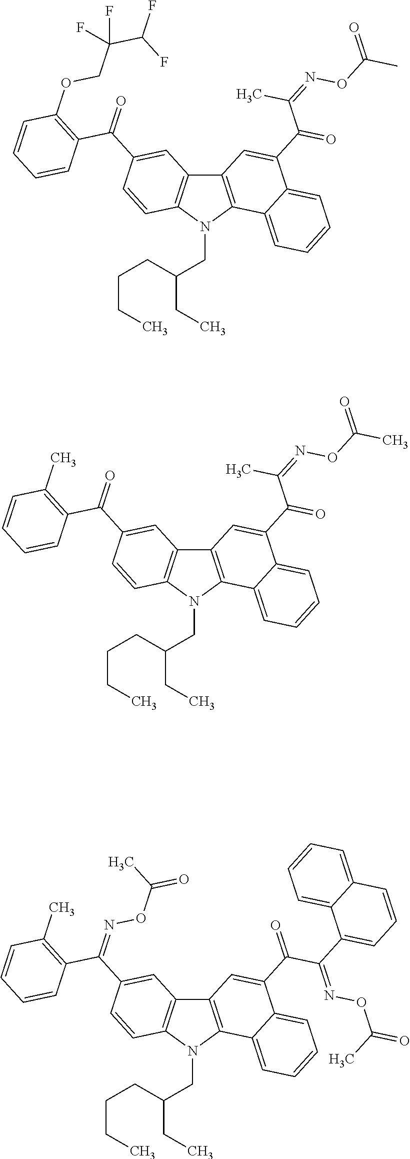 [SMILES: CCCCC(CC)Cn1c2ccc(C(=O)c3ccccc3OCC(F)(F)C(F)F)cc2c2cc(C(=O)/C(C)=N\OC(C)=O)c3ccccc3c21 ; CCCCC(CC)Cn1c2ccc(C(=O)c3ccccc3C)cc2c2cc(C(=O)/C(C)=N\OC(C)=O)c3ccccc3c21 ; CCCCC(CC)Cn1c2ccc(/C(=N\OC(C)=O)c3ccccc3C)cc2c2cc(C(=O)/C(=N/OC(C)=O)c3cccc4ccccc34)c3ccccc3c21]

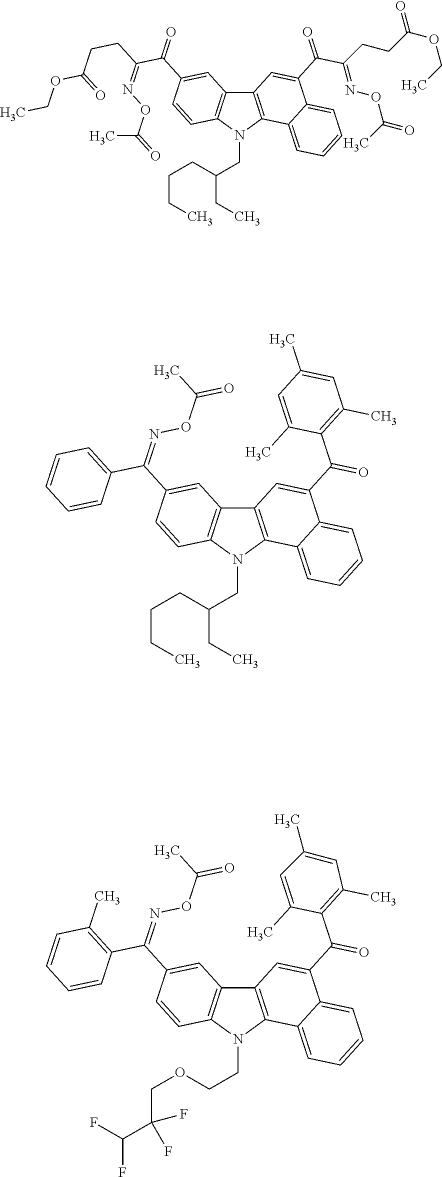 [SMILES: CCCCC(CC)Cn1c2ccc(C(=O)/C(CCC(=O)OCC)=N\OC(C)=O)cc2c2cc(C(=O)/C(CCC(=O)OCC)=N/OC(C)=O)c3ccccc3c21 ; CCCCC(CC)Cn1c2ccc(/C(=N\OC(C)=O)c3ccccc3)cc2c2cc(C(=O)c3c(C)cc(C)cc3C)c3ccccc3c21 ; CC(=O)O/N=C(\c1ccc2c(c1)c1cc(C(=O)c3c(C)cc(C)cc3C)c3ccccc3c1n2CCOCC(F)(F)C(F)F)c1ccccc1C]

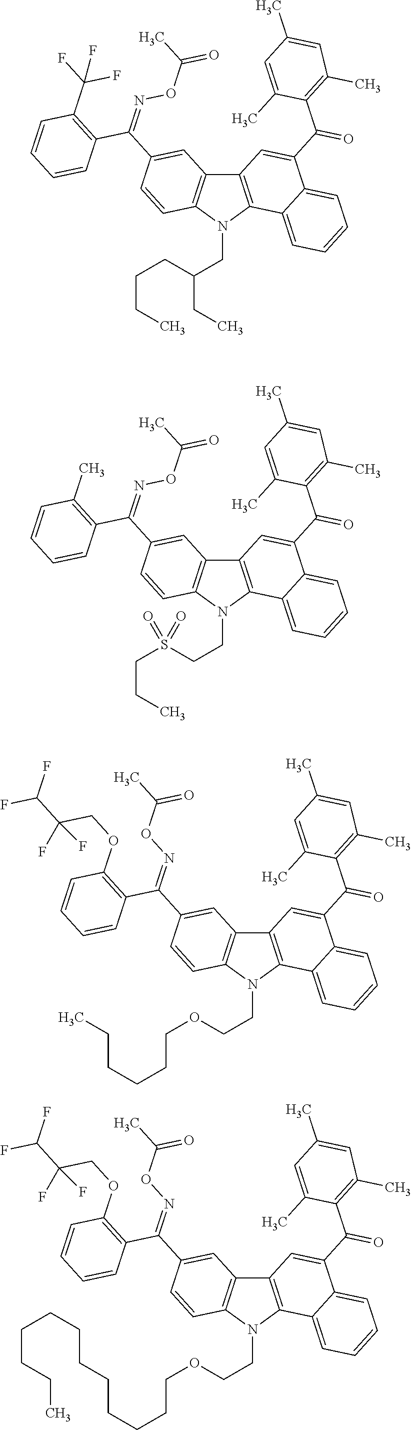

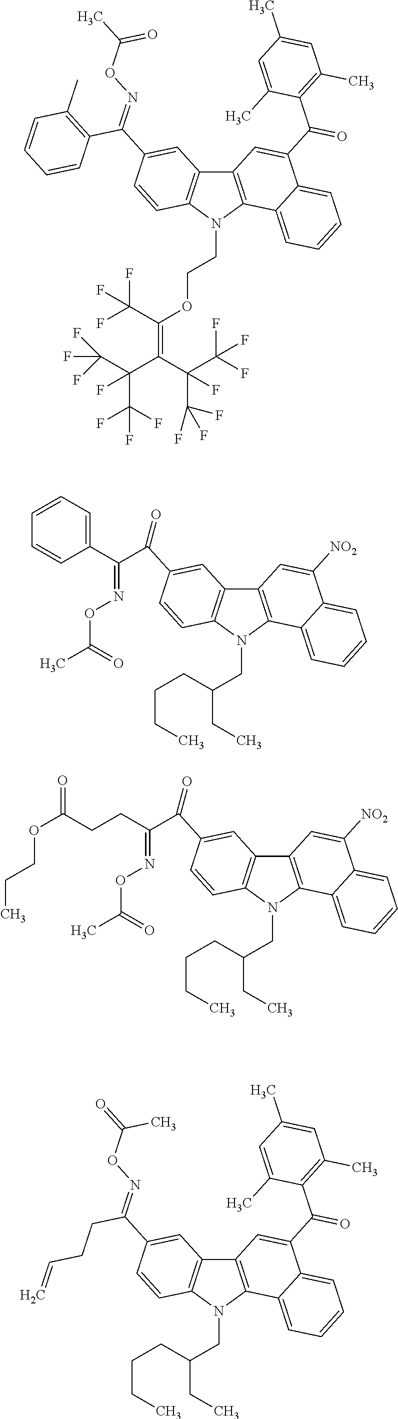

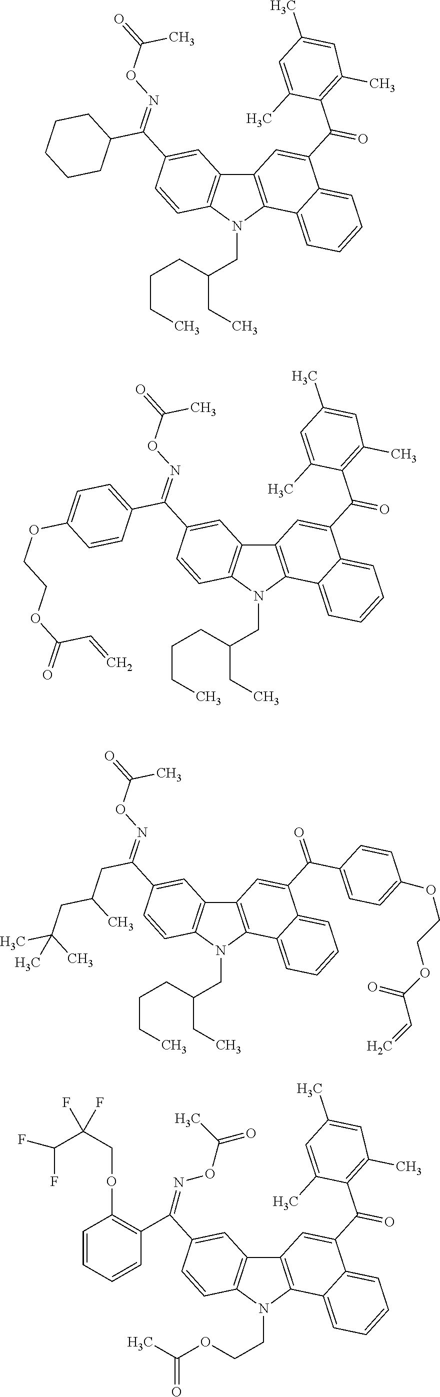

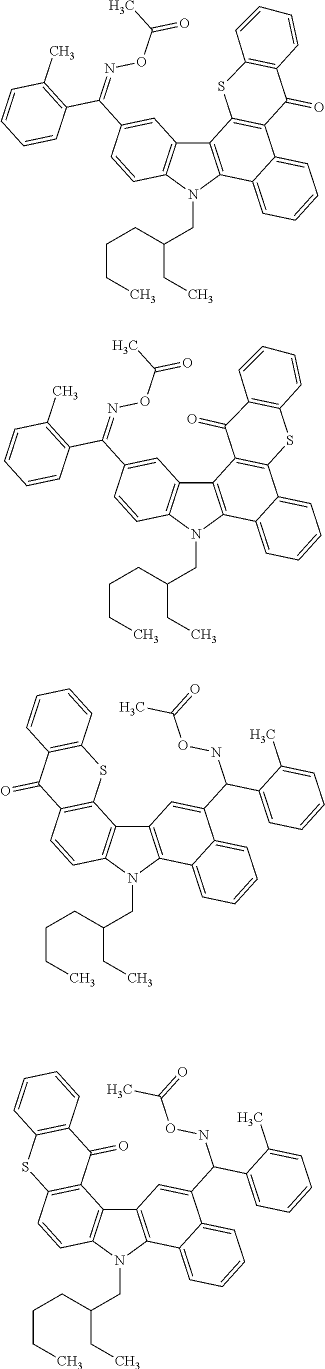 [SMILES: CCCCC(CC)Cn1c2ccc(/C(=N\OC(C)=O)c3ccccc3C)cc2c2c3sc4ccccc4c(=O)c3c3ccccc3c21 ; CCCCC(CC)Cn1c2ccc(/C(=N\OC(C)=O)c3ccccc3C)cc2c2c3c(=O)c4ccccc4sc3c3ccccc3c21 ; CCCCC(CC)Cn1c2ccc3c(=O)c4ccccc4sc3c2c2cc(C(NOC(C)=O)c3ccccc3C)c3ccccc3c21 ; CCCCC(CC)Cn1c2ccc3sc4ccccc4c(=O)c3c2c2cc(C(NOC(C)=O)c3ccccc3C)c3ccccc3c21]

Accordingly, subject of the invention is the use of the photoinitiator (C-1) represented by Formula (4) as defined above for the photopolymerization of a composition comprising at least one ethylenically unsaturated photopolymerizable compound.

Based on 100 parts by weight of the used amount of the alkali-soluble resin (A), the used amount of the photoinitiator (C-1) represented by Formula (4) is from 5 parts by weight to 40 parts by weight, preferably from 7 parts by weight to 35 parts by weight, and more preferably from 10 parts by weight to 30 parts by weight. If the photoinitiator (C-1) represented by Formula (4) is used, the photosensitive resin composition has good linearity of pattern with high finesse.

The photoinitiator (C) may further comprise other photoinitiator (C-2). Examples of the photoinitiator (C-2) include but are not limited to an O-acyloxime compound, a triazine compound, a acetophenone compound, a diimidazole compound, a benzophenone compound, an a-diketone compound, a ketol compound, an acyloin ether compound, an acylphosphine oxide compound, a quinone compound, a halogen-containing compound, peroxide, or any combination of the above-mentioned compounds.

Examples of the O-oxime compound include but are not limited to 1-[4-(phenylthio)phenyl]-heptane-1,2-dione 2-(O-benzoyloxime), 1-[4-(phenylthio)phenyl]-octane-1,2-dione 2-(O-benzoyloxime), 1-[4-(benzoyl)phenyl]-heptane-1,2-dione 2-(O-benzoyloxime), 1-[9-ethyl-6-(2-methylbenzoyl)-9H-carbazol-3-yl]-ethanone 1-(O-acetyloxime), 1-[9-ethyl-6-(3-methylbenzoyl)-9H-carbazol-3-yl]-ethanone 1-(O-acetyloxime), 1-[9-ethyl-6-benzoyl-9H-carbazol-3-yl]-ethanone 1-(O-acetyloxime), ethanone-1-[9-ethyl-6-(2-methyl-4-(tetrahydrofuranyl)benzoyl)-9H-carbazol-3-yl]-1-(O-acetyloxime), ethanone-1-[9-ethyl-6-(2-methyl-4-(tetrahydropyranyl)benzoyl)-9H-carbazol-3-yl]-1-(O-acetyloxime), ethanone-1-[9-ethyl-6-(2-methyl-5-(tetrahydrofuranyl)benzoyl)-9H-carbazol-3-yl]-1-(O-acetyloxime), ethanone-1-[9-ethyl-6-(2-methyl-5-(tetrahydropyranyl)benzoyl)-9H-carbazol-3-yl]-1-(O-acetyloxime), ethanone-1-[9-ethyl-6-(2-methyl-4-(tetrahydrofuranyl)methoxybenzoyl)-9H-carbazol-3-yl]-1-(O-acetyloxime), ethanone-1-[9-ethyl-6-(2-methyl-4-(tetrahydropyranyl)methoxybenzoyl)-9H-carbazol-3-yl]-1-(O-acetyloxime), ethanone-1-[9-ethyl-6-(2-methyl-5-(tetrahydrofuranyl)methoxybenzoyl)-9H-carbazol-3-yl]-1-(O-acetyloxime), ethanone-1-[9-ethyl-6-(2-methyl-5-(tetrahydropyranyl)methoxybenzoyl)-9H-carbazol-3-yl]-1-(O-acetyloxime), ethanone-1-[9-ethyl-6-{2-methyl-4-(2,2-dimethyl-1,3-dioxacyclopentyl)benzoyl}-9H-carbazol-3-yl]-1-(O-acetyloxime), ethanone-1-[9-ethyl-6-{2-methyl-4-(2,2-dimethyl-1,3-dioxacyclopentyl)methoxybenzoyl}-9H-carbazol-3-yl]-1-(O-acetyloxime), or any combination of the above-mentioned compounds.

The O-oxime compound is preferably 1-[4-(phenylthio)phenyl]-octane-1,2-dione-2-(O-benzoyloxime), product name: OXE-01, made by Ciba Specialty Chemicals Co., Ltd., 1-[9-ethyl-6-(2-methylbenzoyl)-9H-carbazol-3-yl]-ethanone 1-(O-acetyloxime), product name: OXE-02, made by Ciba Specialty Chemicals Co., Ltd., ethanone-1-[9-ethyl-6-(2-methyl-4-(tetrahydrofuranyl)methoxybenzoyl)-9H-carbazol-3-yl]-1-(O-acetyloxime), ethanone-1-[9-ethyl-6-{2-methyl-4-(2,2-dimethyl-1,3-dioxacyclopentyl)methoxybenzoyl}-9H-carbazol-3-yl]-1-(O-acetyloxime), or any combination of the above-mentioned compounds. The O-oxime compound may be used alone or in any combination.

Examples of the triazine compound include but are not limited to a vinyl halomethyl-s-triazine compound, a 2-(naphtho-1-yl)-4,6-dihalomethyl-s-triazine compound, a 4-(p-aminophenyl)-2,6-dihalomethyl-s-triazine compound, or a similar compound thereof, or any combination of the above-mentioned compounds.

Examples of the vinyl halomethyl-s-triazine compound include but are not limited to 2,4-bis(trichloromethyl)-6-p-methoxystyryl-s-triazine, 2,4-bis(trichloromethyl)-3-(1-p-dimethylaminophenyl-1,3-butadienyl)-s-triazine, 2-trichloromethyl-3-amino-6-p-methoxystyryl-s-triazine, or a similar compound thereof, or any combination of the above-mentioned compound.

Examples of the 2-(naphtho-1-yl)-4,6-dihalomethyl-s-triazine compound include but are not limited to 2-(naphtho-1-yl)-4,6-bis-trichloromethyl-s-triazine, 2-(4-methoxy-naphtho-1-yl)-4,6-bis-trichloromethyl-s-triazine, 2-(4-ethoxy-naphtho-1-yl)-4,6-bis-trichloromethyl-s-triazine, 2-(4-butoxy-naphtho-1-yl)-4,6-bis-trichloromethyl-s-triazine, 2-(4-(2-methoxyethyl)-naphtho-1-yl)-4,6-bis-trichloromethyl-s-triazine, 2-(4-(2-ethoxyethyl)-naphtho-1-yl)-4,6-bis-trichloromethyl-s-triazine, 2-(4-(2-butoxyethyl)-naphtho-1-yl)-4,6-bis-trichloromethyl-s-triazine, 2-(2-methoxy-naphtho-1-yl)-4,6-bis-trichloromethyl-s-triazine, 2-(6-methoxy-5-methyl-naphtho-2-yl)-4,6-bis-trichloromethyl-s-triazine, 2-(6-methoxynaphtho-2-yl)-4,6-bis-trichloromethyl-s-triazine, 2-(5-methoxy-naphtho-1-yl)-4,6-bis-trichloromethyl-s-triazine, 2-(4,7-dimethoxy-naphtho-1-yl)-4,6-bis-trichloromethyl-s-triazine, 2-(6-ethoxy-naphtho-2-yl)-4,6-bis-trichloromethyl-s-triazine, 2-(4,5-dimethoxy-naphtho-1-yl)-4,6-bis-trichloromethyl-s-triazine, or a similar compound thereof, or any combination of the above-mentioned compounds.

Examples of the 4-(p-aminophenyl)-2,6-dihalomethyl-s-triazine compound include but are not limited to 4-(p-N,N-di(ethoxycarbonylmethyl)aminophenyl)-2,6-di(trichloromethyl)-s-triazine, 4-(o-methyl-p-N,N-di(ethoxycarbonylmethyl)aminophenyl)-2,6-di(trichloromethyl)-s-triazine, 4-(p-N,N-di(chloroethyl)aminophenyl)-2,6-di(trichloromethyl)-s-triazine, 4-(o-methyl-p-N, N-di(chloroethyl)aminophenyl)-2, 6-di(trichloromethyl)-s-triazine, 4-(p-N-chloroethylaminophenyl)-2,6-di(trichloromethyl)-s-triazine, 4-(p-N-ethoxycarbonylmethylaminophenyl)-2,6-di(trichloromethyl)-s-triazine, 4-(p-N,N-di(phenyl)aminophenyl)-2,6-di(trichloromethyl)-s-triazine, 4-(p-N-chloroethylcarbonylaminophenyl)-2,6-di(trichloromethyl)-s-triazine, 4-(p-N-(p-methoxyphenyl)carbonylaminophenyl)-2,6-di(trichloromethyl)-s-triazine, 4-(m-N,N-di(ethoxycarbonylmethyl)aminophenyl)-2, 6-di(trichloromethyl)-s-triazine, 4-(m-bromo-p-N, N-di(ethoxycarbonylmethyl)aminophenyl)-2, 6-di(trichloromethyl)-s-triazine, 4-(m-chloro-p-N,N-di(ethoxycarbonylmethyl)aminophenyl)-2, 6-di(trichloromethyl)-s-triazine, 4-(m-fluoro-p-N,N-di(ethoxycarbonylmethyl)aminophenyl)-2, 6-di(trichloromethyl)-s-triazine, 4-(o-bromo-p-N,N-di(ethoxycarbonylmethyl)aminophenyl)-2,6-di(trichloromethyl)-s-triazine, 4-(o-chloro-p-N,N-di(ethoxycarbonylmethyl)aminophenyl)-2,6-di(trichloromethyl)-s-triazine, 4-(o-fluoro-p-N,N-di(ethoxycarbonylmethyl)aminophenyl)-2,6-di(trichloromethyl)-s-triazine, 4-(o-bromo-p-N,N-di(chloroethyl)aminophenyl)-2,6-di(trichloromethyl)-s-triazine, 4-(o-chloro-p-N,N-di(chloroethyl)aminophenyl)-2,6-di(trichloromethyl)-s-triazine, 4-(o-fluoro-p-N,N-di(chloroethyl)aminophenyl)-2,6-di(trichloromethyl)-s-triazine, 4-(m-bromo-p-N,N-di(chloroethyl)aminophenyl)-2,6-di(trichloromethyl)-s-triazine, 4-(m-chloro-p-N,N-di(chloroethyl)aminophenyl)-2,6-di(trichloromethyl)-s-triazine, 4-(m-fluoro-p-N,N-di(chloroethyl)aminophenyl)-2,6-di(trichloromethyl)-s-triazine, 4-(m-bromo-p-N-ethoxycarbonylmethylaminophenyl)-2, 6-di(trichloromethyl)-s-triazine, 4-(m-chloro-p-N-ethoxycarbonylmethylaminophenyl)-2,6-di(trichloromethyl)-s-triazine, 4-(m-fluoro-p-N-ethoxycarbonylmethylaminophenyl)-2,6-di(trichloromethyl)-s-triazine, 4-(o-bromo-p-N-ethoxycarbonylmethylaminophenyl)-2,6-di(trichloromethyl)-s-triazine, 4-(o-chloro-p-N-ethoxycarbonylmethylaminophenyl)-2,6-di(trichloromethyl)-s-triazine, 4-(o-fluoro-p-N-ethoxycarbonylmethylaminophenyl)-2,6-di(trichloromethyl)-s-triazine, 4-(m-bromo-p-N-chloroethylaminophenyl)-2,6-di(trichloromethyl)-s-triazine, 4-(m-chloro-p-N-chloroethylaminophenyl)-2,6-di(trichloromethyl)-s-triazine, 4-(m-fluoro-p-N-chloroethylaminophenyl)-2,6-di(trichloromethyl)-s-triazine, 4-(o-bromo-p-N-chloroethylaminophenyl)-2, 6-di(trichloromethyl)-s-triazine, 4-(o-chloro-p-N-chloroethylaminophenyl)-2,6-di(trichloromethyl)-s-triazine, 4-(o-fluoro-p-N-chloroethylaminophenyl)-2,6-di(trichloromethyl)-s-triazine, 2,4-di(trichloromethyl)-6-(3-bromo-4-(N,N-di(ethoxycarbonylmethyl)amino)phenyl)-1,3,5-triazine, or a similar compound thereof, or any combination of the above-mentioned compounds.

The triazine compound is preferably 4-(m-bromo-p-N,N-di(ethoxycarbonylmethyl)aminophenyl)-2, 6-di(trichloromethyl)-s-triazine, 2,4-di(trichloromethyl)-6-p-methoxystyryl-s-triazine, or a combination of the above-mentioned compounds. The triazine compound may be used alone or in any combination.

Examples of the acetophenone compound include but are not limited to p-dimethylamino-acetophenone, α,α′-dimethoxyazoxy-acetophenone, 2,2′-dimethyl-2-phenyl-acetophenone, p-methoxy-acetophenone, 2-benzyl-2-N,N-dimethylamino-1-(4-morpholinophenyl)-1-butanone, 2-methyl-1-(4-methylthio phenyl)-2-morpholino-1-propanone, or a similar compound thereof, or any combination of the above-mentioned compounds. The acetophenone compound is preferably 2-methyl-1-(4-methylthio)phenyl-2-morpholinyl-1-propanone or 2-benzyl-2-N,N-dimethylamino-1-(4-morpholino phenyl)-1-butanone. The acetophenone compound may be used alone or in any combination.

Examples of the diimidazole compound include but are not limited to 2,2′-bis(o-chlorophenyl)-4,4′,5,5′-tetraphenyldiimidazole, 2,2′-bis(o-fluorophenyl)-4,4′,5,5′-tetraphenyldiimidazole, 2,2′-bis(o-methylphenyl)-4,4′,5,5′-tetraphenyldiimidazole, 2,2′-bis(o-methoxyphenyl)-4,4′,5,5′-tetraphenyldiimidazole, 2,2′-bis(o-ethylphenyl)-4,4′,5,5′-tetraphenyldiimidazole, 2,2′-bis(p-methoxyphenyl)-4,4′,5,5′-tetraphenyldiimidazole, 2,2′-bis(2,2′,4,4′-tetramethoxyphenyl)-4,4′,5,5′-tetraphenyldiimidazole, 2,2′-bis(2-chlorophenyl)-4,4′,5,5′-tetraphenyldiimidazole, 2,2′-bis(2,4-dichlorophenyl)-4,4′,5,5′-tetraphenyldiimidazole, or a similar compound thereof, or any combination of the above-mentioned compounds. The diimidazole compound may be used alone or in any combinations. The diimidazole compound is preferably 2,2′-bis(2,4-dichlorophenyl)-4,4′,5,5′-tetraphenyldiimidazole.

Examples of the benzophenone compound include thioxanthone, 2,4-diethylthioxanthone, thioxanthone-4-sulfone, benzophenone, 4,4′-bis(dimethylamino)benzophenone, 4,4′-bis(diethylamino)benzophenone, or a similar compound thereof, or any combination of the above-mentioned compounds. The benzophenone compound may be used alone or in any combination. The benzophenone compound is preferably 4,4′-bis(diethylamino)benzophenone.

Examples of the a-diketone compounds include but are not limited to diphenyl-ethanedione or an acetyl group.

Examples of the ketol compound include benzoin.

Examples of the acyloin ether compound include but are not limited to benzoin methyl ether, benzoin ethyl ether, benzoin isopropyl ether, or a similar compound thereof, or any combination of the above-mentioned compounds.

Examples of the acylphosphine oxide compound include but are not limited to (2,4,6-trimethylbenzoyl)diphenylphosphine oxide, bis(2,6-dimethoxybenzoyl)-2,4,4-trimethylpentylphosphine oxide, or a similar compound thereof, or any combination of the above-mentioned compounds.

Examples of the quinone compound include but are not limited to anthraquinone, 1,4-naphthoquinone, or a similar compound thereof, or any combination of the above-mentioned compounds.

Examples of the halogen-containing compound include but are not limited to phenacyl chloride, tribromomethyl phenyl sulfone, tris(trichloromethyl)-s-triazine, or a similar compound thereof, or any combination of the above-mentioned compounds.

Examples of the peroxide include but are not limited to di-tert-butyl peroxide and a similar compound thereof.

The photoinitiator (C-2) is preferably 1-[9-ethyl-6-(2-methylbenzoyl)-9H-carbazol-3-yl]-ethanone 1-(O-acetyloxime), product name: OXE-02, made by Ciba Specialty Chemicals Co., Ltd., 1-[4-(phenylthio)phenyl]-octane-1,2-dione 2-(O-benzoyloxime), product name: OXE-01, made by Ciba Specialty Chemicals Co., Ltd., 2-methyl-1-[4-(methylthio)phenyl]-2-morpholino-1-propanone, product name: IRGACURE 907, made by Ciba Specialty Chemicals Co., Ltd., or any combination of the above-mentioned compounds.

Based on 100 parts by weight of the used amount of the alkali-soluble resin (A), the used amount of the photoinitiator (C-2) is from 0 part by weight to 60 parts by weight, preferably from 1 part by weight to 55 parts by weight, and more preferably from 5 parts by weight to 50 parts by weight.

Based on 100 parts by weight of the used amount of the alkali-soluble resin (A), the used amount of the photoinitiator (C) is from 5 parts by weight to 100 parts by weight, preferably from 8 parts by weight to 90 parts by weight, and more preferably from 15 parts by weight to 80 parts by weight.

Examples of the solvent (D) include but are not limited to an alkylene glycol monoalkyl ether compound, an alkylene glycol monoalkyl ether acetate compound, diethylene glycol alkyl ether, other ether compounds, a ketone compound, a alkyl lactate compound, other ester compounds, an aromatic hydrocarbon compound, a carboxylic acid amine compound, or any combination of the above-mentioned compounds. The solvent (D) may be used alone or in any combination.

Examples of the alkyl glycol monoalkyl ether compound include but are not limited to ethylene glycol monomethyl ether, ethylene glycol monoethyl ether, diethylene glycol monoethyl ether, diethylene glycol mono-n-propyl ether, diethylene glycol mono-n-butyl ether, triethylene glycol monomethyl ether, triethylene glycol monoethyl ether, propylene glycol monomethyl ether, propylene glycol monoethyl ether, dipropylene glycol monomethyl ether, dipropylene glycol monoethyl ether, dipropylene glycol mono-n-propyl ether, dipropylene glycol monon-butyl ether, tripropylene glycol monomethyl ether, tripropylene glycol monoethyl ether, or a similar compound thereof, or any combination of the above-mentioned compounds.

Examples of the alkyl glycol monoalkyl ether acetate compound include but are not limited to ethylene glycol monomethyl ether acetate, ethylene glycol monoethyl ether acetate, propylene glycol monomethyl ether acetate, propylene glycol monoethyl ether acetate, or a similar compound thereof, or any combination of the above-mentioned compounds.

Examples of the diethylene glycol alkyl ether include but are not limited to diethylene glycol dimethyl ether, diethylene glycol ethyl methyl ether, diethylene glycol diethyl ether, or a similar compound thereof, or any combination of the above-mentioned compounds.

Examples of the other ether compounds include but are not limited to tetrahydrofuran or a similar compound thereof.

Examples of the ketone compound include methyl ethyl ketone, cyclohexanone, 2-heptanone, 3-heptanone, diacetone alcohol, or a similar compound thereof, or any combination of the above-mentioned compounds.

Examples of the alkyl lactate compound include but are not limited to methyl lactate, ethyl lactate, or a similar compound thereof, or any combination of the above-mentioned compounds.

Examples of the other ester compounds include but are not limited to methyl 2-hydroxy-2-methylpropanoate, ethyl 2-hydroxy-2-methylpropanoate, methyl 3-methoxypropanoate, ethyl 3-methoxypropanoate, methyl 3-ethoxypropanoate, ethyl 3-ethoxypropanoate, ethyl ethoxyacetate, ethyl hydroxyacetate, methyl 2-hydroxy-3-methylbutyrate, 3-methyl-3-methoxybutyl acetate, 3-methyl-3-methoxybutyl propanoate, ethyl acetate, n-propyl acetate, isopropyl acetate, n-butyl acetate, isobutyl acetate, n-amyl acetate, isoamyl acetate, n-butyl propanoate, ethyl butyrate, n-propyl butyrate, isopropyl butyrate, n-butyl butyrate, methyl pyruvate, ethyl pyruvate, n-propyl pyruvate, methyl acetoacetate, ethyl acetoacetate, ethyl 2-oxybutyrate, or a similar compound thereof, or any combination of the above-mentioned compounds.

Examples of the aromatic hydrocarbon compound include but are not limited to toluene, xylene, or a similar compound thereof, or any combination of the above-mentioned compounds.

Examples of the carboxylic acid amine compound include N-methylpyrrolidone, N,N-dimethyl formamide, N,N-dimethyl acetamide, or a similar compound thereof, or any combination of the above-mentioned compounds.

The solvent (D) is preferably propylene glycol monomethyl ether acetate or ethyl 3-ethoxypropionate.

Based on 100 parts by weight of the used amount of the alkali-soluble resin (A), the used amount of the solvent (D) is from 800 parts by weight to 3000 parts by weight, preferably from 850 parts by weight to 2500 parts by weight, and more preferably from 900 parts by weight to 2000 parts by weight.

The black pigment (E) according to the present invention is preferably a black pigment having a good heat resistance, light resistance, and solvent resistance.

Examples of the black pigment (E) include organic black organic pigments such as perylene black, cyanine black, or aniline black; a near-black mixture of organic pigments obtained by mixing two or more pigments selected from the pigments of red, blue, green, purple, yellow, cyanine, or magenta; light-shielding materials such as carbon black, chromium oxide, ferric oxide, titanium black, or graphite.

Examples of the carbon black include C.I. pigment black 7 or commercial products made by Mitsubishi Chemical Corporation (product names MA100, MA230, MA8, #970, #1000, #2350, or #2650). The black pigment (E) may be used alone or in multiple combinations.

The black pigment (E) is preferably carbon black or the commercial product MA100 or MA230.

Based on 100 parts by weight of the used amount of the alkali-soluble resin (A), the used amount of the black pigment (E) is from 100 parts by weight to 500 parts by weight, preferably from 130 parts by weight to 450 parts by weight, and more preferably from 150 parts by weight to 400 parts by weight.

The compound (F) having the structure represented by Formula (1) according to the present invention is:

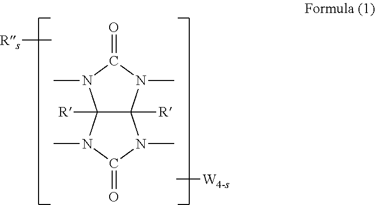

in Formula (1), R′ is selected from the group consisting of a hydrogen atom, a substituted or unsubstituted C₁-C₂₀ hydrocarbon group and a substituted or unsubstituted C₁-C₂₀ acyl group; each R′ is the same or different;
R″ is selected from the group consisting of a hydrogen atom, a substituted or unsubstituted C₁-C₁₅ hydrocarbon group, a substituted or unsubstituted C₁-C₁₅ acyl group and a substituted or unsubstituted C₁-C₁₅ nitro group; each R″ is the same or different;
s represents 0, 1 or 2; and
W represents

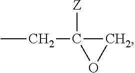

wherein, Z represents a hydrogen atom or a C₁-C₄ alkyl group.

The compound (F) having the structure represented by Formula (1) according to the present invention is glycoluril derivatives, which is characterized by that at least 2 glycidyl groups in the bicyclic system are respectively located at the N-substituent position of the ring system. The substituted positions of the 2 glycidyl groups are shown as Formula (1), which means that the 2 glycidyl groups are respectively bonded at the N-substituted positions in the same 5-membered ring (1,3-position). Besides, the compound (F) having the structure represented by Formula (1) according to the present invention may comprise 2 glycidyl groups respectively bonded at two N-substituted positions in two 5-membered rings (1,5-position or 1,7-position). The compound (F) having the structure represented by Formula (1) according to the present invention may comprise 3 glycidyl groups, wherein the 3 glycidyl groups are respectively bonded at N-substituted positions in two 5-membered rings (1,3,5-position or 1,3,7-position). The compound (F) having the structure represented by Formula (1) according to the present invention may comprise 4 glycidyl groups, wherein the 4 glycidyl groups are respectively bonded at N-substituted positions in two 5-membered rings (1,3,5,7-position).

In Formula (1), R′ is selected from the group consisting of a hydrogen atom, a substituted or unsubstituted C₁-C₂₀ hydrocarbon group and a substituted or unsubstituted C₁-C₂₀ acyl group. Preferably, the carbon number of R′ is 1 to 15; more preferably, the carbon number of R′ is 1 to 12. The carbon number of R′ may be less than the carbon number as mentioned above; for example, the carbon number of R′ is 10, 8 or 4. The carbon number is also suitable for the unsubstituted R′. When the aforementioned hydrocarbon group is substituted, and then more carbon atoms may be introduced into R′. The following illustration of the hydrocarbon group is also applied in the acyl group.

The hydrocarbon group of R′ may comprise a C₁-C₂₀ linear and/or branched alkyl group and a C₁-C₂₀ linear and/or branched alkenyl group; an aryl group is also contained. The definition according to the invention, the hydrocarbon group may comprise an aromatic group in the narrower sense, for example, an alkaryl group or aralkyl group constituted by one aromatic ring alone. When R′ represents the aryl group, alkaryl group or aralkyl group, the preferred examples include but are not limited to phenyl, benzyl, tolyl, xylyl or the aforementioned congeners.

Besides, the aforementioned R′ may be a cycloalkyl group or a cycloalkenyl group, and the cycloalkyl group or the cycloalkenyl group may comprise a substituted cycloalkyl group or a substituted cycloalkenyl group. In another aspect, when R′ represents a saturated cyclic group or a partially saturated cyclic group, the preferred examples are a cyclopentyl group, a cyclohexyl group and its derivatives. In still another aspect, when R′ represents a heterocyclic group, the preferred examples are a cyclic compound having O, N and/or S. Preferably, the aforementioned ring system comprises 1, 2 or 3 heteroatoms, or is a saturated or unsaturated or an aromatic cyclic group.

Optionally, R′ according to the invention may further comprise other substituted groups. The preferred examples are halogen, an alkoxy group, an acyl group or an acyloxy group, wherein, more preferably, the halogen is chlorine and/or bromine.

When R′ further comprises the substituted hydrocarbon group, the carbon number of the substituted group preferably may not exceed 10; more preferably not exceed 8; still more preferably may not exceed 6; and most preferably may not exceed 4. The substituted hydrocarbon group according to the invention includes but is not limited to an aryl group, an aralkyl group, an alkaryl group, a cycloalkyl group and/or an alkyl group having a substituted group containing halogen, an alkoxy group or the like. Besides, it also comprises the aforementioned heterocyclic ring system; for examples, a heterocyclic ring system containing 1 to 3 heteroatoms.

The compound (F) having the structure represented by Formula (1) according to the invention, the total carbon number of R′ is no more than 12 disregarding any substituents; preferably, no more than 10; more preferably, no more than 8; still more preferably, no more than 4 or 6. The aforementioned carbon number is also suitable for R′ containing the substituted group.

Optionally, if R″ according to the invention is not a hydrogen atom, R″ may be the same or different hydrocarbon group. Preferably, the carbon number of each hydrocarbon group is no more than 12; more preferably no more than 10 or 8; still more preferably, no more than 6 or 4. The illustration of R′ is also suitable for R″.

The hydrocarbon group of R″ may comprise a C₁-C₁₅ linear and/or branched alkyl group and a C₁-C₁₅ linear and/or branched alkenyl group; an aryl groups is also contained. The definition of R′ is also suitable for R″. Therefore, the aryl group also comprises an alkaryl group or aralkyl group and the illustrations of the aforementioned cycloalkyl group, cycloalkenyl group and heterocyclic group are suitable for R″.

Preferably, the substituted group of R′ is halogen, a hydroxyl group, an amine group, an N-substituted amine group, a mercapto group, an alkylmercapto group, an arylmercapto group, an alkoxy group, an aryloxy group and/or an acyloxy group. R″ may have one or more than one substituted groups. Preferably, R″ has 1 to 3 substituted groups; more preferably, R″ has a substituted or unsubstituted alkyl group. The illustration of the number of R′ is suitable for R″.

In one preferred embodiment, the compound (F) having the structure represented by Formula (1) comprises N,N′-diglycidyl glycoluril represented by Table 1.

TABLE 1

| R″ | number of R″ | R′ | number of R′ |
|---|---|---|---|
| — | 0 | — | 0 |
| methyl | 2 | — | — |
| nitro | 2 | — | — |
| — | — | methyl | 2 |
| — | — | methyl | 1 |
| acetyl | 2 | methyl | 2 |
| propionyl | 2 | methyl | 2 |
| butyryl | 2 | methyl | 2 |
| methyl | 2 | methyl | 2 |
| methyl | 2 | phenyl | 2 |
| acetyl | 2 | phenyl | 2 |
| — | — | phenyl | 2 |
| propionyl | 2 | phenyl | 2 |
| butyryl | 2 | phenyl | 2 |
| methyl | 1 | — | — |
| methyl | 1 | acetyl | 1 |
| formyl | 1 | — | — |
| benzyl | 2 | — | — |
| capryloyl | 2 | — | — |
| acetyl | 2 | — | — |
| propionyl | 2 | — | — |
| butyryl | 2 | — | — |
| dihydroxypropyl | 1 | — | — |
| diethylamino | 1 | — | — |
| hydroxypropyl | | | |
| dimethylamino | 1 | — | — |
| hydroxypropyl | | | |
| halogen | 1 | — | — |
| hydroxypropyl | | | |

wherein, ″—″ represented a hydrogen atom.

If the compound (F) having the structure represented by Formula (1) is absent, the photosensitive resin composition has poor linearity of pattern with high finesse.

Based on 100 parts by weight of the used amount of the alkali-soluble resin (A), the used amount of the compound (F) having the structure represented by Formula (1) is from 1 part by weight to 40 parts by weight, preferably from 2 parts by weight to 35 parts by weight, and more preferably from 3 parts by weight to 30 parts by weight.

Without affecting the efficacy of the invention, the photosensitive resin composition according to the invention may further comprise an additive (G). The additive (G) includes but is not limited to a surfactant, a filler, an adhesion promoting agent, a bridging agent, an antioxidant, an anti-coagulant, or other polymers other than the alkali-soluble resin (A) that can improve any property (such as mechanical property).

Examples of the aforementioned surfactant include but are not limited to a cationic, an anionic, a nonionic, a zwitterionic, a polysiloxane, and a fluoro surfactant, or any combination thereof.

The surfactant includes but is not limited to, polyoxyethylene alkyl ethers such as polyoxyethylene lauryl ether, polyoxyethylene stearyl ether, or polyoxyethylene oleyl ether; polyoxyethylene alkyl phenyl ethers such as polyoxyethylene octyl phenyl ether or polyoxyethylene nonyl phenyl ether; polyethylene glycol diesters such as polyethylene glycol dilaurate and polyethylene glycol distearate; sorbitol anhydride fatty acid esters; fatty acid-modified polyesters; and tertiary amine-modified polyurethanes. Examples of the surfactant are KP (manufactured by Shin-Etsu Chemical Co., Ltd.), SF-8427 (manufactured by Toray Dow Corning Silicone Co., Ltd.), Polyflow (manufactured by Kyoeisha Oil Chemical Co., Ltd.), F-Top (manufactured by Tochem Product Co., Ltd.), Megafac (manufactured by Dainippon Ink and Chemicals Co., Ltd.), Fluorade (manufactured by Sumitomo 3M, Ltd.), Asahi Guard (manufactured by Asahi glass Co., Ltd.), Asahi Guard or Surflon (manufactured by Asahi glass Co., Ltd.). The aforementioned surfactant may be used alone or in combination.

The filler includes but is not limited to glass or aluminium.

Examples of the adhesion promoting agent are vinyltrimethoxysilane, vinyltriethoxysilane, vinyltris(2-methoxyethoxy)silane, N-(2-aminoethyl)-3-aminopropylmethyldimethoxysilane, N-(2-aminoethyl)-3-aminopropyltrimethoxysilane, 3-aminopropyltriethoxysilane, 3-glycidoxypropyltrimethoxysilane, 3-glycidoxypropylmethyldiethoxysilane, 2-(3,4-epoxycyclohexyl)ethyltrimethoxysilane, 3-chloropropylmethyldimethoxysilane, 3-chloropropyltrimethoxysilane, 3-methacryloyloxypropyl trimethoxysilane and 3-mercaptopropyltrimethoxysilane.

Examples of the antioxidant are 2,2-thiobis(4-methyl-6-t-butyl phenol) or 2,6-di-t-butyl phenol.

Example of the anti-coagulant is sodium polyacrylate.

Based on 100 parts by weight of the used amount of the alkali-soluble resin (A), the used amount of the filler, the adhesion promoting agent, the antioxidant, the anti-coagulant, or polymers other than the alkali-soluble resin (A) in the additive (G) is preferably below 10 parts by weight; more preferably below 6 parts by weight.

The photosensitive resin composition of the invention is prepared by, for instance, placing and stirring the alkali-soluble resin (A), the compound (B) containing the ethylenically unsaturated group, the photoinitiator (C), the solvent (D), the black pigment (E), and the compound (F) having the structure represented by Formula (1) in an agitator such that the ingredients are evenly mixed into a solution state. When necessary, the additive (G) such as the surfactant, the filler, the adhesion promoting agent, the bridging agent, the antioxidant, and the anti-coagulant can be added. After the solution is evenly mixed, the photosensitive resin composition in a solution state can be obtained.

The preparation method of the photosensitive resin composition of the invention is not particularly limited. For instance, the black pigment (E) can be directly added and dispersed in other ingredients of the photosensitive resin composition in order to form the photosensitive resin composition. Alternately, a portion of the pigment (E) can first be dispersed in a portion of a medium including the alkali-soluble resin (A) and the solvent (D) to form a pigment dispersion solution, and then mixed with the rest of the compound (B) containing the ethylenically unsaturated group, the photoinitiator (C), the compound (F) having the structure represented by Formula (1), the alkali-soluble resin (A), and the solvent (D) to prepare the photosensitive resin composition.

The dispersion steps of the black pigment (E) can be performed by mixing the ingredients with a mixer such as a beads mill or a roll mill.

The present invention also provides a black matrix, which is formed by photosensitive resin composition as mentioned above.

The black matrix is obtained by applying the treatments of pre-baking, exposure, development, and post-bake to the aforementioned photosensitive resin composition in turn, wherein when the film thickness of the black matrix is 1 jm, the range of the optical density can be at least 3.0, preferably 3.2 to 5.5, and more preferably 3.5 to 5.5. The preparation method of the black matrix is described in detail below.

Firstly, the photosensitive resin composition in liquid state for a black matrix is uniformly coated on a substrate by a coating method such as spin coating or cast coating to form a coating film. Specific examples of the substrate include alkali-free glass, soda-lime glass, hard glass (Pyrex glass), silica glass, and glasses with a transparent conductive film attached thereto, or a substrate (e.g., a silicon substrate) used for a photoelectric conversion device such as a solid imaging device.

After the coating film is formed, most of the solvent is removed by drying under reduced pressure. Next, the remaining solvent is completely removed by a pre-baking process to form a pre-baking coating film. It should be mentioned that, the conditions for drying under reduced pressure and pre-baking can vary according to the components and the ratio of each component. Generally, drying under reduced pressure is conducted at a pressure of less than 200 mmHg for 1 second to 20 seconds, and the pre-bake is a heat treatment conducted on the coating film at a temperature of 70° C. to 110° C. for 1 minute to 15 minutes.

Then, the pre-baking coating film is exposed with a photomask having a specific pattern. The light used in the exposure process is preferably an ultraviolet light such as a g-line, a h-line, or an i-line. In addition, the UV light irradiation device can be a(n) (ultra-)high pressure mercury vapor lamp or a metal halide lamp.

Then, after the exposure treatment, the coating film is immersed in a developing solution at a temperature of 21° C. to 25° C. to remove the unexposed portion of the pre-baked coating film and to form a specific pattern on the substrate.

The above-mentioned developing solution can include an alkali compound such as sodium hydroxide, potassium hydroxide, sodium carbonate, sodium hydrogen carbonate, potassium carbonate, potassium hydrogen carbonate, sodium silicate, sodium methylsilicate, ammonia solution, ethylamine, diethylamine, dimethylethylanolamine, tetramethylammonium hydroxide, tetraethylammonium hydroxide, choline, pyrrole, piperidine, or 1,8-diazabicyclo-[5,4,0]-7-undecene. The concentration of the developing solution is generally 0.001 wt % to 10 wt %, preferably 0.005 wt % to 5 wt %, and more preferably 0.01 wt % to 1 wt %.

After the pre-baked coating film is developed, the substrate having a specific pattern is rinsed with water, and then the specific pattern is air dried with compressed air or compressed nitrogen. Then, a post-bake treatment is conducted with a heating device such as a hot plate or an oven, and a black matrix can be formed on the substrate. The post-bake temperature is generally 150 to 250° C., wherein the heating time when using the hot plate is 5 minutes to 60 minutes and the heating time when using the oven is 15 minutes to 150 minutes. After the treatment steps, the black matrix can be formed on the substrate.

The present invention also provides a color filter comprising the black matrix as mentioned above.

The formation method of the color filter according to the invention can be performed by coating the photosensitive composition for the color filter, which is mixed into a solution state, on a substrate by a coating method such as spin-coating, cast coating, or roll coating, wherein the black matrix for separating each pixel color layer is formed on the substrate in advance by using the photosensitive resin composition.

After coating, most of the solvent is removed by a method of reduced pressure drying, and then the solvent is removed by pre-baking to form a pre-baked coating film. The aforementioned conditions of the reduced pressure drying and pre-bake can be specified based on the type and the mix ratio of each ingredient. Generally, the reduced pressure drying can be performed at a pressure of 0 mmHg to 200 mmHg for 1 second to 60 seconds, and the pre-bake can be performed at a temperature of 70° C. to 110° C. for 1 minute to 15 minutes.

After the pre-bake, the coating film is exposed by a specified mask. The light used in the exposure step is preferably an ultraviolet light such as a g-line, a h-line, or an i-line, and the ultra-violet irradiation device can be, for instance, a(n) (ultra-)high pressure mercury vapor lamp or a metal halide lamp.

After the exposure treatment, the coating film is immersing in a developing solution at a temperature of 21° C. to 25° C. to remove the unnecessary portion of the aforementioned coating film so as to form a specific pattern.

After development, the pattern is first washed with water and then air-dried with compressed air or compressed nitrogen, and then a heating device such as a hot plate or an oven is used to perform the post-baking treatment. The conditions of the post-baking treatment are the same as described above and are not repeated herein. The steps are repeated in sequence for the photosensitive composition of each color (mainly including red, green, and blue) to prepare the pixel layer of the color filter.

Next, in a vacuum environment with a temperature in the range of 220° C. to 250° C., an indium tin oxide (ITO) film is formed on the pixel layer. When needed, after the ITO film is etched and wired, a polyimide for a liquid crystal alignment film is coated and burned to obtain the color filter for a liquid crystal display element.

The present invention further provides a liquid crystal display element comprising the color filter as mentioned above.

The liquid crystal display element according to the invention can be formed by the following method: the color filter substrate formed by the preparation method of the color filter and a driving substrate with a thin film transistor (TFT) are placed opposite to each other with a gap (cell gap) between the two, and then the surrounding area of the two substrates is laminated with a sealing agent. Next, a liquid crystal is injected into the gap separated by the surface of the substrates and the sealing agent to seal the injection hole and to form a liquid crystal cell. Then, a polarizer is laminated to the outer surface of the liquid crystal cell, i.e. the other side surfaces of each of the substrates forming the liquid crystal cell so as to fabricate the liquid crystal display element.

The liquid crystal can be a liquid crystal compound or a liquid crystal composition. The specific composition of the liquid crystal is not particularly limited, and any liquid crystal compound and liquid crystal composition known by those skilled in the art can be used.

Moreover, the liquid crystal alignment film is used to limit the alignment of the liquid crystal molecules and is not particularly limited, and can be any inorganic matter or organic matter. Furthermore, the technique of forming the liquid crystal alignment film is well known by those skilled in the art and is thus not repeated herein.

The following examples are given for the purpose of illustration only and are not intended to limit the scope of the present invention.

### Synthesis of Alkali-Soluble Resin (A-1)

### Synthesis Example A-1-1

100 parts by weight of a fluorene epoxy compound (model number: ESF-300, made by Nippon Steel Chemical, epoxy equivalent: 231), 30 parts by weight of acrylic acid, 0.3 parts by weight of benzyltriethylammonium chloride, 0.1 parts by weight of 2,6-di-tert-butyl-p-cresol and 130 parts by weight of propylene glycol monomethyl ether acetate were added in a 500 ml four-neck flask in a continuous manner. The feeding speed was controlled at 25 parts by weight/minute, the temperature of the reaction process was maintained at 100° C. to 110° C., and the mixture was reacted for 15 hours to obtain a light yellow transparent mixture solution having a solid content of 50 wt %.

Next, 100 parts by weight of the mixture solution was dissolved in 25 parts by weight of ethylene glycol ethyl ether acetate, and at the same time, 6 parts by weight of tetrahydrophthalic anhydride and 13 parts by weight of benzophenonetetracarboxylic dianhydride were added, and then the mixture solution was heated to 110° C. to 115° C. and reacted for 2 hours to obtain the resin (A-1-1) having the unsaturated group, wherein the resin (A-1-1) had an acid value of 98.0 mgKOH/g.

### Synthesis Example A-1-2

A 500 mL four-necked flask was continuously added with 100 parts by weight of a fluorene epoxy compound (Model ESF-300, manufactured by Nippon Steel Chemical Co., epoxy equivalent 231), 30 parts by weight of acrylic acid, 0.3 parts by weight of benzyltriethylammonium chloride, 0.1 parts by weight of 2,6-di-t-butyl-p-cresol, and 130 parts by weight of propylene glycol methyl ether acetate, wherein the feeding rate was controlled at 25 parts by weight/min, the temperature was maintained in the range of 100° C. to 110° C., and the mixture was reacted for 15 hours to obtain a light yellow and transparent mixture solution having a solid content concentration of 50 wt %.

Next, 100 parts by weight of the mixture solution was dissolved in 25 parts by weight of ethylene glycol ethyl ether acetate, and at the same time, 13 parts by weight of benzophenone tetracarboxylic dianhydride was added, and then the mixture solution was reacted for 2 hours at 110° C. to 115° C. Then, 6 parts by weight of tetrahydrophthalic anhydride was added, and the mixture solution was reacted for 4 hours at 90° C. to 95° C. to obtain the resin (A-1-2) having the unsaturated group, wherein the resin (A-1-2) had an acid value of 99.0 mgKOH/g.

### Synthesis Example A-1-3

A reaction vessel was added with 400 parts by weight of an epoxy compound (Model NC-3000, manufactured by Nippon Kayaku Co. Ltd.; epoxy equivalent 288), 102 parts by weight of acrylic acid, 0.3 parts by weight of methoxyphenol, 5 parts by weight of triphenyl phosphine, and 264 parts by weight of propylene glycol methyl ether acetate, wherein the temperature was maintained at 95° C. and the mixture was reacted for 9 hours to obtain an intermediate product having an acid value of 2.2 mgKOH/g. Then, 151 parts by weight of tetrahydrophthalic anhydride was added and the mixture was reacted for 4 hours at 95° C. to obtain the resin (A-1-3) having the unsaturated group, wherein the resin (A-1-3) had an acid value of 102 mgKOH/g and a weight averaged molecular weight of 3,200.

### Synthesis of Alkali-Soluble Resin (A-2)

### Synthesis Example A-2-1

Firstly, 1 part by weight of 2,2′-azobisisobutyronitrile, 240 parts by weight of propylene glycol monomethyl ether acetate, 20 parts by weight of methacrylic acid, 15 parts by weight of styrene, 35 parts by weight of benzyl methacrylate, 10 parts by weight of glycerol monomethacrylate, and 20 parts by weight of N-phenylmaleimide were placed in a round-bottom flask provided with a stirrer. Then, a condenser was provided on the round-bottom flask and the round-bottom flask was filled with nitrogen gas. Next, the components were slowly stirred and the temperature was raised to 80° C. such that the reactants were uniformly mixed, and then a polymerization reaction proceeded for 4 hours. Then, the temperature was further raised to 100° C. and 0.5 parts by weight of 2,2′-azobisisobutyronitrile was added. After polymerizing for 1 hour, the other alkali-soluble resin (A-2-1) was obtained.

### Synthesis Example A-2-2

Firstly, 2 parts by weight of 2,2′-azobisisobutyronitrile, 300 parts by weight of di(propylene glycol)monomethyl ether, 15 parts by weight of methacrylic acid, 15 parts by weight of 2-hydroxyethyl acrylate, and 70 parts by weight of benzyl methacrylate were placed in a round-bottom flask provided with a stirrer. Then, a condenser was provided on the round-bottom flask and the round-bottom flask was filled with nitrogen gas. Next, the components were slowly stirred and the temperature was raised to 80° C. such that the reactants were uniformly mixed, and then a polymerization reaction proceeded for 3 hours. Then, the temperature was further raised to 100° C. and 0.5 parts by weight of 2,2′-azobisisobutyronitrile was added. Next, after polymerizing for 1 hour, the other alkali-soluble resins A-2-2 was obtained.

### <Preparation of Photosensitive Resin Composition>

The photosensitive resin compositions of Examples 1 to 9 and comparative examples 1 to 7 were prepared according to Tables 2 and 3 below.

### Examples 1

100 parts by weight of the as-prepared alkali-soluble resin (A-1-1), 20 parts by weight of trimethylolpropyl triacrylate (hereinafter abbreviated as B-1), 30 parts by weight of 1-[9-ethyl-6-(2-methylbenzoyl)-9H-carbazol-3-yl]-ethanone 1-(O-acetyloxime) (OXE-02 from Ciba, hereinafter abbreviated as C-2-1), 200 parts by weight of MA100 (Product of Mitsubishi Chemical Corporation, hereinafter abbreviated as E-1) and 3 parts by weight of the compound (F-1) represented by Table 2 were added into 1200 parts by weight of propylene glycol monomethyl ether acetate (hereinafter abbreviated as D-1) and uniformly mixed in a shaking type stirrer to form the photosensitive resin composition for black matrix of Example 1. The resulted photosensitive resin composition was evaluated in terms of heat-enduring resistance stability by the approach described below. The results were shown in Table 2.

### Examples 2 to 9 and Comparative Examples 1 to 7

The photosensitive resin compositions of examples 2 to 9 and comparative examples 1 to 7 were prepared by the same method as described in connection to example 1, except that the components and the amount of each component in the photosensitive resin composition were changed. The formula and the results of the evaluation are shown in Tables 2 and 3, and the details are omitted here.

TABLE 2

| | | | Example | | | | | | | | |
|---|---|---|---|---|---|---|---|---|---|---|---|
| Composition | | | 1 | 2 | 3 | 4 | 5 | 6 | 7 | 8 | 9 |
| alkali-soluble resin (A) | A-1 | A-1-1 | 100 | | | 80 | | | 30 | | |
| (parts by weight) | | A-1-2 | | 100 | 60 | | 70 | | | | 100 |
| | | A-1-3 | | | 40 | 20 | | 50 | | 80 | |
| | A-2 | A-2-1 | | | | | 30 | | 35 | | |
| | | A-2-2 | | | | | | 50 | 35 | 20 | |
| compound (B) containing an | B-1 | | 20 | | | 10 | | 150 | | | |
| ethylenically unsaturated group | B-2 | | | 50 | | 30 | 20 | | | 90 | 200 |
| (parts by weight) | B-3 | | | | 30 | | 80 | 30 | 100 | 60 | |
| photoinitiator (C) | C-1 | C-1-1 | | | 20 | 5 | 10 | | | | |
| (parts by weight) | | C-1-2 | | | | | 5 | 5 | | | 30 |
| | | C-1-3 | | | | 25 | | | 40 | | |
| | C-2 | C-2-1 | 30 | | | | | 45 | | | 50 |
| | | C-2-2 | | 50 | | | | 5 | | 30 | |
| | | C-2-3 | | | | | 40 | | 20 | 30 | |

| solvent (D) | D-1 | 1200 | | | 1000 | | | 1000 | | |
|---|---|---|---|---|---|---|---|---|---|---|
| (parts by weight) | D-2 | | 850 | 900 | 800 | 1100 | | | 800 | 1200 |
| | D-3 | | | 500 | | | 1200 | 2000 | | 1000 |
| black pigment (E) | E-1 | 200 | | | | 90 | 50 | | 100 | |
| (parts by weight) | E-2 | | 150 | | 100 | | 150 | | | 400 |
| | E-3 | | | 120 | 150 | 90 | | 500 | | |
| compound (F) | F-1 | 3 | | | 5 | | 15 | | | 20 |
| (parts by weight) | F-2 | | 5 | | 10 | 10 | | 40 | | |
| | F-3 | | | 10 | | 20 | 20 | | 1 | |
| additives (G) | G-1 | | | | | 3 | | | | |
| (parts by weight) | G-2 | | | | | | | 1 | | |
| | G-3 | | | 5 | | | | | | |
| Evaluation | Linearity of | ◯ | ◯ | ⊚ | ⊚ | ⊚ | ⊚ | ⊚ | ◯ | ⊚ |
| | Pattern with high | | | | | | | | | |
| | finesse | | | | | | | | | |

TABLE 3

| | | | Comparative example | | | | | | |
|---|---|---|---|---|---|---|---|---|---|
| Composition | | | 1 | 2 | 3 | 4 | 5 | 6 | 7 |
| alkali-soluble resin (A) | A-1 | A-1-1 | 100 | 80 | | | | | 100 |
| (parts by weight) | | A-1-2 | | | 70 | | | | |
| | | A-1-3 | | 20 | | | | | |
| | A-2 | A-2-1 | | | 30 | 100 | 60 | 50 | |
| | | A-2-2 | | | | | 40 | 50 | |
| compound (B) containing an | B-1 | | 20 | 10 | | 20 | | 150 | |
| ethylenically unsaturated group | B-2 | | | 30 | 20 | | | | |
| (parts by weight) | B-3 | | | | 80 | | 30 | 30 | 15 |
| photoinitiator (C) | C-1 | C-1-1 | | 5 | 10 | | 20 | | |
| (parts by weight) | | C-1-2 | | | 5 | | | 5 | |
| | | C-1-3 | | 25 | | | | | |
| | C-2 | C-2-1 | 30 | | | 30 | | 45 | 30 |
| | | C-2-2 | | | | | | 5 | 3.8 |
| | | C-2-3 | | | 40 | | | | |

| | | | | | | | | |
|---|---|---|---|---|---|---|---|---|
| solvent (D) | D-1 | 1200 | 1000 | | 1200 | | | 260 |
| (parts by weight) | D-2 | | 800 | 1100 | | 900 | | 278 |
| | D-3 | | | | | 500 | 1200 | |
| black pigment (E) | E-1 | 200 | | 90 | 200 | | 50 | |
| (parts by weight) | E-2 | | 100 | | | | 150 | 1070 |
| | E-3 | | 150 | 90 | | 120 | | |
| compound (F) | F-1 | | | | 3 | | | |
| (parts by weight) | F-2 | | | | | | | |
| | F-3 | | | | | 10 | | |
| additives (G) | G-1 | | | 3 | | | | |
| (parts by weight) | G-2 | | | | | | | 0.5 |
| | G-3 | | | | | 5 | | |
| Evaluation | Linearity of | X | X | X | X | X | X | X |
| | Pattern with | | | | | | | |
| | high finesse | | | | | | | |

### In Table 2 and Table 3:

B-1 trimethylolpropyl triacrylate
B-2 dipentaerythritol tetracrylate
B-3 dipentaerythritol hexaacrylate

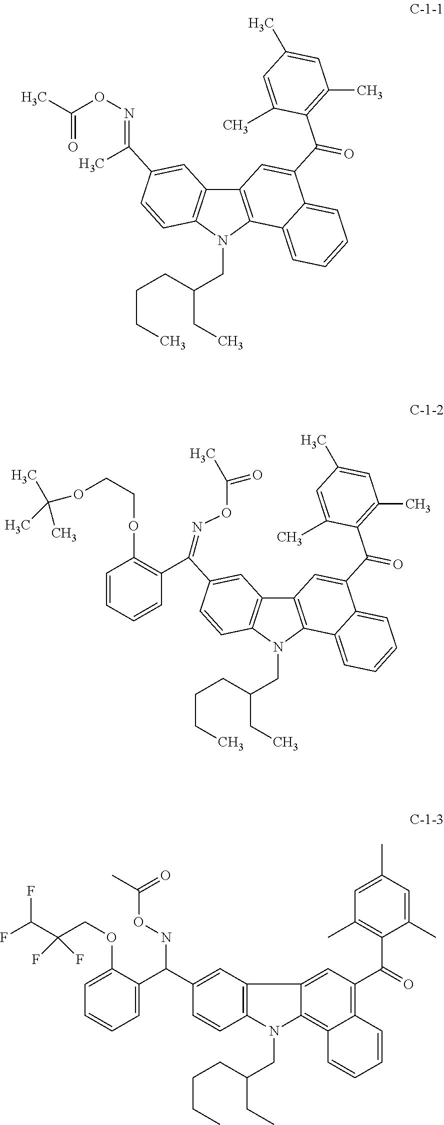

C-2-1 1-[9-ethyl-6-(2-methylbenzoyl)-9H-carbazol-3-yl]-ethanone 1-(O-acetyloxime) (product name OXE-02 manufactured by Ciba Specialty Chemicals)
C-2-2 2-benzyl-2-N,N-dimethylamino-1-(4-morpholinophenyl)-1-butanone
C-2-3 1-[4-(phenylthio)phenyl]-octane-1,2-dione 2-(O-benzoyloxime) (product name OXE-01 manufactured by Ciba Specialty Chemicals)
D-1 propylene glycol monomethyl ether acetate
D-2 cyclohexanone
D-3 ethyl 3-ethoxypropionate
E-1 MA100 (manufactured by Mitsubishi Chemical Corporation)
E-2 MA230 (manufactured by Mitsubishi Chemical Corporation)
E-3 #1000 (manufactured by Mitsubishi Chemical Corporation)

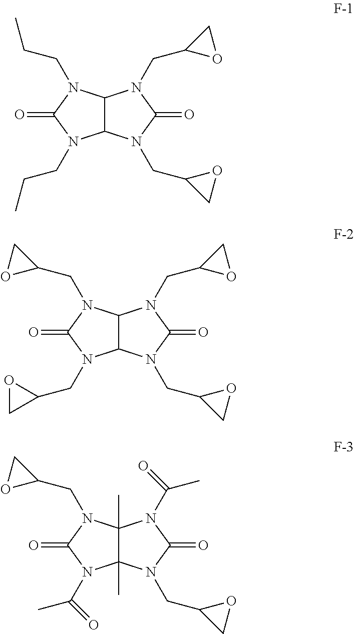

G-1 SF-8427 (Toray Dow Corning Silicon)
G-2 3-glycidoxypropyltrimethoxysilane (product name KBM403, manufactured by Shin-Etsu Chemical Co., Ltd.)
G-3 Megafac (manufactured by Dainippon Ink and Chemicals Co., Ltd.)
   Linearity of Pattern with High Finesse:

The photosensitive resin composition of the Examples 1 to 9 or the Comparative Examples 1 to 7 was coated on a glass substrate with the length and width of 100 mm and dried at a pressure of 100 mmHg for 30 seconds. Then, the aforementioned glass substrate was pre-baked at 80° C. for 3 minutes to form a pre-baked coating film having the film thickness of 2.5 m. The pre-baked coating film was exposed under a mask with stripe pattern of 2.5 μm width and 50 m pitch and by ultraviolet light (exposure machine model: AG500-4N) at the energy density of 300 mJ/cm². Then, the pre-baked coating film was immersed in a developing solution at 23° C. for 2 minutes. After washing with pure water, the pre-baked coating film was post baked in an oven at 200° C. for 80 minutes. A photosensitive resin layer of 2.0 m film thickness was thus formed on the glass substrate.

The stripe pattern formed by the aforementioned method was observed and evaluated by using an optical microscope. The criteria are shown below:
⊚: good linearity of pattern with high finesse;
∘: partially poor linearity of pattern with high finesse;
X: poor linearity of pattern with high finesse.

While embodiments of the present invention have been illustrated and described, various modifications and improvements can be made by persons skilled in the art. It is intended that the present invention is not limited to the particular forms as illustrated, and that all modifications not departing from the spirit and scope of the present invention are within the scope as defined in the following claims.

What is claimed is:

1. A photosensitive resin composition comprising:
an alkali-soluble resin (A);
a compound (B) containing an ethylenically unsaturated group;
a photoinitiator (C);
a solvent (D);
a black pigment (E); and
a compound (F) having a structure represented by Formula (1);
wherein:
the alkali-soluble resin (A) comprises a resin (A-1) having an unsaturated group, and the resin (A-1) having the unsaturated group is obtained by polymerizing a mixture comprising an epoxy compound (a-1-1) containing at least two epoxy groups, and a compound (a-1-2) containing at least one carboxylic acid group and at least one ethylenically unsaturated group; 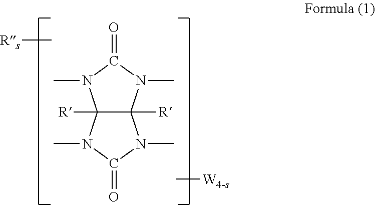
in Formula (1), R′ is selected from the group consisting of a hydrogen atom, a substituted or unsubstituted C₁-C₂₀ hydrocarbon group and a substituted or unsubstituted C₁-C₂₀ acyl group; each R′ is the same or different;
R″ is selected from the group consisting of a hydrogen atom, a substituted or unsubstituted C₁-C₁₅ hydrocarbon group, a substituted or unsubstituted C₁-C₁₅ acyl group and a substituted or unsubstituted C₁-C₁₅ nitro group; each R″ is the same or different;
s represents 0, 1 or 2; and
W represents 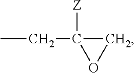
wherein, Z represents a hydrogen atom or a C₁-C₄ alkyl group.

2. The photosensitive resin composition according to claim 1, wherein the epoxy compound (a-1-1) containing at least two epoxy groups comprises a structure represented by Formula (2), a structure represented by Formula (3) or combinations thereof: 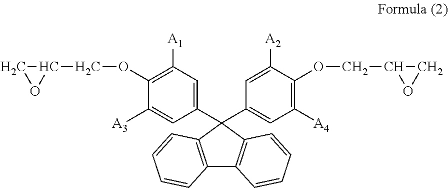
wherein in Formula (2), A₁ to A₄ independently represent a hydrogen atom, a halogen atom, a C₁-C₅ alkyl group, a C₁-C₅ alkoxy group, a C₆-C₁₂ aromatic group or a C₆-C₁₂ aromatic alkyl group; 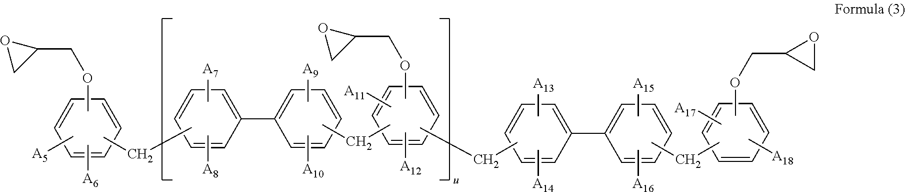
wherein in Formula (3), A₅ to A₁₈ independently represent a hydrogen atom, a halogen atom, a C₁-C₈ alkyl group or a C₆-C₁₅ aromatic group, and u represents an integer of 0 to 10.

3. The photosensitive resin composition according to claim 1, wherein based on 100 parts by weight of the used amount of the alkali-soluble resin (A), the used amount of the resin (A-1) having the unsaturated group is from 30 parts by weight to 100 parts by weight; the used amount of the compound (B) containing the ethylenically unsaturated group is from 20 parts by weight to 200 parts by weight; the used amount of the photoinitiator (C) is from 5 parts by weight to 100 parts by weight; the used amount of the solvent (D) is from 800 parts by weight to 3000 parts by weight; and the black pigment (E) is from 100 parts by weight to 500 parts by weight; and the compound (F) having the structure represented by Formula (1) is from 1 parts by weight to 40 parts by weight.

4. The photosensitive resin composition according to claim 1, wherein the photoinitiator (C) comprises a photoinitiator (C-1) represented by Formula (4): 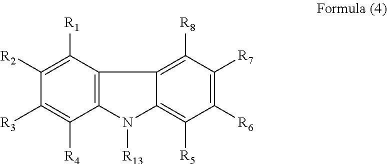
wherein in Formula (4), R₁, R₂, R₃, R₄, R₅, R₆, R₇ and R₈ are independently hydrogen, C₁-C₂₀ alkyl, 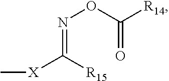
COR₁₆, OR₁₇, halogen, NO₂ or 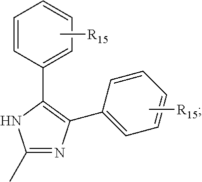
or
R₁ and R₂, R₂ and R₃, R₃ and R₄, R₅ and R₆, R₆ and R₇, or R₇ and R₈ are independently C₂-C₁₀ alkenyl which is substituted by 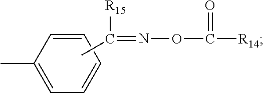
R₁ and R₂, R₂ and R₃, R₃ and R₄, R₅ and R₆, R₆ and R₇, or R₇ and R₈ are together independently —(CH₂)ₚ—Y—(CH₂)_{q}—; or
R₁ and R₂, R₂ and R₃, R₃ and R₄, R₅ and R₆, R₆ and R₇, or R₇ and R₈ are together independently 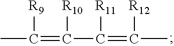
and
provided that R₁ and R₂, R₂ and R₃, R₃ and R₄, R₅ and R₆, R₆ and R₇, R₇ and R₈, or any combination thereof, is 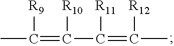
R₉, R₁₀, R₁₁ and R₁₂ are independently hydrogen, C₁-C₂₀ alkyl which is unsubstituted or substituted by one or more halogen, phenyl, CN, OH, SH, C₁-C₄-alkoxy, (CO)OH or any combination thereof, or by (CO)O(C₁-C₄ alkyl);
or R₉, R₁₀, R₁₁ and R₁₂ are independently unsubstituted phenyl or phenyl substituted by one or more C₁-C₆ alkyl, halogen, CN, OR₁₇, SR₁₈, or any combination thereof, or by NR₁₉R₂₀; or
R₉, R₁₀, R₁₁, and R₁₂ are independently halogen, CN, OR₁₇, SR₁₈, SOR₁₈, SO₂R₁₈, or NR₁₉R₂₀, wherein OR₁₇, SR₁₈, or NR₁₉R₂₀ optionally comprises a 5-membered ring or 6-membered ring via radicals R₁₇, R₁₈, R₁₉, R₂₀, or any combination thereof, with one of carbon atoms of a naphthyl ring; or
R₉, R₁₀, R₁₁, and R₁₂ are independently 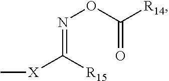
COR₁₆ or NO₂;
Y is O, S, NR₂₆ or a direct bond;
p is an integer 0, 1, 2 or 3;
q is an integer 1, 2 or 3;
X is CO or a direct bond;
R₁₃ is C₁-C₂₀ alkyl which is unsubstituted or substituted by one or more halogen, R₁₇, COOR₁₇, OR₁₇, SR₁₈, CONR₁₉R₂₀, NR₁₉R₂₀, PO(OCₖH₂ₖ₊₁)₂, or any combination thereof, or by 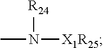
or
R₁₃ is C₂-C₂₀ alkyl which is interrupted by one or more O, S, SO, SO₂, NR₂₆, CO, or any combination thereof; or R₁₃ is C₂-C₁₂ alkenyl which is uninterrupted or is interrupted by one or more O, CO, NR₂₆, or any combination thereof, wherein the interrupted C₂-C₂₀ alkyl and the uninterrupted or interrupted C₂-C₁₂ alkenyl are unsubstituted or substituted by one or more halogen; or
R₁₃ is C₄-C₈ cycloalkenyl, C₂-C₁₂ alkynyl, or C₃-C₁₀ cycloalkyl which is uninterrupted or interrupted by O, S, CO, NR₂₆, or any combination thereof; or
R₁₃ is phenyl or naphthyl, each of which is unsubstituted or substituted by one or more OR₁₇, SR₁₈, NR₁₉R₂₀, 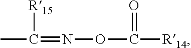
COR₁₆, CN, NO₂, halogen, C₁-C₂₀ alkyl, C₁-C₄ haloalkyl, C₂-C₂₀ alkyl, or any combination thereof, which is interrupted by one or more O, S, CO, NR₂₆, or any combination thereof, or each of which is substituted by C₃-C₁₀ cycloalkyl or by C₃-C₁₀ cycloalkyl which is interrupted by one or more O, S, CO, NR₂₆, or any combination thereof;
k is an integer 1-10;
R₁₄ is hydrogen, C₃-C₈ cycloalkyl, C₂-C₈ alkenyl, C₁-C₂₀ alkoxy, or C₁-C₂₀ alkyl which is unsubstituted or substituted by one or more halogen, phenyl, C₁-C₂₀ alkylphenyl, CN, or any combination thereof; or
R₁₄ is phenyl or naphthyl, each of which is unsubstituted or substituted by one or more C₁-C₆ alkyl, C₁-C₄ haloalkyl, halogen, CN, OR₁₇, SR₁₈, NR₁₉R₂₀, or any combination thereof; or
R₁₄ is C₃-C₂₀ heteroaryl, C₁-C₈ alkoxy, benzyloxy or phenoxy, which benzyloxy and phenoxy are unsubstituted or substituted by C₁-C₆ alkyl, C₁-C₄ haloalkyl, halogen, or any combination thereof;
R₁₅ is C₆-C₂₀ aryl or C₃-C₂₀ heteroaryl each of which is unsubstituted or substituted by one or more phenyl, halogen, C₁-C₄ haloalkyl, CN, NO₂, OR₁₇, SR₁₈, NR₁₉R₂₀, PO(OCₖH₂ₖ₊₁)₂, SO—C₁-C₁₀ alkyl, SO₂—C₁-C₁₀ alkyl, or any combination thereof, by C₂-C₂₀ alkyl which is interrupted by one or more O, S, NR₂₆, or any combination thereof, or each of which is substituted by C₁-C₂₀ alkyl which is unsubstituted or substituted by one or more halogen, COOR₁₇, CONR₁₉R₂₀, phenyl, C₃-C₈ cycloalkyl, C₃-C₂₀ heteroaryl, C₆-C₂₀ aryloxycarbonyl, C₃-C₂₀ heteroaryloxycarbonyl, OR₁₇, SR₁₈, NR₁₉R₂₀, or any combination thereof; or
R₁₅ is hydrogen, C₂-C₁₂ alkenyl, C₃-C₈ cycloalkyl which is uninterrupted or is interrupted by one or more O, CO, NR₂₆, or any combination thereof; or
R₁₅ is C₁-C₂₀ alkyl which is unsubstituted or substituted by one or more halogen, OR₁₇, SR₁₈, C₃-C₈ cycloalkyl, C₃-C₂₀ heteroaryl, C₆-C₂₀ aryloxycarbonyl, C₃-C₂₀ heteroaryloxycarbonyl, NR₁₉R₂₀, COOR₁₇, CONR₁₉R₂₀, PO(OCₖH₂ₖ₊₁)₂, 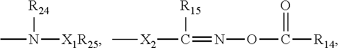
phenyl, or any combination thereof, or the C₁-C₂₀ alkyl is substituted by phenyl which is substituted by halogen, C₁-C₂₀ alkyl, C₁-C₄ haloalkyl, OR₁₇, SR₁₈, or NR₁₉R₂₀; or
R₁₅ is C₂-C₂₀ alkyl which is interrupted by one or more O, SO, SO₂, or any combination thereof, and which interrupted C₂-C₂₀ alkyl is unsubstituted or substituted by one or more halogen, OR₁₇, COOR₁₇, CONR₁₉R₂₀, phenyl or, by phenyl which is substituted by OR₁₇, SR₁₈, or NR₁₉R₂₀; or
R₁₅ is C₂-C₂₀ alkanoyl, or benzoyl which is unsubstituted or substituted by one or more C₁-C₆ alkyl, halogen, phenyl, OR₁₇, SR₁₈, NR₁₉R₂₀, or any combination thereof; or
R₁₅ is naphthoyl which is unsubstituted or is substituted by one or more OR₁₇ or is C₃-C₁₄ heteroarylcarbonyl; or
R₁₅ is C₂-C₁₂ alkoxycarbonyl which is uninterrupted or is interrupted by one or more O and which interrupted or uninterrupted C₂-C₁₂ alkoxycarbonyl is unsubstituted or substituted by a one or more hydroxyl group;
or R₁₅ is phenoxycarbonyl which is unsubstituted or substituted by one or more C₁-C₆ alkyl, halogen, C₁-C₄ haloalkyl, phenyl, OR₁₇, SR₁₈, NR₁₉R₂₀, or any combination thereof; or
R₁₅ is CN, CONR₁₉R₂₀, NO₂, C₁-C₄ haloalkyl, S(O)ₘ—C₁-C₆ alkyl; S(O)ₘ-phenyl which is unsubstituted or substituted by C₁-C₁₂ alkyl or SO₂—C₁-C₆ alkyl; or
R₁₅ is SO₂O-phenyl which is unsubstituted or substituted by C₁-C₁₂ alkyl; or R₁₅ is diphenyl phosphinoyl or di-(C₁-C₄ alkoxy)-phosphinoyl;
m is 1 or 2;
R′₁₄ has one of the meanings as given for R₁₄;
R′₁₅ has one of the meanings as given for R₁₅;
X₁ is O, S, SO, or SO₂;
X₂ is O, CO, S, or a direct bond;
R₁₆ is C₆-C₂₀ aryl or C₃-C₂₀ heteroaryl each of which is unsubstituted or substituted by one or more phenyl, halogen, C₁-C₄ haloalkyl, CN, NO₂, OR₁₇, SR₁₈, NR₁₉R₂₀, or any combination thereof, or by C₁-C₂₀ alkyl which is interrupted by one or more O, S, or NR₂₆, or any combination thereof, each of which is substituted by one or more C₁-C₂₀ alkyl which is unsubstituted or substituted by one or more halogen, COOR₁₇, CONR₁₉R₂₀, phenyl, C₃-C₈ cycloalkyl, C₃-C₂₀ heteroaryl, C₆-C₂₀ aryloxycarbonyl, C₃-C₂₀ heteroaryloxycarbonyl, OR₁₇, SR₁₈, NR₁₉R₂₀, or any combination thereof; or
R₁₆ is hydrogen, C₁-C₂₀ alkyl which is unsubstituted or substituted by one or more halogen, phenyl, OH, SH, CN, C₃-C₆ alkenoxy, OCH₂CH₂CN, OCH₂CH₂(CO)O(C₁-C₄ alkyl), O(CO)—(C₁-C₄ alkyl), O(CO)-phenyl, (CO)OH, (CO)O(C₁-C₄ alkyl), or any combination thereof; or
R₁₆ is C₂-C₁₂ alkyl which is interrupted by one or more O, S, NR₂₆, or any combination thereof; or
R₁₆ is (CH₂CH₂O)ₙ₊₁H, (CH₂CH₂O)ₙ(CO)—(C₁-C₈ alkyl), C₂-C₁₂ alkenyl, or C₃-C₈ cycloalkyl; or
R₁₆ is phenyl substituted by SR₁₈ wherein radical R₁₈ denotes a direct bond to a phenyl or naphthyl ring of a carbazole moiety to which a COR₁₆ group is attached;
n is 1 to 20;
R₁₇ is hydrogen, phenyl-C₁-C₃ alkyl, C₁-C₂₀ alkyl which is unsubstituted or substituted by one or more halogen, OH, SH, CN, C₃-C₆ alkenoxy, OCH₂CH₂CN, OCH₂CH₂(CO)O(C₁-C₄ alkyl), O(CO)—(C₁-C₄alkyl), O(CO)—(C₂-C₄)alkenyl, O(CO)-phenyl, (CO)OH, (CO)O(C₁-C₄ alkyl), C₃-C₂₀ cycloalkyl, SO₂—(C₁-C₄ haloalkyl), O(C₁-C₄ haloalkyl), or any combination thereof, or by C₃-C₂₀ cycloalkyl which is interrupted by one or more O; or
R₁₇ is C₂-C₂₀ alkyl which is interrupted by O, S, NR₂₆, or any combination thereof; or
R₁₇ is (CH₂CH₂O)ₙ₊₁H, (CH₂CH₂O)ₙ(CO)—(C₁-C₈ alkyl), C₁-C₈ alkanoyl, C₂-C₁₂ alkenyl, C₃-C₆ alkenoyl, or C₃-C₂₀ cycloalkyl which is uninterrupted or interrupted by one or more O, S, CO, NR₂₆, or any combination thereof; or
R₁₇ is C₁-C₈ alkyl-C₃-C₁₀ cycloalkyl which is uninterrupted or interrupted by one or more O; or
R₁₇ is benzoyl which is unsubstituted or substituted by one or more C₁-C₆ alkyl, halogen, OH, C₁-C₃ alkoxy, or any combination thereof; or
R₁₇ is phenyl, naphthyl, or C₃-C₂₀ heteroaryl, each of which is unsubstituted or substituted by one or more halogen, OH, C₁-C₁₂ alkyl, C₁-C₁₂ alkoxy, CN, NO₂, phenyl-C₁-C₃ alkyloxy, phenoxy, C₁-C₁₂ alkylsulfanyl, phenylsulfanyl, N(C₁-C₁₂ alkyl)₂, diphenylamino, 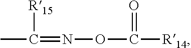
or any combination thereof; or
R₁₇ comprises a direct bond to one of carbon atoms of phenyl or naphthyl ring on which 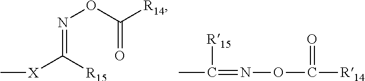
is located;
R₁₈ is hydrogen, C₂-C₁₂ alkenyl, C₃-C₂₀ cycloalkyl, or phenyl-C₁-C₃ alkyl, wherein the C₂-C₁₂ alkenyl, C₃-C₂₀ cycloalkyl, or phenyl-C₁-C₃ alkyl is uninterrupted or interrupted by one or more O, S, CO, NR₂₆, COOR₁₇, or any combination thereof; or
R₁₈ is C₁-C₂₀ alkyl which is unsubstituted or is substituted by one or more OH, SH, CN, C₃-C₆ alkenoxy, OCH₂CH₂CN, OCH₂CH₂(CO)O(C₁-C₄ alkyl), O(CO)—(C₂-C₄)alkenyl, O(CO)—(C₁-C₄ alkyl), O(CO)-phenyl, (CO)OR₁₇, or any combination thereof; or
R₁₈ is C₂-C₂₀ alkyl which is interrupted by one or more O, S, CO, NR₂₆, COOR₁₇, or any combination thereof; or
R₁₈ is (CH₂CH₂O)ₙH, (CH₂CH₂O)ₙ(CO)—(C₁-C₈ alkyl), C₂-C₈ alkanoyl, or C₃-C₆ alkenoyl; or
R₁₈ is benzoyl which is unsubstituted or substituted by one or more C₁-C₆ alkyl, halogen, OH, C₁-C₄ alkoxy, C₁-C₄ alkylsulfanyl, or any combination thereof; or
R₁₈ is phenyl, naphthyl, or C₃-C₂₀ heteroaryl, each of which is unsubstituted or substituted by one or more halogen, C₁-C₁₂ alkyl, C₁-C₄ haloalkyl, C₁-C₁₂ alkoxy, CN, NO₂, phenyl-C₁-C₃ alkyloxy, phenoxy, C₁-C₁₂ alkylsulfanyl, phenylsulfanyl, N(C₁-C₁₂ alkyl)₂, diphenylamino, (CO)O(C₁-C₈ alkyl), (CO)—C₁-C₈ alkyl, (CO)N(C₁-C₈ alkyl)₂, 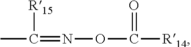
or any combination thereof;
R₁₉ and R₂₀ are independently hydrogen, C₁-C₂₀ alkyl, C₂-C₄ hydroxyalkyl, C₂-C₁₀ alkoxyalkyl, C₂-C₅ alkenyl, C₃-C₂₀ cycloalkyl, phenyl-C₁-C₃ alkyl, C₁-C₈ alkanoyl, C₁-C₈ alkanoyloxy, C₃-C₁₂ alkenoyl SO₂—(C₁-C₄ haloalkyl), or benzoyl; or
R₁₉ and R₂₀ are phenyl, naphthyl, or C₃-C₂₀ heteroaryl, each of which is unsubstituted or substituted by one or more halogen, C₁-C₄ haloalkyl, C₁-C₂₀ alkoxy, C₁-C₁₂ alkyl, benzoyl, C₁-C₁₂ alkoxy, or any combination thereof; or
R₁₉ and R₂₀ together with the N-atom to which they are attached comprise a 5- or 6-membered saturated or unsaturated ring which is uninterrupted or is interrupted by one or more O, S, or NR₁₇, and which is unsubstituted or substituted by one or more C₁-C₂₀ alkyl, C₁-C₂₀ alkoxy, ═O, OR₁₇, SR₁₈, NR₂₁R₂₂, (CO)R₂₃, NO₂, halogen, C₁-C₄-haloalkyl, CN, phenyl, 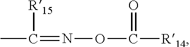
or any combination thereof, or by C₃-C₂₀ cycloalkyl which is uninterrupted or is interrupted by one or more O, S, CO, NR₁₇, or any combination thereof; or
R₁₉ and R₂₀ together with the N-atom to which they are attached comprise a heteroaromatic ring system which is unsubstituted or substituted by one or more C₁-C₂₀ alkyl, C₁-C₄ haloalkyl, C₁-C₂₀ alkoxy, ═O, OR₁₇, SR₁₈, NR₂₁R₂₂, (CO)R₂₃, 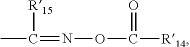
halogen, NO₂, CN, phenyl, or any combination thereof, or by C₃-C₂₀ cycloalkyl which is uninterrupted or is interrupted by one or more O, S, CO, NR₁₇, or any combination thereof;
R₂₁ and R₂₂ are independently hydrogen, C₁-C₂₀ alkyl, C₁-C₄ haloalkyl, C₃-C₁₀ cycloalkyl, or phenyl; or
R₂₁ and R₂₂ together with the N-atom to which they are attached comprise a 5- or 6-membered saturated or unsaturated ring, which is uninterrupted or is interrupted by O, S, or NR₂₆, and which 5- or 6-membered saturated or unsaturated ring is not condensed or to which 5- or 6-membered saturated or unsaturated ring a benzene ring is condensed;
R₂₃ is hydrogen, OH, C₁-C₂₀ alkyl, C₁-C₄ haloalkyl, C₂-C₂₀ alkyl which is interrupted by one or more O, CO, or NR₂₆, C₃-C₂₀ cycloalkyl, or any combination thereof, which is uninterrupted or is interrupted by O, S, CO, or NR₂₆, or R₂₃ is phenyl, naphthyl, phenyl-C₁-C₄ alkyl, OR₁₇, SR₁₈, or NR₂₁R₂₂;
R₂₄ is (CO)OR₁₇, CONR₁₉R₂₀, (CO)R₁₇; or R₂₄ has one of the meanings given for R₁₉ and R₂₀;
R₂₅ is COOR₁₇, CONR₁₉R₂₀, (CO)R₁₇; or R₂₅ has one of the meanings given for R₁₇;
R₂₆ is hydrogen, C₁-C₂₀ alkyl, C₁-C₄ haloalkyl, or C₂-C₂₀ alkyl which is interrupted by one or more O or CO, or any combination thereof, or is phenyl-C₁-C₄ alkyl, or C₃-C₈ cycloalkyl which is uninterrupted or is interrupted by one or more O or CO, or any combination thereof, or is (CO)R₁₉ or is phenyl which is unsubstituted or substituted by one or more C₁-C₂₀ alkyl, halogen, C₁-C₄ haloalkyl, OR₁₇, SR₁₈, NR₁₉R₂₀, 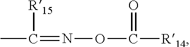
or any combination thereof; and
provided that at least one group 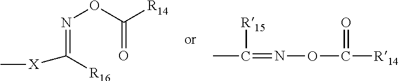
is present in the molecule.

5. The photosensitive resin composition according to claim 4, wherein the photoinitiator (C) comprises a photoinitiator (C-1) represented by Formula (4), wherein R₁, R₂, R₃, R₄, R₅, R₆, R₇, and R₈ are independently hydrogen, C₁-C₂₀ alkyl, 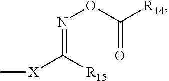
COR₁₆, or NO₂, or R₁ and R₂, R₂ and R₃, R₃ and R₄, R₅ and R₆, R₆ and R₇, or R₇ and R₈ are together independently 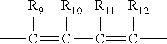
provided that R₁ and R₂, R₂ and R₃, R₃ and R₄, R₅ and R₆, R₆ and R₇, R₇ and R₈, or any combination thereof, is 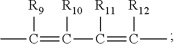
X is CO or a direct bond;
R₁₃ is C₁-C₂₀ alkyl which is unsubstituted or substituted by halogen, OR₁₇, SR₁₈, COOR₁₇, CONR₁₉R₂₀, or any combination thereof, or by PO(OCₖH₂ₖ₊₁)₂; or
R₁₃ is C₂-C₂₀ alkyl which is interrupted by O, S, NR₂₆, CO, or any combination thereof; or
R₁₃ is phenyl or naphthyl both of which are unsubstituted or substituted by 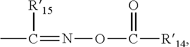
COR₁₆, or any combination thereof;
R₁₄ is C₁-C₂₀ alkyl, phenyl, or C₁-C₈ alkoxy;
R₁₅ is phenyl, naphthyl, or C₃-C₂₀ heteroaryl each of which is unsubstituted or substituted by phenyl, halogen, C₁-C₄ haloalkyl, OR₁₇, SR₁₈, C₂-C₂₀ alkyl, or any combination thereof, which is interrupted by O or S, or any combination thereof, or each of which is substituted by C₁-C₂₀ alkyl which is unsubstituted or substituted by halogen, COOR₁₇, CONR₁₉R₂₀, phenyl, C₃-C₈ cycloalkyl, C₃-C₂₀ heteroaryl, C₆-C₂₀ aryloxycarbonyl, C₄-C₂₀ heteroaryloxycarbonyl, OR₁₇, SR₁₈, NR₁₉R₂₀, PO(OCₖH₂ₖ₊₁)₂, or any combination thereof; or
R₁₅ is C₁-C₂₀ alkyl which is unsubstituted or substituted by OR₁₇, SR₁₈, C₃-C₈ cycloalkyl, C₃-C₂₀ heteroaryl, NR₁₉R₂₀, COOR₁₇, CONR₁₉R₂₀, PO(OCₖH₂ₖ₊₁)₂, or any combination thereof;
R′₁₄ is R₁₄;
R′₁₅ is R₁₅;
R₁₆ is phenyl which is unsubstituted or substituted by OR₁₇, SR₁₈, NR₁₉R₂₀, or any combination thereof, or by C₂-C₂₀ alkyl which is interrupted by O, S, NR₂₆, or any combination thereof; or
R₁₆ is phenyl which is substituted by C₁-C₂₀ alkyl which is unsubstituted or substituted by halogen, COOR₁₇, CONR₁₉R₂₀, phenyl, C₃-C₈ cycloalkyl, C₃-C₂₀ heteroaryl, C₆-C₂₀ aryloxycarbonyl, C₄-C₂₀ heteroaryloxycarbonyl, OR₁₇, SR₁₈, NR₁₉R₂₀, or any combination thereof; or
R₁₆ is C₁-C₂₀ alkyl which is unsubstituted or substituted by halogen, phenyl, OH, SH, CN, C₃-C₆ alkenoxy, OCH₂CH₂(CO)O(C₁-C₄ alkyl), O(CO)—(C₁-C₄ alkyl), or (CO)O(C₁-C₄ alkyl);
R₁₇ is C₁-C₂₀ alkyl which is unsubstituted or substituted by halogen, OCH₂CH₂(CO)O(C₁-C₄ alkyl), O(C₁-C₄ alkyl), (CO)O(C₁-C₄ alkyl), C₃-C₂₀ cycloalkyl, or any combination thereof, or by C₃-C₂₀ cycloalkyl which is interrupted by O; or
R₁₇ is C₂-C₂₀ alkyl which is interrupted by O;
R₁₈ is methyl substituted by (CO)OR₁₇;
R₁₉ and R₂₀ are independently hydrogen, phenyl, C₁-C₂₀ alkyl, C₁-C₈ alkanoyl, or C₁-C₈ alkanoyloxy; or
R₁₉ and R₂₀ together with a N-atom to which they are attached comprise a heteroaromatic ring system which is unsubstituted or substituted by 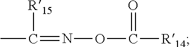
provided that 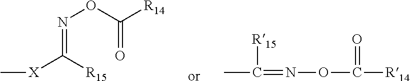
is present in a molecule.

6. The photosensitive resin composition according to claim 4, wherein the photoinitiator (C) comprises a photoinitiator (C-1) represented by Formula (4), wherein R₁, R₂, R₃, R₄, R₅, R₆, R₇, and R₈ are independently hydrogen, or R₁ and R₂, R₃ and R₄, or R₅ and R₆, are together independently 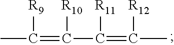
provided that R₁ and R₂, R₃ and R₄, R₅ and R₆, or any combination thereof, is 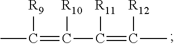
or
R₂ is 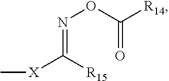
COR₁₆, NO₂, or 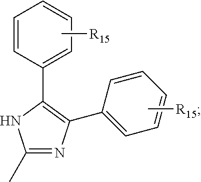
or
R₇ is 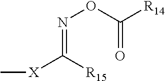
or COR₁₆;
R₉, R₁₁, and R₁₂ are hydrogen;
R₁₀ is hydrogen, OR₁₇, or COR₁₆;
X is CO or a direct bond;
R₁₃ is C₁-C₂₀ alkyl which is unsubstituted or substituted by halogen, R₁₇, OR₁₇, SR₁₈, or any combination thereof, or by PO(OCₖH₂ₖ₊₁)₂; or
R₁₃ is C₂-C₂₀ alkyl which is interrupted by O; or
R₁₃ is phenyl;
k is an integer 2;
R₁₄ is C₁-C₂₀ alkyl or thienyl;
R₁₅ is phenyl or naphthyl each of which is unsubstituted or substituted by OR₁₇, C₁-C₂₀ alkyl, or any combination thereof; or
R₁₅ is thienyl, hydrogen, or C₁-C₂₀ alkyl which is unsubstituted or substituted by OR₁₇, SR₁₈, C₃-C₈ cycloalkyl, NR₁₉R₂₀, or any combination thereof, or by COOR₁₇; or
R₁₅ is C₂-C₂₀ alkyl which is interrupted by SO₂;
R₁₆ is phenyl or naphthyl each of which is unsubstituted or substituted by OR₁₇, SR₁₈, NR₁₉R₂₀, or any combination thereof, or by C₁-C₂₀ alkyl; or
R₁₆ is thienyl;
R₁₇ is hydrogen, C₁-C₈ alkanoyl, or C₁-C₂₀ alkyl which is unsubstituted or substituted by halogen, O(CO)—(C₁-C₄ alkyl), O(CO)—(C₂-C₄)alkenyl, or any combination thereof, or by C₃-C₂₀ cycloalkyl which is interrupted by O; or
R₁₇ is C₂-C₂₀ alkyl which is interrupted by O;
R₁₈ is C₃-C₂₀ cycloalkyl, C₁-C₂₀ alkyl which is unsubstituted or is substituted by OH, O(CO)—(C₂-C₄)alkenyl, (CO)OR₁₇, or any combination thereof; or
R₁₈ is phenyl which is unsubstituted or substituted by halogen;
R₁₉ and R₂₀ are independently C₁-C₈ alkanoyl or C₁-C₈ alkanoyloxy; or
R₁₉ and R₂₀ together with a N-atom to which they are attached comprise a 5- or 6-membered saturated ring which is interrupted by O;
provided that 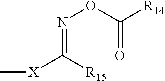
R₁ is present in the molecule.

7. The photosensitive resin composition according to claim 4, wherein based on 100 parts by weight of the used amount of the alkali-soluble resin (A), the used amount of the photoinitiator (C-1) represented by Formula (4) is from 5 parts by weight to 40 parts by weight.

8. A black matrix formed with the photosensitive resin composition according to claim 1 through pre-baking treatment, exposure treatment, developing treatment and post-baking treatment.

9. A color filter comprising the black matrix according to claim 8.

10. A liquid crystal display device comprising the color filter according to claim 9.
